(19) United States
(12) Patent Application Publication
(10) Pub. No.: US 2026/0160929 A1
(43) Pub. Date: Jun. 11, 2026

(54) LIGHT ABSORPTION FILTER, OPTICAL FILTER, MANUFACTURING METHOD FOR OPTICAL FILTER, ORGANIC ELECTROLUMINESCENT DISPLAY DEVICE, INORGANIC ELECTROLUMINESCENT DISPLAY DEVICE, AND LIQUID CRYSTAL DISPLAY DEVICE

(71) Applicant: FUJIFILM Corporation, Tokyo (JP)

(72) Inventor: Nobutaka FUKAGAWA, Kanagawa (JP)

(73) Assignee: FUJIFILM Corporation, Tokyo (JP)

(21) Appl. No.: 19/182,174

(22) Filed: Apr. 17, 2025

Related U.S. Application Data
(63) Continuation of application No. PCT/JP2023/037643, filed on Oct. 18, 2023.

(30) Foreign Application Priority Data
Oct. 21, 2022 (JP) 2022-168878
Mar. 3, 2023 (JP) 2023-032507
Aug. 31, 2023 (JP) 2023-141860
Oct. 11, 2023 (JP) 2023-176170

(51) Int. Cl. G02B 5/22; G02F 1/135; H10H 29/01; H10K 59/38

(52) U.S. Cl. CPC G02B 5/223; G02F 1/1351; H10H 29/034; H10K 59/38

(57) ABSTRACT

A light absorption filter including a support, and a dye layer containing a resin, a dye having a main absorption wavelength band in a wavelength range of 400 to 700 nm, and a compound that generates a radical upon ultraviolet irradiation, the dye layer being provided on the support, in which a layer that inhibits diffusion of a component in the dye layer to the support is provided between the support and the dye layer, an optical filter using the light absorption filter, a manufacturing method for an optical filter, an organic electroluminescent display device, an inorganic electroluminescent display device, and a liquid crystal display device.

### CROSS-REFERENCE TO RELATED APPLICATIONS

This application is a Continuation of PCT International Application No. PCT/JP2023/037643 filed on Oct. 18, 2023, which was published under PCT Article 21(2) in Japanese, and which claims priority under 35 U.S.C. § 119(a) to Japanese Patent Application No. 2022-168878 filed in Japan on Oct. 21, 2022, Japanese Patent Application No. 2023-032507 filed in Japan on Mar. 3, 2023, Japanese Patent Application No. 2023-141860 filed in Japan on Aug. 31, 2023, and Japanese Patent Application No. 2023-176170 filed in Japan on Oct. 11, 2023. Each of the above applications is hereby expressly incorporated by reference, in its entirety, into the present application.

### BACKGROUND OF THE INVENTION

### 1. Field of the Invention

The present invention relates to a light absorption filter, an optical filter, a manufacturing method for the optical filter, an organic electroluminescent display device, an inorganic electroluminescent display device, and a liquid crystal display device.

### 2. Description of the Related Art

As image display devices, an organic electroluminescent (OLED) display device, an inorganic electroluminescent display device (inorganic EL display device), a liquid crystal display device, and the like have been used in recent years.

A liquid crystal display device is widely used year by year as a space-saving image display device with low power consumption. The liquid crystal display device is a non-light emitting element in which the liquid crystal panel itself displaying an image does not emit light, and thus the liquid crystal display device includes a backlight unit which is disposed on a rear surface of the liquid crystal panel and supplies light to the liquid crystal panel.

The OLED display device is a device that displays an image by utilizing self-luminescence of OLED elements. Therefore, the OLED display device has advantages that a high contrast ratio, a high color reproducibility, a wide viewing angle, a high-speed responsiveness, and a reduction in thickness and weight can be achieved, as compared with various display devices such as a liquid crystal display device and a plasma display device. In addition to these advantages, in terms of flexibility, research and development are being actively carried out as a next-generation display device.

The inorganic EL display device is a device that displays an image by utilizing self-luminescence of inorganic EL elements as a fluorescent material, instead of the OLED elements in the OLED display device. As a result of recent research, it is expected that a display device more excellent than the OLED display device in terms of a large screen size, a longer service life, and the like can be realized.

In the development of an image display device, there is known a technology of incorporating a light absorption filter as a configuration.

For example, in a liquid crystal display device, in a case where a white light emitting diode (LED) is used as a light source for a backlight unit, an attempt has been made to provide a light absorption filter in order to block light having unnecessary wavelengths emitted from the white LED. In addition, in the OLED display device, an attempt has been made to provide a light absorption filter from the viewpoint of suppressing the reflection of external light.

Regarding another form of the light absorption filter that is incorporated in an image display device, research has been also carried out on an optical filter having both a light absorptive portion having a light absorption effect and a portion in which the light absorbability has been eliminated (hereinafter, also simply referred to as a “light absorption property-eliminated portion”), which is obtained by eliminating the light absorbability of a desired portion. In particular, in a form in which an optical filter is used by being incorporated in an image display device, light absorption characteristics close to being colorless are required at a light absorption property-eliminated portion in the optical filter.

For example, WO2021/132674A describes a light absorption filter containing a resin; a dye that has a main absorption wavelength band in a wavelength range of 400 to 700 nm; and a compound that generates a radical upon ultraviolet irradiation, in which the dye includes a squaraine-based coloring agent represented by General Formula (1) or a benzylidene-based coloring agent described in WO2021/132674A or a cinnamylidene-based coloring agent represented by General formula (V). According to the light absorption filter described in WO2021/132674A, it is said that a high decolorization rate is exhibited upon ultraviolet irradiation, and absorption derived from a new coloration structure (hereinafter, also referred to as “secondary absorption”) associated with the decomposition of the dye upon ultraviolet irradiation hardly occurs, whereby high decolorizing properties can be obtained.

### SUMMARY OF THE INVENTION

However, in a case where the light absorption filter described in WO2021/132674A is used, a decolorization rate may not be sufficient, and there is room for improvement.

That is, an object of the present invention is to provide a light absorption filter which exhibits a more excellent decolorization rate in a case where ultraviolet irradiation is applied, with respect to a light absorption filter in the related art, and in which secondary absorption associated with the decomposition of a dye due to ultraviolet irradiation hardly occurs.

In addition, another object of the present invention is to provide an optical filter using the light absorption filter and having a light absorptive portion and a light absorption property-eliminated portion at a desired position, a manufacturing method for an optical filter, and an organic electroluminescent (OLED) display device, an inorganic electroluminescent (inorganic EL) display device, and a liquid crystal display device, each of which includes the optical filter.

As a result of intensive studies in view of the above-described problems, the present inventors have found that a decrease in decolorization rate is caused by diffusion of a part of a dye contained in a light absorption filter, a compound that generates a radical upon ultraviolet irradiation, and the like into a support. Based on the present finding, the present inventors have found that an excellent decolorization rate can be obtained by providing a layer that inhibits diffusion of a component in a dye layer to a support between a layer (in the present invention, referred to as a “dye layer”) containing a compound that generates a radical upon ultraviolet irradiation and a dye (coloring agent) and a support. Further studies have been carried out based on these findings, whereby the present invention has been completed.

That is, the above object has been achieved by the following means.

<1>

A light absorption filter comprising:
a support; and
a dye layer containing a resin, a dye having a main absorption wavelength band in a wavelength range of 400 to 700 nm, and a compound that generates a radical upon ultraviolet irradiation, the dye layer being provided on the support,
in which a layer that inhibits diffusion of a component in the dye layer to the support is provided between the support and the dye layer.
   <2>

The light absorption filter according to <1>,
in which the compound that generates the radical upon the ultraviolet irradiation includes a combination of a compound A having an acid group and a compound B having a structure that is capable of forming a hydrogen bond with the acid group contained in the compound A.
   <3>

The light absorption filter according to <2>,
in which the compound A is chemically bonded to a polymer that constitutes the resin.
   <4>

The light absorption filter according to any one of <1> to <3>,
in which in the light absorption filter, the dye is chemically changed to be decolorized upon the ultraviolet irradiation.
   <5>

An optical filter that is obtained by subjecting the light absorption filter according to any one of <1> to <4> to mask exposure by ultraviolet irradiation.

<6>

An organic electroluminescent display device, an inorganic electroluminescent display device, or a liquid crystal display device, comprising:
the optical filter according to <5>.
   <7>

The organic electroluminescent display device, the inorganic electroluminescent display device, or the liquid crystal display device according to claim <6>,
in which a layer that inhibits light absorption of the compound that generates the radical upon the ultraviolet irradiation is provided on a viewer side with respect to the optical filter.
   <8>

A manufacturing method for an optical filter, comprising:
irradiating the light absorption filter according to any one of <1> to <4> with an ultraviolet ray to carry out mask exposure.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In addition, in a case where a plurality of substituents and the like come close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, each of the components (the resin, the dye, and the compound (radical generator) that generates a radical upon ultraviolet irradiation such as a combination of a compound A having an acid group, a compound B having a structure capable of forming a hydrogen bond with the acid group contained in the compound A, and other components that may be appropriately contained) constituting the dye layer may be contained in one kind or two or more kinds in the dye layer. The same applies to the components (resins and the like) constituting the diffusion inhibiting layer, and one kind of component may be contained in the diffusion inhibiting layer, or two or more kinds of components may be contained therein. The same applies to an optical filter produced by using the light absorption filter according to the aspect of the present invention.

Unless otherwise specified, the optical filter according to the aspect of the present invention can preferably apply the description regarding the light absorption filter according to the aspect of the present invention, except that it has a light absorption property-eliminated portion formed by ultraviolet irradiation.

In the present invention, in a case where an E type double bond and a Z type double bond are present in a molecule, the double bond may be any one thereof or may be a mixture thereof, unless otherwise specified.

In the present invention, the representation of a compound (including a complex) is used to have a meaning including not only the compound itself but also a salt thereof, and an ion thereof. In addition, the expression of a compound has a meaning to include that a part of a structure is changed within a range in which an effect of the present invention is not impaired. Further, a compound for which substitution or non-substitution is not specified means that the compound may have a predetermined substituent within a range in which an effect of the present invention is not impaired. The same applies to the definition of a substituent or a linking group.

In addition, in the present invention, the numerical value range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (respective components are uniformly dispersed).

In the present invention, the description of “having a main absorption wavelength band in a wavelength range of XX to YY nm” means that a wavelength at which the maximal absorption is exhibited (that is, the maximal absorption wavelength) is present in the wavelength range of XX to YY nm. Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present either inside or outside the above-described wavelength range of XX to YY nm.

In the present invention, “(meth)acrylate” represents either or both of acrylate and methacrylate, “(meth)acrylic acid” represents any one or both of acrylic acid and methacrylic acid and “(meth)acryloyl” represents any one or both of acryloyl and methacryloyl.

The light absorption filter according to the aspect of the present invention exhibits a more excellent decolorization rate in a case where ultraviolet irradiation is performed, with respect to a light absorption filter in the related art, and in which secondary absorption associated with the decomposition of a dye due to ultraviolet irradiation hardly occurs.

In addition, the optical filter according to the aspect of the present invention, as well as the OLED display device, the inorganic EL display device, and the liquid crystal display device according to the aspect of the present invention, which include this optical filter, can have a light absorptive portion and a light absorption property-eliminated portion at a desired position of the optical filter.

In addition, according to the manufacturing method according to the aspect of the present invention, it is possible to obtain the optical filter according to the aspect of the present invention, which has a light absorptive portion and a light absorption property-eliminated portion at a desired position.

### BRIEF DESCRIPTION OF THE DRAWINGS

FIG. 1 is a schematic view illustrating an outline of one embodiment of a liquid crystal display device having an optical filter according to the present invention.

### DESCRIPTION OF THE PREFERRED EMBODIMENTS

### [Light Absorption Filter]

The light absorption filter according to the embodiment of the present invention has a configuration in which a diffusion inhibiting layer is provided on a support, and a dye layer described later is further provided thereon. That is, the light absorption filter according to the embodiment of the present invention includes a support, a diffusion inhibiting layer provided on the support, and a dye layer described later provided on the diffusion inhibiting layer. In addition, the light absorption filter according to the embodiment of the present invention may further have a gas barrier layer on the dye layer, as necessary. Hereinafter, the diffusion inhibiting layer, the dye layer, and the gas barrier layer will be described in order. In addition, for the support, refer to the description of the support in the coating method described later.

### <<Diffusion Inhibiting Layer>>

The diffusion inhibiting layer in the light absorption filter according to the embodiment of the present invention is not particularly limited as long as it has an effect of suppressing the diffusion of the components in the dye layer described later into the support.

Diffusion of the components in the dye layer to the support may occur in any state of a state in which the dye layer is formed on the support and a state after the dye layer is formed on the support. In the light absorption filter according to the embodiment of the present invention, the diffusion of the components in the dye layer into the support can be suppressed by the diffusion inhibiting layer. In this manner, the fading and decolorization reaction of the dye due to the ultraviolet irradiation on the light absorption filter according to the embodiment of the present invention can be carried out as the fading and decolorization reaction of the dye due to the compound that generates a radical upon ultraviolet irradiation in the dye layer, and the decolorization rate can be improved.

In the present invention, particularly in a case of forming the dye layer on the support, it is considered that the influence of the swelling of the support by the solvent in the coating liquid for forming the dye layer and the increase in the free volume in the support is large. From this viewpoint, in the light absorption filter according to the embodiment of the present invention, it is preferable that the resin constituting the diffusion inhibiting layer provided between the support and the dye layer has a low affinity for a solvent used in a case where the dye layer is formed on the diffusion inhibiting layer. For example, in a case where the resin constituting the diffusion inhibiting layer is a material in which a component such as a dye contained in the dye layer or a compound that generates a radical upon ultraviolet irradiation is dissolved in an organic solvent (non-aqueous solvent), the resin constituting the diffusion inhibiting layer is preferably a resin having low affinity for an organic solvent, that is, a water-soluble resin.

The affinity between the solvent used in the formation of the dye layer and the resin constituting the diffusion inhibiting layer can be evaluated by the solubility parameter dt calculated according to the Hoy method. For example, the solubility parameter δt can be calculated by a method described in the column of “2) Method of Hoy (1985, 1989)” on pages 214 to 220 of the literature “Properties of Polymers 3^{rd}, ELSEVIER, (1990)”.

In the present invention, the absolute value of the difference between the δt value of the solvent used in the formation of the dye layer and the δt value of the resin constituting the diffusion inhibiting layer is preferably 1.0 or more, more preferably 2.0 or more, still more preferably 3.0 or more, and particularly preferably 4.0 or more. In a case where the absolute value of the difference between the δt value of the solvent used in the formation of the dye layer and the St value of the resin constituting the diffusion inhibiting layer is adjusted to be equal to or greater than the above-described preferred value, the solvent contained in the liquid forming the dye layer is suppressed from permeating the diffusion inhibiting layer in a case where the liquid forming the dye layer is applied onto the diffusion inhibiting layer, and thus the swelling of the support is effectively suppressed, which is preferable. The upper limit value of the absolute value of the difference between the δt value of the solvent used in the formation of the dye layer and the δt value of the resin constituting the diffusion inhibiting layer is practically 20.0 or less, and the absolute value of the difference between the δt value of the solvent used in the formation of the dye layer and the δt value of the resin constituting the diffusion inhibiting layer is preferably 1.0 to 20.0, more preferably 2.0 to 20.0, still more preferably 3.0 to 20.0, and particularly preferably 4.0 to 20.0.

In a case where two or more kinds of solvents are used in the formation of the dye layer, the St value of the solvent means a weight-average value of St values of each solvent. In addition, in a case where the diffusion inhibiting layer is composed of two or more kinds of resins, the δt value of the resin means a weight-average value of each resin.

### (Resin)

As the resin constituting the diffusion inhibiting layer, a water-soluble resin is preferable. The water-soluble resin may be any of a thermosetting resin or a thermoplastic resin, and in a case where the water-soluble resin is a thermoplastic resin, the water-soluble resin may be crystalline or non-crystalline.

For example, as the water-soluble resin, polyvinyl alcohol, polyvinylpyridine, a (meth)acrylic resin, polyurethane, polyester, an epoxy resin, a cellulose resin, or the like can be preferably used. At least one part of these water-soluble resins may be modified.

The polyvinyl alcohol may be modified or may not be modified. Examples of the modified polyvinyl alcohol include modified polyvinyl alcohol into which a group such as an acetoacetyl group and a carboxy group is introduced.

From the viewpoint of further enhancing the barrier properties (permeation suppression performance) of the organic solvent, the saponification degree of the polyvinyl alcohol is preferably 60.0 mol % or more, more preferably 80.0 mol % or more, and still more preferably 90.0 mol % or more. The upper limit value thereof is not particularly limited, and it is practically 99.99 mol % or less. The saponification degree of the polyvinyl alcohol is a value calculated based on the method described in JIS K 6726 (1994).

The above-described (meth)acrylic resin may be any resin including at least one of a constitutional unit derived from (meth)acrylic acid or a constitutional unit derived from a (meth)acrylic acid ester, and a resin including a constitutional unit derived from (meth)acrylic acid is preferable. The proportion of the constitutional unit derived from (meth)acrylic acid in all constitutional units constituting the (meth)acrylic resin is preferably 70 to 100 mol %, more preferably 80 to 100 mol %, and still more preferably 90 to 100 mol %.

Among these, from the viewpoint that the crystal portion can effectively suppress the permeation of solvent molecules and the viewpoint that swelling due to the organic solvent used in the dye layer is unlikely to occur, as the resin constituting the diffusion inhibiting layer, at least one of a polyvinyl alcohol or a (meth)acrylic resin is preferably used, and at least one of a polyvinyl alcohol or a poly(meth)acrylic acid is more preferably used.

Furthermore, from the viewpoint of further improving the adhesiveness between each layer constituting the light absorption filter according to the embodiment of the present invention, the resin constituting the diffusion inhibiting layer is still more preferably poly(meth)acrylic acid.

The content of the resin (preferably, the water-soluble resin) in the diffusion inhibiting layer is, for example, preferably 90% by mass or more and more preferably 95% by mass or more. The upper limit value thereof is not particularly limited, and it can be set to 100% by mass.

From the viewpoint of further improving the diffusion inhibition ability, the thickness of the diffusion inhibiting layer is preferably 0.1 to 5.0 μm and more preferably 0.2 to 4.0 μm.

### (Method for Producing Diffusion Inhibiting Layer)

A method of forming the diffusion inhibiting layer is not particularly limited, and examples thereof include a method of preparing the diffusion inhibiting layer on a support by a casting method such as spin coating or slit coating according to a conventional method.

The solvent used in this case can be used without particular limitation as long as a desired diffusion inhibiting layer can be obtained. For example, in a case where the resin constituting the diffusion inhibiting layer is a water-soluble resin, a water-soluble solvent such as water, ethanol, or isopropyl alcohol can be preferably used.

Regarding the support, the description of the support in the coating method described later can be applied as it is.

### <<Dye Layer>>

Next, the dye layer in the light absorption filter according to the embodiment of the present invention will be described.

The dye layer contains a resin, a compound that generates a radical upon ultraviolet irradiation, and a dye having a main absorption wavelength band in a wavelength range of 400 to 700 nm (in the present invention, also simply referred to as a “dye”).

In the present invention, the main absorption wavelength band of a dye is the main absorption wavelength band of the dye, which is measured in the state of being a light absorption filter. Specifically, in examples described later, it is measured in a state of being a base material-attached light absorption filter under the conditions described in the section of the absorbance of the light absorption filter.

In the dye layer, the “dye” is dispersed (preferably dissolved) in the resin to form a layer in which the dye layer exhibits a specific absorption spectrum derived from the dye. This dispersion may be any type of dispersion, such as a random type or a regular type.

In the light absorption filter according to the embodiment of the present invention, a compound that generates a radical upon ultraviolet irradiation is dispersed (preferably dissolved) in the resin, and thus the radical is generated in a case where ultraviolet irradiation is applied, the generated radical reacts with the dye, and the dye undergoes a chemical change, whereby the dye can be faded and decolorized. That is, the light absorption filter according to the embodiment of the present invention has such a characteristic that the dye is chemically changed to be decolorized upon ultraviolet irradiation.

In addition, in a case where the dye layer in the light absorption filter according to the embodiment of the present invention contains a compound A having an acid group as will be described later, as a compound that generates a radical upon ultraviolet irradiation, and a compound B having a structure that is capable of forming a hydrogen bond with the acid group contained in the compound A, the efficiency of generating radical species upon ultraviolet irradiation is improved as compared with a case where a commonly used photoradical generator such as a benzophenone compound is used. As a result, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized.

In addition, in the dye layer in the light absorption filter according to the embodiment of the present invention, in a case where the compound A having an acid group is bonded to a polymer that constitutes the resin, a radical is generated in the vicinity of the dye upon ultraviolet irradiation, and an effect that the radical easily reacts with the dye is exhibited.

Further, “the compound B having a structure that is capable of forming a hydrogen bond with the acid group contained in the compound A” described above is dispersed (preferably dissolved) in the resin by forming a hydrogen bond with the compound A or forms a hydrogen bond with the compound A in the resin in a case where the compound A containing the acid group is bonded to a polymer that constitutes the resin. In a case of being subjected to ultraviolet irradiation, the compound B generates a radical, and this radical easily reacts with a dye, which makes it possible for a dye to be efficiently faded and decolorized by a mechanism in which the generated radical reacts with a dye in the vicinity.

<Dye Having Main Absorption Wavelength Band in Wavelength Range of 400 to 700 nm>

Specific examples of the dye that is used in the present invention having a main absorption wavelength band in a wavelength range of 400 to 700 nm include tetraazaporphyrin (TAP)-based, squaraine (SQ)-based, cyanine (CY)-based, benzylidene-based, cinnamylidene-based, azo-based, and indoaniline-based coloring agents (dyes).

The dye that can be contained in the dye layer may be one kind or two or more kinds.

The dye layer can also contain a dye other than the above-described dye.

Among these, from the viewpoint that a secondary coloration structure associated with the decomposition of the dye is less likely to be generated, the dye layer preferably contains at least one of a squaraine-based coloring agent represented by General Formula (1), an azo-based coloring agent represented by any of General Formulae (i) to (iv), or an indoaniline-based coloring agent represented by General Formula (v) as the dye. In a case where a coloring agent that hardly generates the secondary coloration structure associated with the decomposition of the dye as described above is used as the dye, the portion irradiated with ultraviolet light can be efficiently made colorless.

Furthermore, from the viewpoint that the absorption waveform in the main absorption wavelength band is sharp, the above-described dye is preferably at least one of a squaraine-based coloring agent represented by General Formula (1), an azo-based coloring agent represented by any of General Formulae (i) to (iv), or an indoaniline-based coloring agent represented by General Formula (v). In a case where a coloring agent that has a sharp absorption waveform as described above is used as the dye, it is possible to minimize a decrease in the transmittance of the display light and prevent the reflection of external light.

That is, in a case where at least one of a squaraine-based coloring agent represented by General Formula (1), an azo-based coloring agent represented by any of General Formulae (i) to (iv), or an indoaniline-based coloring agent represented by General Formula (v) is used as the dye, the optical filter according to the embodiment of the present invention can be suitably produced by subjecting the light absorption filter according to the embodiment of the present invention to mask exposure under ultraviolet irradiation.

Furthermore, in the light absorption filter according to the embodiment of the present invention, it is more preferable that the light absorption filter contains at least one of an azo-based coloring agent represented by any of General Formulae (i) to (iv) described later or an indoaniline-based coloring agent represented by General Formula (v) described later as a dye having a main absorption wavelength band in a wavelength range of 400 to 700 nm. The azo-based coloring agent represented by General Formula (i) described later is a dye having a main absorption wavelength band in a wavelength range of approximately 400 to 500 nm, the azo-based coloring agent represented by any of General Formulae (ii) to (iv) described later is a dye having a main absorption wavelength band in a wavelength range of approximately 450 to 600 nm, and the indoaniline-based coloring agent represented by General Formula (v) described later is a dye having a main absorption wavelength band in a wavelength range of approximately 580 to 700 nm. In a form in which the light absorption filter according to the embodiment of the present invention has such a configuration, the light absorption filter can exhibit an excellent decolorizing property even in a case where ultraviolet irradiation is applied at room temperature (meaning 10° C. to 30° C.), which is a mild environment.

The reason for this is presumed as follows: the azo-based coloring agent represented by General Formula (i) described later exhibits excellent decolorizing properties since a hydroxy group on a pyridine ring bonded to an azo group (—N═N—) contributes to the generation of radical species, and thus an excellent decolorization rate is obtained even in a case where the ultraviolet irradiation is carried out under a mild temperature condition such as room temperature, and the azo-based coloring agent itself represented by General Formula (i) described later hardly causes secondary absorption associated with the decomposition of the dye. The azo-based coloring agent represented by any of General Formulae (ii) to (iv) described later has a structure in which an electron donating group (an amino group) is substituted at one terminal of a chromophore and an electron withdrawing group (a thiazole group or an isothiazole group) is substituted at the other terminal thereof. In general, the effect of stabilizing a radical by substituting both an electron donating group and an electron withdrawing group with respect to a radical center is known as a “captodative effect”, which is described, for example, on pages 148 to 154 of Acc. Chem. Res., vol. 18 (1985). It is considered that since the azo-based coloring agent represented by any of General Formulae (ii) to (iv) described later is also likely to generate a radical due to the “captodative effect” described above, an excellent decolorization rate is obtained in a case of being irradiated with ultraviolet rays. In addition, it is considered that since the indoaniline-based coloring agent represented by General Formula (v) described later also has a structure in which an electron donating group (an amino group) is substituted at one terminal of a chromophore and an electron withdrawing group (a carbonyl group) is substituted at the other terminal thereof, an excellent decolorization rate is obtained due to the “captodative effect” described above, even in a case where the ultraviolet irradiation is carried out under a mild temperature condition such as room temperature, and the azo-based coloring agent itself represented by any of General Formulae (ii) to (iv) described later and the indoaniline-based coloring agent itself represented by General Formula (v) described later hardly cause secondary absorption associated with the decomposition of the dye, excellent decolorizing properties are exhibited.

On the other hand, as the dye having a main absorption wavelength band in a wavelength range of approximately 400 to 500 nm among the dyes having a main absorption wavelength band in a wavelength range of 400 to 700 nm described in WO2021/132674A, a benzylidene-based coloring agent represented by General Formula (V) or a cinnamylidene-based coloring agent, which is described in WO2021/132674A, is described. However, in a case where a light absorption filter containing this coloring agent is subjected to ultraviolet irradiation at room temperature (which means 10° C. to 30° C.), which is a mild environment, the decolorization rate is as low as 84% as described in Comparative Example No. c202 in Reference Example β described later, and the decolorizing properties at room temperature are deteriorated. In a case where an azo-based coloring agent represented by General Formula (i) described later instead of the benzylidene-based coloring agent represented by General Formula (V) or the cinnamylidene-based coloring agent, which is described in WO2021/132674A, is contained, the light absorption filter according to the embodiment of the present invention has a main absorption wavelength band in a wavelength range of approximately 400 to 500 nm, and can exhibit excellent decolorizing properties even in a case of being subjected to ultraviolet irradiation at room temperature (which means 10° C. to 30° C.), which is a mild environment.

In addition, in a case where the azo-based coloring agent represented by any of General Formulae (ii) to (iv) described later or the indoaniline-based coloring agent represented by General Formula (v) described later is contained, the light absorption filter according to the embodiment of the present invention has a main absorption wavelength band in a wavelength range of approximately 450 to 700 nm and can exhibit excellent decolorizing properties equivalent to those of a light absorption filter containing the squaraine-based coloring agent represented by General Formula (1) described in WO2021/132674A, even in a case of being subjected to ultraviolet irradiation at room temperature (which means 10° C. to 30° C.), which is a mild environment.

In the present invention, in the coloring agents represented by each of General Formulae, a cation is present in a delocalized manner, and a plurality of tautomer structures are present. Therefore, in the present invention, in a case where at least one tautomer structure of a certain coloring agent matches with each of the General Formulae, a certain coloring agent is considered as the coloring agent represented by each of General Formulae. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

### (1) Squaraine-Based Coloring Agent Represented by General Formula (1)

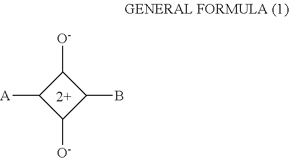

In General Formula (1), A and B each independently represent an aryl group which may have a substituent, a heterocyclic group which may have a substituent, or —CH=G, where G represents a heterocyclic group which may have a substituent.

With regard to definition and a preferred range of each substituent in General Formula (1), each of descriptions related to each substituent of coloring agents represented by General Formula (1) described in WO2021/132674A can be applied unless otherwise specified.

For the preferred embodiment of the coloring agent represented by General Formula (1), a coloring agent represented by any of General Formulae (2) to (5) described in [0045] to [0070] of WO2021/132674A and the description regarding the specific example can be applied as they are. However, the present invention is not limited thereto.

In addition, in addition to the above-described specific examples, specific examples of the coloring agent represented by any one of General Formulae (3) to (5) include the compounds described in [0071] to [0080] of WO2021/132674A. However, the present invention is not limited thereto.

In addition, for the one preferred embodiment of the coloring agent represented by General Formula (1), the description regarding the coloring agent represented by any of General Formulae (6) to (9) described in [0081] to [0095] of WO2021/132674A and the specific examples thereof can be applied as they are. However, the present invention is not limited thereto.

### (Quencher-Embedded Coloring Agent)

The squaraine-based coloring agent represented by General Formula (1) may be a quencher-embedded coloring agent in which a quencher moiety is linked to a coloring agent by a covalent bond through a linking group. The quencher-embedded coloring agent can also be preferably used as the above dye. That is, the quencher-embedded coloring agent is counted as the above dye according to the wavelength having the main absorption wavelength band.

Examples of the quencher-embedded coloring agent include an electron-donating quencher-embedded coloring agent in which the quencher moiety is an electron-donating quencher moiety, and an electron-accepting quencher moiety in which the quencher moiety is an electron-accepting quencher moiety.

The electron-donating quencher moiety means a structure portion that inactivates a coloring agent in the excited state to the ground state by donating an electron to a SOMO (singly occupied molecular orbital) at a low energy level of two SOMO's of the coloring agent in the excited state and then receiving an electron from a SOMO at a high energy level of the coloring agent. The electron-accepting quencher moiety means a structure portion that inactivates a coloring agent in the excited state to the ground state by accepting an electron from a SOMO at a high energy level of two SOMO's of the coloring agent in the excited state and then donating an electron to a SOMO at a low energy level of the coloring agent.

Examples of the electron-donating quencher moiety include a ferrocene group in the substituent X which may be contained in A, B, and G in General Formula (1) described in WO2021/132674A, and a quencher moiety in the quencher compound described in paragraphs [0199] to [0212] and paragraphs [0234] to [0287] of WO2019/066043A, where a ferrocene group in the substituent X which may be contained in A, B, and G in General Formula (1) described in WO2021/132674A is preferable. In addition, examples of the electron-accepting quencher moiety include the quencher moieties in the quencher compounds described in paragraphs [0288] to [0310] of WO2019/066043A.

In the light absorption filter according to the embodiment of the present invention, from the viewpoint of the light resistance of the light absorptive portion, the dye having a main absorption wavelength band in a wavelength range of 400 to 700 nm preferably includes an electron-donating quencher-embedded coloring agent, and more preferably includes a squarine-based coloring agent represented by General Formula (1A) described below.

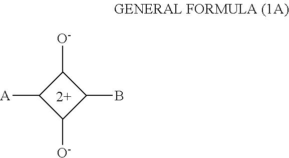

In the formula, A and B each independently represent an aryl group which may have a substituent, a heterocyclic group which may have a substituent, or —CH=G, where G represents a heterocyclic group which may have a substituent. However, at least one of A or B includes an electron-donating quencher moiety.

The coloring agent represented by General Formula (1A) is the same as the coloring agent represented by General Formula (1) described later, except that in the coloring agent represented by General Formula (1) described above, at least one of A or B includes an electron-donating quencher moiety. Therefore, for the description relating to A, B, and G in General Formula (1A), the description relating to A, B, and G in General Formula (1) described in WO2021/132674A can be applied. In addition, as a preferred embodiment of the coloring agent represented by General Formula (1A), a description in which, in the description of the coloring agent represented by any of General Formulae (2) to (9), which is a preferred embodiment of the coloring agent represented General Formula (1), at least one of the structures corresponding to A and B in General Formula (1) is changed to include an electron-donating quencher moiety can be applied.

The electron-donating quencher moiety contained in at least one of A or B is preferably a ferrocene group in the substituent X which may be contained in A, B, and G in General Formula (1) described in WO2021/132674A.

Among the squaraine-based coloring agents represented by General Formula (1), specific examples of the coloring agent corresponding to the quencher-embedded coloring agent include the compounds described in [0097] to [0114] of WO2021/132674A. However, the present invention is not limited thereto.

### (2-1) an Azo-Based Coloring Agent Represented by General Formula (i).

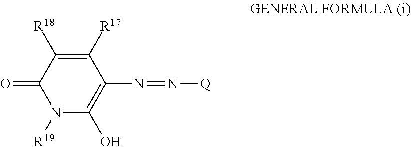

In the formula, R¹⁷ and R¹⁸ each independently represent a hydrogen atom or a monovalent substituent.

R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group.

Q represents a diazo component residue.

However, R¹⁷ to R¹⁹ and Q do not have a squaraine structure.

The above-described squaraine structure means a structure of a squaraine-based coloring agent. The squaraine-based coloring agent is a coloring agent having a structure that has a skeleton derived from squaric acid in a central part of a x-conjugated system. Examples thereof include a squaraine-based coloring agent represented by General Formula (1) described above.

Examples of the monovalent substituent that can be adopted as R¹⁷ and R¹⁸ include a halogen atom, an aliphatic group, an aryl group, a heterocyclic group, a cyano group, a carboxy group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an amino group (—NH₂), an aliphatic amino group, an arylamino group, a heterocyclic amino group, an acylamino group, a carbamoylamino group, sulfamoylamino group, an aliphatic oxycarbonylamino group, an aryloxycarbonylamino group, an aliphatic sulfonylamino group, an arylsulfonylamino group, a nitro group, an aliphatic thio group, an arylthio group, an aliphatic sulfonyl group, an arylsulfonyl group, a sulfamoyl group, a sulfo group, an imide group, and a heterocyclic thio group. Among these, an aliphatic group, an aryl group, a heterocyclic group, a cyano group, a carbamoyl group, an aliphatic oxycarbonyl group, an aryloxycarbonyl group, an acyl group, an aliphatic oxy group, an aryloxy group, an aliphatic amino group, or an arylamino group is preferable mainly from the viewpoint of imparting solubility.

The substituents that can be adopted as R¹⁷ and R¹⁸ may be further substituted.

The aliphatic group that can be adopted as R¹⁷ to R¹⁹ may further have a monovalent substituent, may be saturated or unsaturated, and may be cyclic. Specific examples thereof include an alkyl group, a substituted alkyl group, an alkenyl group, a substituted alkenyl group, an alkynyl group, a substituted alkynyl group, an aralkyl group, and a substituted aralkyl group. The total number of carbon atoms in the aliphatic group is preferably 1 to 30 and more preferably 1 to 16. Specific examples of the aliphatic group include a methyl group, an ethyl group, a butyl group, an isopropyl group, a t-butyl group, a hydroxyethyl group, a methoxyethyl group, a cyanoethyl group, a trifluoromethyl group, a 3-sulfopropyl group, a 4-sulfobutyl group, a 2-(2-hydroxyethoxy)ethyl group, a 2-(2-(acetyloxy)ethoxy)ethyl group, a cyclohexyl group, a benzyl group, a 2-phenethyl group, a vinyl group, and an allyl group.

It is noted that Examples of the monovalent substituent which may be contained include the monovalent substituents that can be adopted as R¹⁷ and R¹⁸, and the same applies to the following description regarding the monovalent substituent which may be contained. The monovalent substituent which may be contained is, for example, preferably an alkoxy group, an acyloxy group, or a hydroxy group. In addition, this substituent may further have a substituent, and preferred examples thereof include an alkoxy group, an acyloxy group, and a hydroxy group.

The aryl group that can be adopted as R¹⁷ to R¹⁹ may further have a monovalent substituent, and the aryl group is preferably an aryl group having a total number of carbon atoms of 6 to 30, and more preferably an aryl group having a total number of carbon atoms of 6 to 16. Specific examples thereof include a phenyl group, a 4-tolyl group, a 4-methoxyphenyl group, a 2-chlorophenyl group, a 3-(3-sulfopropylamino)phenyl group, a 4-sulfamoylphenyl group, a 4-(ethoxyethylsulfamoyl)phenyl group, and a 3-(dimethylcarbamoyl)phenyl group.

The heterocyclic group that can be adopted as R¹⁷ to R¹⁹ may be a saturated or unsaturated aliphatic ring group or may be an aromatic ring group, and it is preferably an aromatic heterocyclic group. Examples of the ring-constituting atom constituting the heterocyclic group include those containing at least any one of a heteroatom such as a nitrogen atom, a sulfur atom, or an oxygen atom, where the heterocyclic group may further have a monovalent substituent. The heterocyclic group is preferably a heterocyclic group having a total number of carbon atoms of 1 to 30, and more preferably a heterocyclic group having a total number of carbon atoms of 1 to 15. Specific examples thereof include a 2-pyridyl group, a 2-thienyl group, a 2-thiazolyl group, a 2-benzothiazolyl group, a 2-benzoxazolyl group, and a 2-furyl group.

The carbamoyl group that can be adopted as R¹⁷ to R¹⁹ includes, in addition to an unsubstituted carbamoyl group (—CONH₂), a carbamoyl group substituted with an aliphatic group, an aryl group, or the like.

The carbamoyl group that can be adopted as R¹⁷ to R¹⁹ may further have a monovalent substituent, and the carbamoyl group is preferably a carbamoyl group having a total number of carbon atoms of 1 to 30, and more preferably a carbamoyl group having 1 to 16 carbon atoms. Specific examples thereof include a methylcarbamoyl group, a dimethylcarbamoyl group, a phenylcarbamoyl group, and a N-methyl-N-phenylcarbamoyl group.

To the aliphatic group in the aliphatic oxycarbonyl group that can be adopted as R¹⁷ and R¹⁸, the description of the aliphatic group that can be adopted as R¹⁷ to R¹⁹ can be applied.

The aliphatic oxycarbonyl group that can be adopted as R¹⁷ and R¹⁸ may further have a monovalent substituent, may be saturated or unsaturated, or may be cyclic, and the aliphatic oxycarbonyl group is preferably an aliphatic oxycarbonyl group having a total number of carbon atoms of 2 to 30, and more preferably an aliphatic oxycarbonyl group having a total number of carbon atoms of 2 to 16. Specific examples thereof include a methoxycarbonyl group, an ethoxycarbonyl group, and a 2-methoxyethoxycarbonyl group.

The alkoxycarbonyl group that can be adopted as R¹⁹ may further have a monovalent substituent, may be saturated or unsaturated, or may be cyclic, and the alkoxycarbonyl group is preferably an alkoxycarbonyl group having a total number of carbon atoms of 2 to 30 and more preferably an alkoxycarbonyl group having a total number of carbon atoms of 2 to 16. Specific examples thereof include a methoxycarbonyl group, an ethoxycarbonyl group, and a 2-methoxyethoxycarbonyl group.

The aryloxycarbonyl group that can be adopted as R¹⁷ to R¹⁹ may further have a monovalent substituent, and it is preferably an aryloxycarbonyl group having a total number of carbon atoms of 7 to 30 and more preferably an aryloxycarbonyl group having the number of carbon atoms of 7 to 16. Specific examples thereof include a phenoxycarbonyl group, a 4-methylphenoxycarbonyl group, and a 3-chlorophenoxycarbonyl group.

The acyl group that can be adopted as R¹⁷ to R¹⁹ includes an aliphatic carbonyl group, an arylcarbonyl group, and a heterocyclic carbonyl group, where an aspect in which the total number of carbon atoms is 1 to 30 is preferable, and an aspect in which the total number of carbon atoms is 1 to 16 is more preferable. Specific examples thereof include an acetyl group, a methoxyacetyl group, a thienoyl group, and a benzoyl group.

To the aliphatic group in the aliphatic sulfonyl group that can be adopted as R¹⁷ and R¹⁸ the description of the aliphatic group that can be adopted as R¹⁷ to R¹⁹ can be applied.

The aliphatic sulfonyl group that can be adopted as R¹⁷ and R¹⁸ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The alkylsulfonyl group that can be adopted as R¹⁹ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The arylsulfonyl group that can be adopted as R¹⁷ to R¹⁹ may further have a monovalent substituent, where an aspect in which the total number of carbon atoms is 6 to 30 is preferable, and an aspect in which the total number of carbon atoms is 6 to 18 is more preferable. Specific examples thereof include a benzenesulfonyl group and a toluenesulfonyl group.

The sulfamoyl group that can be adopted as R¹⁷ to R¹⁹ includes, in addition to an unsubstituted sulfamoyl group (—SO₂NH₂), a carbamoyl group substituted with an aliphatic group, an aryl group, or the like.

The sulfamoyl group that can be adopted as R¹⁷ to R¹⁹ may further have a monovalent substituent, where an aspect in which the total number of carbon atoms is 0 to 30 is preferable, and an aspect in which the total number of carbon atoms is 0 to 16 is more preferable. Specific examples thereof include an unsubstituted sulfamoyl group, a dimethylsulfamoyl group, and a di-(2-hydroxyethyl) sulfamoyl group.

The imide group that can be adopted as R¹⁷ and R¹⁸ may further have a monovalent substituent, and it is preferably an imide group of a 5- or 6-membered ring. In addition, an aspect in which the total number of carbon atoms in the imide group is 4 to 30 is preferable, and an aspect in which the total number of carbon atoms in the imide group is 4 to 20 is more preferable. Specific examples thereof include a succinimide group and a phthalimide group.

To the aliphatic group in the aliphatic oxy group, the aliphatic amino group, the aliphatic oxycarbonylamino group, the aliphatic sulfonylamino group, and the aliphatic thio group, which can be adopted as R¹⁷ and R¹⁸, the description of the aliphatic group that can be adopted as R¹⁷ to R¹⁹ can be applied.

To the aryl group in the aryloxy group, the arylamino group, the aryloxycarbonylamino group, the arylsulfonylamino group, and the arylthio group, which can be adopted as R¹⁷ and R¹⁸, the description of the aryl group that can be adopted as R¹⁷ to R¹⁹ can be applied.

To the acyl group in the acyloxy group and the acylamino group, which can be adopted as R¹⁷ and R¹⁸, the description of the acyl group, which can be adopted as R¹⁷ to R¹⁹, can be applied.

To the carbamoyl group in the carbamoyloxy group and the carbamoylamino group, which can be adopted as R¹⁷ and R¹⁸, the description of the carbamoyl group, which can be adopted as R¹⁷ to R¹⁹, can be applied.

To the heterocyclic group in the heterocyclic oxy group, the heterocyclic amino group, and the heterocyclic thio group, which can be adopted as R¹⁷ and R¹⁸, the description of the heterocyclic group, which can be adopted as R¹⁷ to R¹⁹, can be applied.

To the sulfamoyl group in the sulfamoylamino group that can be adopted as R¹⁷ and R¹⁸, the description of the sulfamoyl group, which can be adopted as R¹⁷ to R¹⁹, can be applied.

The diazo component residue represented by Q means a residue of a diazo component “Q-NH₂”. In particular, from the viewpoint of the color reproducibility to be targeted, Q is preferably an aryl group or an aromatic heterocyclic group.

The aromatic hydrocarbon ring constituting the aryl group that can be adopted as Q may be a monocyclic ring or a fused ring, and it is preferably a monocyclic ring. It is preferably an aryl group having a total number of carbon atoms of 6 to 30, and more preferably an aryl group having a total number of carbon atoms of 6 to 16. Specifically, a phenyl group is preferable. The aryl group that can be adopted as Q may have a substituent, and preferred examples of the substituent that may be contained include a sulfamoyl group (preferably an alkylsulfamoyl group or a dialkylsulfamoyl group), a sulfonyl group (preferably an alkylsulfonyl group), and a cyano group.

The aromatic heterocyclic group that can be adopted as Q is an aromatic ring group containing, as a ring-constituting atom constituting a heterocyclic group, at least any one among heteroatoms such as a nitrogen atom, a sulfur atom, and an oxygen atom, where the aromatic heterocyclic group is preferably composed of a 5- or 6-membered ring. The number of carbon atoms in the aromatic heterocyclic group is preferably 1 to 25 and more preferably 1 to 15. The aromatic heterocyclic ring constituting the aromatic heterocyclic group may be a monocyclic ring or a fused ring, and it is preferably a monocyclic ring.

Specific examples of the aromatic heterocyclic group include a pyrazole group, a 1,2,4-triazole group, an isothiazole group, a benzisothiazole group, a thiazole group, a benzothiazole group, an oxazole group, and a 1,2,4-thiadiazole group.

Examples of the azo-based coloring agent represented by General Formula (i) include the following exemplary compounds (B-12) to (B-16), (B-18), and (B-19). However, the present invention is not limited thereto.

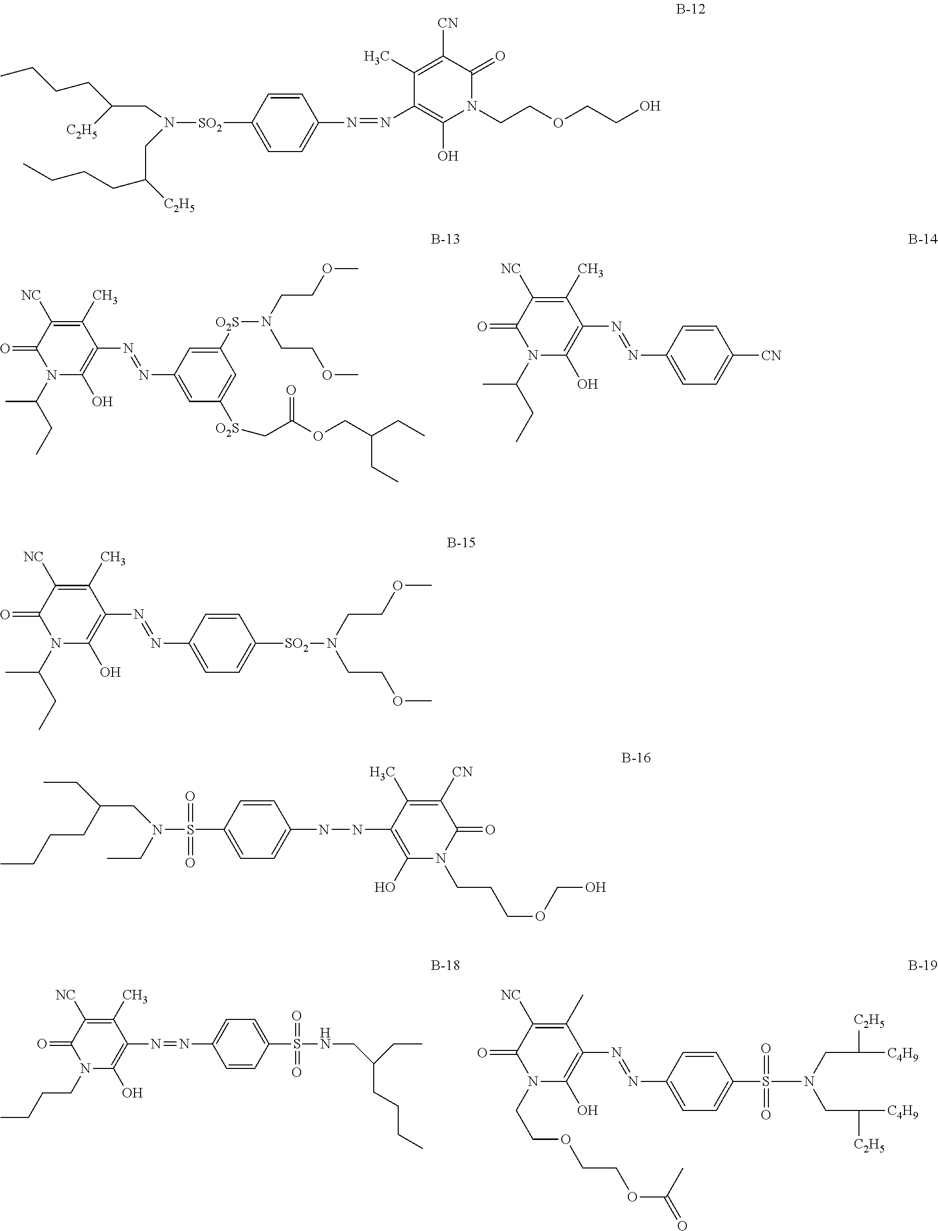

### (2-2) an Azo-Based Coloring Agent Represented by General Formula (ii).

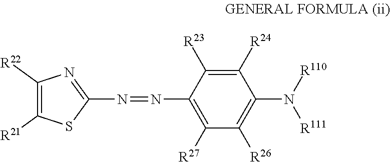

In the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group.

R¹⁰⁸ to R¹²¹ represent a hydrogen atom, an acyclic hydrocarbon group, a monocyclic hydrocarbon group, a fused polycyclic hydrocarbon group, or a heterocyclic group. n is a positive integer.

It is noted that the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group.

The acyclic hydrocarbon group that can be adopted as R²¹ to R²⁴, R²⁶, R²⁷, and R¹⁰⁸ to R¹²¹ means an acyclic alkyl group in which one hydrogen atom is removed from an acyclic alkane. However, the acyclic alkyl group may have a ring structure as a substituent. The number of carbon atoms in the acyclic alkyl group is preferably 1 to 30, more preferably 1 to 20, still more preferably 1 to 12, particularly preferably 1 to 8, and among these, it is preferably 1 to 6.

The monocyclic hydrocarbon group that can be adopted as R²¹ to R²⁴, R²⁶, R²⁷, and R¹⁰⁸ to R¹²¹ means a monocyclic cycloalkyl group, a monocyclic cycloalkenyl group, a monocyclic cycloalkynyl group, or a monocyclic aryl group, which is a group in which one hydrogen atom is removed from a monocyclic aliphatic hydrocarbon ring (which may be any of a monocyclic cycloalkane, a monocyclic cycloalkene, or a monocyclic cycloalkyne) or a monocyclic aromatic hydrocarbon ring.

The number of carbon atoms in the monocyclic cycloalkyl group, the monocyclic cycloalkenyl group, and the monocyclic cycloalkynyl group is not particularly limited as long as it is allowed in terms of the structure; however, it is more preferably 3 to 30, more preferably 3 to 20, and still more preferably 3 to 16. The number of carbon atoms in the monocyclic aryl group is more preferably 6 to 30, still more preferably 6 to 20, and even still more preferably 6 to 16.

The fused polycyclic hydrocarbon group that can be adopted as R²¹ to R²⁴, R²⁶, R²⁷, and R¹⁰⁸ to R¹²¹ means a fused polycyclic cycloalkyl group, a fused polycyclic cycloalkenyl group, a fused polycyclic cycloalkynyl group, or a fused polycyclic aryl group, which is a group in which one hydrogen atom is removed from a fused polycyclic aliphatic hydrocarbon ring (which may be any of a fused polycyclic cycloalkane, a fused polycyclic cycloalkene, or a fused polycyclic cycloalkyne) or a fused polycyclic aromatic hydrocarbon ring.

The number of carbon atoms in the fused polycyclic cycloalkyl group, the fused polycyclic cycloalkenyl group, and the fused polycyclic cycloalkynyl group is not particularly limited as long as it is allowed in terms of the structure; however, it is more preferably 8 to 30 and more preferably 8 to 20. The number of carbon atoms in the fused polycyclic aryl group is more preferably 12 to 30 and still more preferably 12 to 20.

To the heterocyclic group that can be adopted as R²¹ to R²⁴, R²⁶, R²⁷, and R¹⁰⁸ to R¹²¹, the description of the heterocyclic group that can be adopted as R¹⁷ to R¹⁹ in General Formula (i) can be applied.

n is preferably an integer of 1 to 12, more preferably an integer of 1 to 6, and still more preferably an integer of 1 to 3.

Regarding the specific group of each of the substituents in General Formula (ii), unless otherwise specified, the descriptions regarding R¹ to R⁴, R⁶, R⁷, and R⁸ to R²¹ for the compound represented by General Formula [1] described in JP1993-257180A (JP-H5-257180A) can be applied as they are to R²¹ to R²⁴, R²⁶, R²⁷, and R¹⁰⁸ to R¹²¹, respectively.

R²¹ is preferably a cyano group, a nitro group, —OR¹⁰⁸, an acyclic hydrocarbon group (preferably an acyclic alkyl group or an acyclic alkenyl group), or a heterocyclic group, more preferably a cyano group or a nitro group, or an acyclic alkyl group (preferably an alkyl group substituted with a fluorine atom) substituted with a halogen atom, and still more preferably a cyano group.

R²² is preferably a hydrogen atom, a cyano group, an acyclic hydrocarbon group (preferably an acyclic alkyl group), or a monocyclic hydrocarbon group, more preferably a hydrogen atom, an alkyl group, or an aryl group, and still more preferably an alkyl group or an aryl group.

It is noted that at least one of R²¹ or R²² is preferably a cyano group or a nitro group, or an acyclic alkyl group substituted with a halogen atom, a cyano group, or a nitro group.

R²³ is preferably a hydrogen atom, —OR¹⁰⁸, —SR¹⁰⁹, —NR¹¹⁰R¹¹¹, —C(═O)NR¹¹⁴R¹¹⁵, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, —SR¹⁰⁹, —NR¹¹⁰R¹¹¹, —NHC(═O)R¹¹⁶, or an acyclic alkyl group, and still more preferably —NHC(═O)R¹¹⁶. Here, R¹⁰⁸ to R¹¹¹, R¹¹⁶, and R¹¹⁸ to R¹²¹ are preferably an acyclic alkyl group.

R²⁴ and R²⁷ are preferably a hydrogen atom.

R²⁶ is preferably a hydrogen atom, —OR¹⁰⁸, —SR¹⁰⁹, —NR¹¹⁰R¹¹¹, —NHC(═O)R¹¹⁶, —O(CH₂CH₂O)NR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, or —SR¹⁰⁹, and still more preferably a hydrogen atom. Here, R¹⁰⁸ to R¹¹¹, R¹¹⁶, and R¹¹⁸ to R¹²¹ are preferably an acyclic alkyl group.

In —NR¹¹⁰R¹¹¹ that is located at the ortho position with respect to R²⁴ and R²⁶, R¹¹⁰ is preferably an acyclic alkyl group, and R¹¹¹ is preferably an acyclic alkyl group and more preferably an unsubstituted acyclic alkyl group or an acyclic alkyl group having-OR¹⁰⁸, a monocyclic hydrocarbon group, or a fused polycyclic hydrocarbon group as a substituent. Here, R¹⁰⁸ is preferably a hydrogen atom or an acyclic alkyl group.

Specific examples of the coloring agent represented by General Formula (ii) include, in addition to the compounds that are used in Examples described later, the compounds described in paragraphs [0023] to [0034] of JP1993-257180A (JP-H5-257180A), and the compounds described in paragraphs [0050] and [0052], the compound D-18 described in paragraph [0055], and the compound described in paragraph [0056] of JP2013-129712A. However, the present invention is not limited thereto.

(2-3) an Azo-Based Coloring Agent Represented by General Formula (iii).

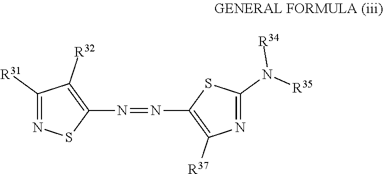

In the formula, R³¹ represents a hydrogen atom, an alkyl group, an alkoxy group, a cyano group, a carbonyl group (an alkyloxycarbonyl group or an aryloxycarbonyl group is preferable), an aromatic group, or a heterocyclic group.

R³² represents a hydrogen atom, an alkyl group, an alkoxy group, a cyano group, a nitro group, a carbonyl group (an alkyloxycarbonyl group or an aryloxycarbonyl group is preferable), an aromatic group, or a heterocyclic group.

R³⁴ and R³⁵ each independently represent a hydrogen atom, an alkyl group, or an aromatic group.

R³⁷ represents a hydrogen atom, an alkyl group, an alkoxy group, a cyano group, a carbonyl group (an alkyloxycarbonyl group or an aryloxycarbonyl group is preferable), an acylamino group, or an aromatic group.

R³⁴ and R³⁵ may be bonded to each other to form a ring.

Regarding the definition and the preferred range of each of the substituents in General Formula (iii), unless otherwise specified, the descriptions regarding R¹ and R² regarding General Formula (1) described in JP2013-129712A can be applied as they are to R³¹ and R³², respectively, and the description regarding R⁴, R⁵, and R⁷ regarding General Formula (3) described in JP2013-129712A can be applied as it is to R³⁴, R³⁵, and R³⁷, respectively.

It is noted that, in the present invention, R³⁷ can adopt the following acylamino group in addition to the hydrogen atom, the alkyl group, the alkoxy group, the cyano group, the carbonyl group, and the aromatic group, which can be adopted by R⁷ regarding General Formula (3) described in JP2013-129712A.

The number of carbon atoms in the acylamino group that can be adopted as R³⁷ is preferably 1 to 12 and more preferably 1 to 6.

In the present invention, the number of carbon atoms in the alkyl group that can be adopted as R³¹, R³², and R³⁷ is more preferably 1 to 20, still more preferably 1 to 12, and particularly preferably 1 to 6.

The number of carbon atoms in the alkoxy group that can be adopted as R³¹, R³², and R³⁷ is more preferably 1 to 20, still more preferably 1 to 12, and particularly preferably 1 to 6.

The number of carbon atoms in the alkyloxycarbonyl group that can be adopted as R³¹, R³², and R³⁷ is preferably 2 to 30, more preferably 2 to 20, still more preferably 2 to 12, and particularly preferably 2 to 7.

The number of carbon atoms in the alkyl group that can be adopted as R³⁴ and R³⁵ is preferably 1 to 30, more preferably 1 to 20, and still more preferably 1 to 12.

R³¹ is preferably an alkyl group or an aryl group, and more preferably an alkyl group.

R³² is preferably an alkyl group or a cyano group, and more preferably a cyano group.

R³⁴ and R³⁵ are preferably a hydrogen atom or an alkyl group, and more preferably an alkyl group.

R³⁷ is preferably a hydrogen atom, an alkyl group, an acylamino group, or an aromatic group, more preferably a hydrogen atom or an alkyl group, and still more preferably an alkyl group.

Specific examples of the coloring agent represented by General Formula (iii) include the following compounds. However, the present invention is not limited thereto.

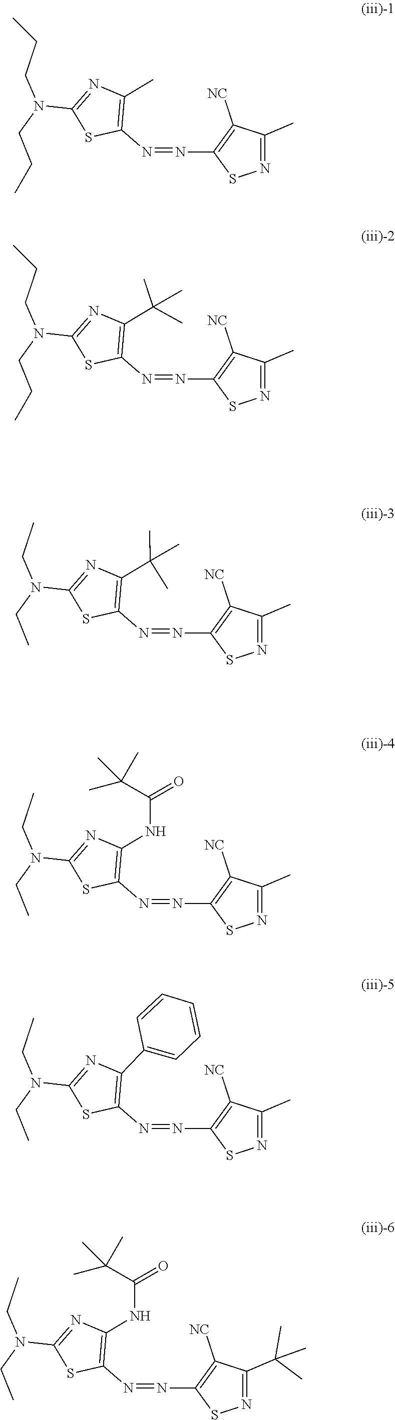

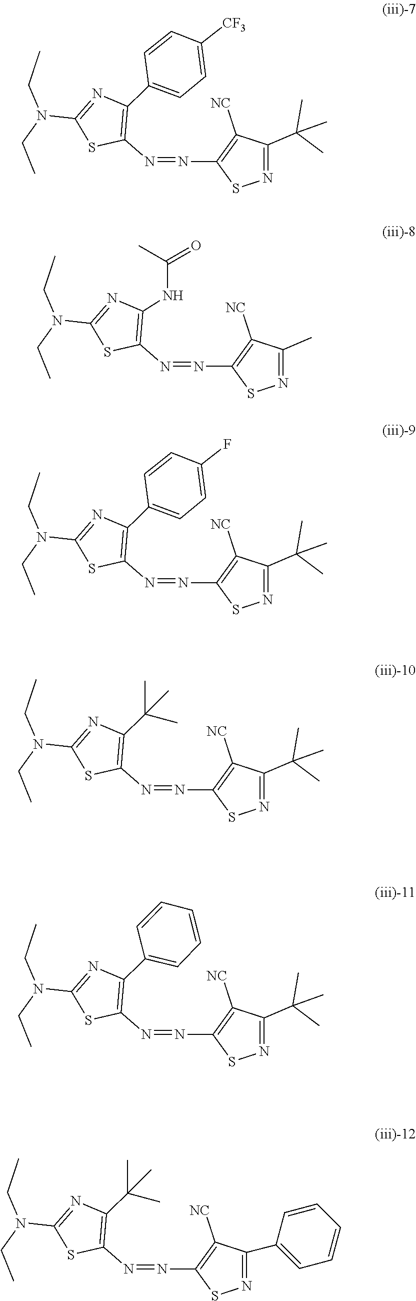

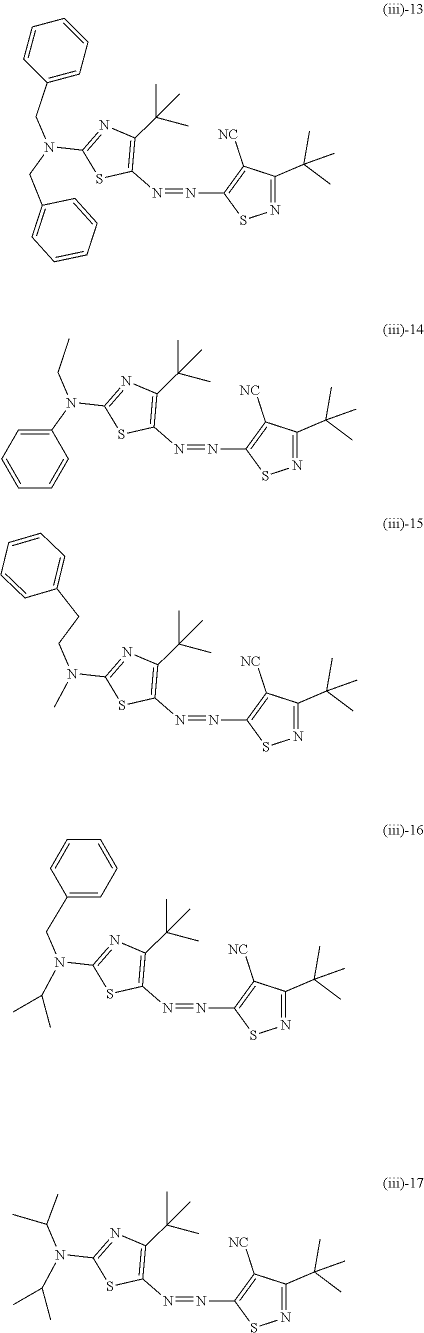

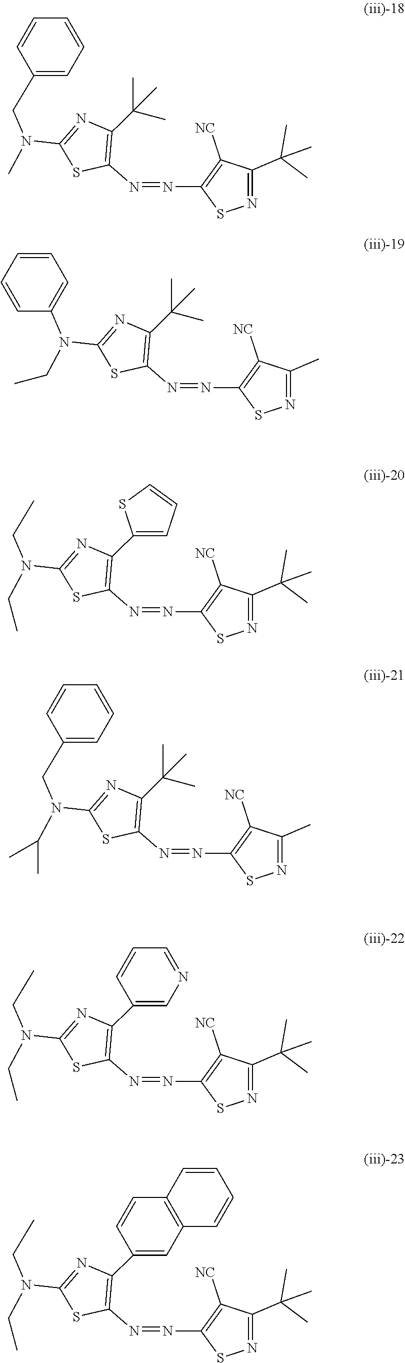

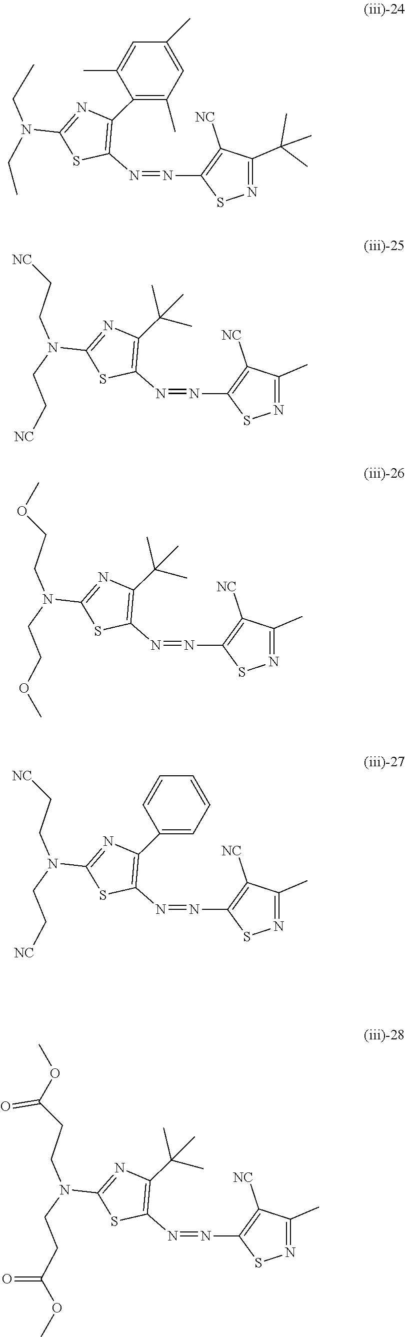

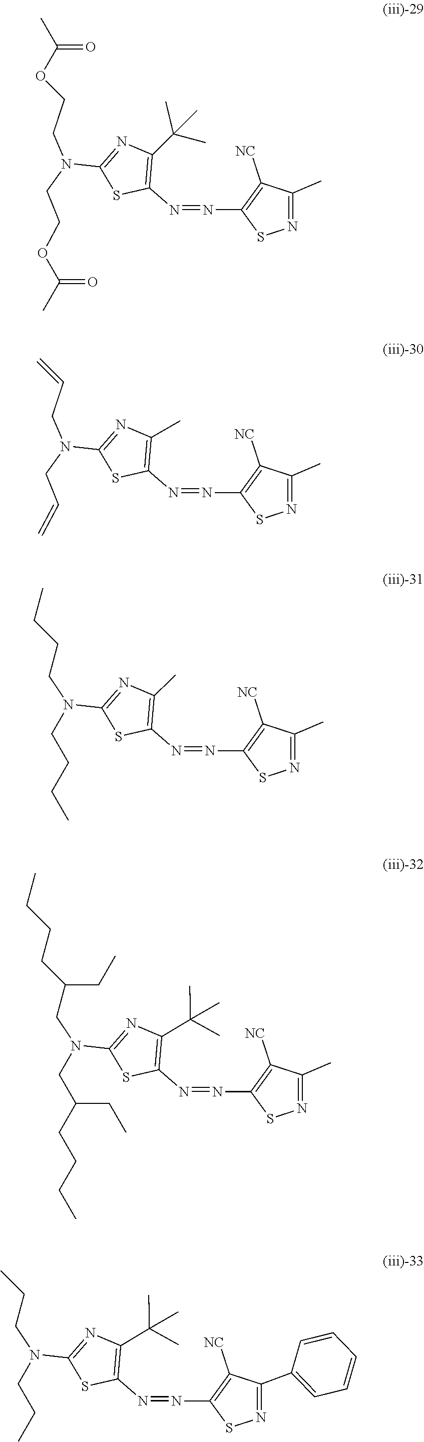

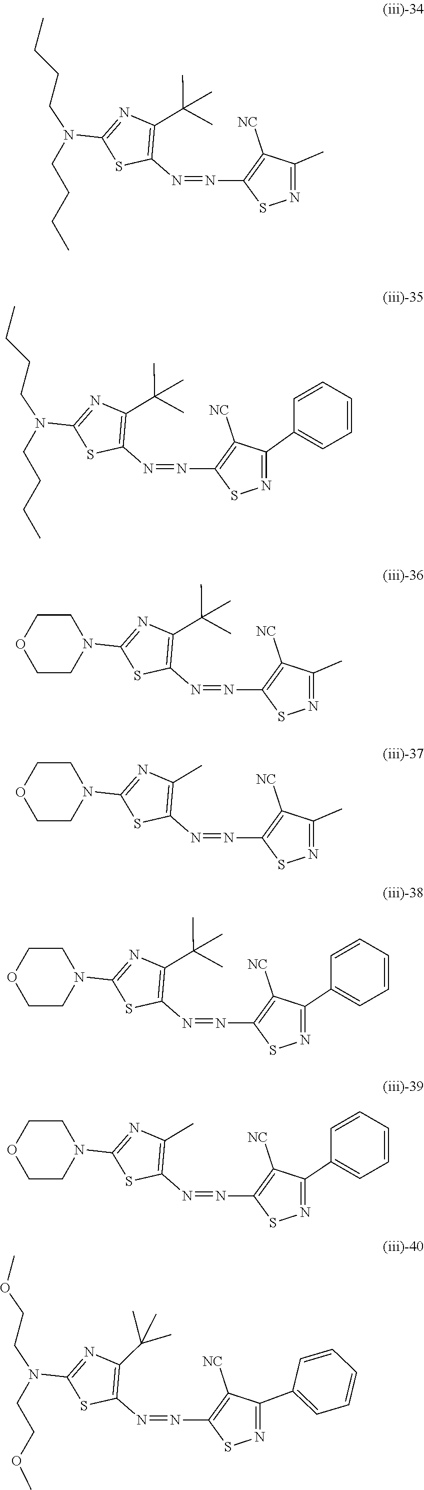

### (2-4) an Azo-Based Coloring Agent Represented by General Formula (iv).

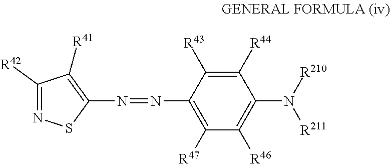

In the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹—S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group.

R²⁰⁸ to R²²¹ represent a hydrogen atom, an acyclic hydrocarbon group, a monocyclic hydrocarbon group, a fused polycyclic hydrocarbon group, or a heterocyclic group. n is a positive integer.

The acyclic hydrocarbon group, the monocyclic hydrocarbon group, the fused polycyclic hydrocarbon group, and the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, and —S(CH₂CH₂S)ₙR²²¹.

The descriptions of R²¹ to R²⁴, R²⁶, R²⁷, R¹⁰⁸ to R¹²¹, and n in General Formula (ii) can be applied as they are to R⁴¹ to R⁴⁴, R⁴⁶, R⁴⁷, R²⁰⁸ to R²²¹, and n in General Formula (iv), respectively, unless otherwise specified.

R⁴³ is preferably a hydrogen atom, —OR²⁰⁸, —SR²⁰⁹, —NR²¹⁰R²¹¹, —NHC(═O)R²¹⁶, O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, or an acyclic hydrocarbon group (preferably an acyclic alkyl group), more preferably a hydrogen atom, —OR²⁰⁸—SR²⁰⁹, —NR²¹⁰R²¹¹, —NHC(═O)R²¹⁶, or an acyclic alkyl group, and still more preferably —NHC(═O)R²¹⁶ or an acyclic alkyl group. Here, R²⁰⁸ to R²¹¹, R²¹⁶, and R²¹⁸ to R²²¹ are preferably an acyclic alkyl group.

In —NR²¹⁰R²¹¹ that is located at the ortho position with respect to R⁴⁴ and R⁴⁶, R²¹⁰ is preferably an acyclic alkyl group, and R²¹¹ is preferably an acyclic alkyl group and more preferably an unsubstituted acyclic alkyl group (including an acyclic alkyl group substituted with an acyclic alkyl group) or an acyclic alkyl group having —OR²⁰⁸, a monocyclic hydrocarbon group, or a fused polycyclic hydrocarbon group as a substituent. Here, R²⁰⁸ is preferably a hydrogen atom or an acyclic alkyl group.

It is noted that R⁴⁴ and/or R⁴⁶ in General Formula (iv) may be bonded to R²¹⁰ and/or R²¹¹ in —NR²¹⁰R²¹¹ located at the ortho position with respect to R⁴⁴ and R⁴⁶ on the benzene ring, thereby forming a ring. The ring which may be formed is preferably a 5- or 6-membered ring and may be saturated or unsaturated, and it is preferably a saturated 6-membered ring. The ring which may be formed may further have a substituent, and for example, it preferably has an alkyl group.

Among these, regarding a form in which a ring is formed, it is preferable that R⁴⁶ and R²¹¹ in-NR²¹⁰R²¹¹ that is located at the ortho position with respect to R⁴⁴ and R⁴⁶ on the benzene ring are bonded to each other to form a saturated 6-membered ring.

Specific examples of the coloring agent represented by General Formula (iv) include, in addition to the compounds that are used in Examples described later, the compounds described in paragraph [0053] of JP2013-129712A. However, the present invention is not limited thereto.

### (2-5) an Indoaniline-Based Coloring Agent Represented by General Formula (v).

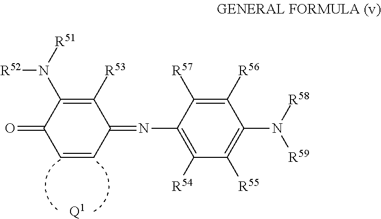

In the formula, Q¹ represents an atomic group that contains at least one nitrogen atom and is necessary for forming a 5- to 7-membered nitrogen-containing heterocyclic ring together with carbon atoms to be bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵⁸ and R⁵⁹ represent a hydrogen atom, an alkyl group, or an aryl group.

R⁵¹ and R⁵³, R⁵⁴ and R⁵⁵, and/or R⁵⁵ and R⁵⁹, or R⁵⁸ and R⁵⁹ each may be bonded to each other to form a ring. That is, it means that R⁵¹ and R⁵³ may be bonded to each other to form a ring, R⁵⁴ and R⁵⁵ and/or R⁵⁵ and R⁵⁹ may be bonded to each other to form a ring, or R⁵⁸ and R⁵⁹ may be bonded to each other to form a ring.

Regarding the definition and the preferred range of each of the substituents in General Formula (v), unless otherwise specified, the descriptions regarding R¹ to R⁶, R⁸, R⁹, and Q¹ in General Formula (I) described in JP1990-92686A (JP-H2-92686A) can be applied as they are to R⁵¹ to R⁵⁶, R⁵⁸, R⁵⁹, and Q¹, respectively.

It is noted that in the present invention, R⁵³ to R⁵⁶ can adopt the following acylamino group and alkylsulfonylamino group, in addition to the hydrogen atom, the alkyl group, the alkoxy group, and the halogen atom, which can be adopted by R³ to R⁶ regarding General Formula (I) described in JP1990-92686A (JP-H02-92686A).

The number of carbon atoms in the acylamino group that can be adopted as R⁵³ to R⁵⁷ is preferably 1 to 12 and more preferably 1 to 6.

The number of carbon atoms in the alkylsulfonylamino group that can be adopted as R⁵³ to R⁵⁷ is preferably 1 to 12 and more preferably 1 to 6.

To the alkyl group, the alkoxy group, and the halogen atom, which can be adopted as R⁵⁷, the descriptions of the alkyl group, the alkoxy group, and the halogen atom, which can be adopted as R⁵³ to R⁵⁶, can be applied as they are.

Q¹ is preferably represented by —NR¹⁶C(═O)-Q²-. Q² represents an atomic group required for forming a 5- to 7-membered nitrogen-containing heterocyclic ring together with a carbon atom to which —NR¹⁶C(═O)-Q²- is bonded and —NR¹⁶C(═O)—, and examples thereof include a divalent amino group, an ether bond, a thioether bond, an alkylene bond, an ethylene bond, an imino bond, a sulfonyl bond, a carbonyl bond, an arylene bond or a divalent heterocyclic group, and a group obtained by combining a plurality of these. R¹⁶ represents a hydrogen atom, an alkyl group, an aryl group, or a heterocyclic group, where a hydrogen atom is preferable. To each of the definition and the preferred range of each substituent of R¹⁶, the description regarding R¹⁶ regarding General Formula (I) described in JP1990-92686A (JP-H2-92686A) can be applied as it is.

R⁵¹ is preferably an acyl group having 2 to 7 carbon atoms or an alkoxycarbonyl group having 2 to 7 carbon atoms.

R⁵² is preferably a hydrogen atom, and R⁵³ to R⁵⁶ are preferably a hydrogen atom.

R⁵⁷ is preferably an alkoxy group, an acylamino group, or an alkylsulfonylamino group, and more preferably an alkoxy group or an acylamino group.

R⁵⁸ and R⁵⁹ are preferably an alkyl group having 1 to 6 carbon atoms.

Among the above, the indoaniline-based coloring agent represented by General Formula (v) is preferably represented by General Formula (v-a).

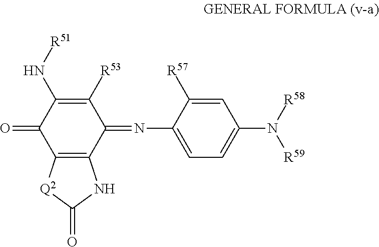

In the formula, R⁵¹, R⁵³, R⁵⁷ to R⁵⁹, and Q² have the same meanings as R⁵¹, R⁵³, R⁵⁷ to R⁵⁹, and Q² in General Formula (v).

Q² is preferably —CR¹¹R¹²CR¹³R¹⁴—, —CR¹¹R¹²—, or —NR¹¹—, and more preferably —CR¹¹R¹²CR¹³R¹⁴—.

R¹¹ to R¹⁴ represent a hydrogen atom or an alkyl group having 1 to 4 carbon atoms, and it is preferable that R¹¹ and R¹² are a hydrogen atom and R¹³ and R¹⁴ are an alkyl group having 1 to 4 carbon atoms.

It is noted that-CR¹¹R¹²CR¹³R¹⁴— is preferably bonded to >C═O on the side of the carbon atom to which R¹¹ and R¹² are bonded.

Specific examples of the coloring agent represented by General Formula (v) include, in addition to the compounds that are used in Examples described later, the compounds of Nos. 1 to 51 on pages 5 and 6 of JP1990-92686A (JP-H2-92686A). However, the present invention is not limited thereto.

The total content of the dyes in 100 parts by mass of the dye layer is preferably 0.10 parts by mass or more, more preferably 0.15 parts by mass or more, still more preferably 0.20 parts by mass or more, particularly preferably 0.25 parts by mass or more, and especially preferably 0.30 parts by mass or more. In a case where the total content of the dyes in the dye layer is equal to or higher than the above-described preferred lower limit value, good light absorption properties such as an antireflection effect can be obtained.

In addition, the total content of the dyes in 100 parts by mass of the dye layer is usually 50 parts by mass or less, preferably 40 parts by mass or less, more preferably 30 parts by mass or less, still more preferably 15 parts by mass or less, and particularly preferably 10 parts by mass or less.

That is, the total content of the dye in 100 parts by mass of the dye layer is preferably 0.10 to 50 parts by mass, more preferably 0.15 to 40 parts by mass, still more preferably 0.20 to 30 parts by mass, particularly preferably 0.25 to 15 parts by mass, and especially preferably 0.30 to 10 parts by mass.

The content of the squaraine-based coloring agent represented by General Formula (1) in 100 parts by mass of the dye layer is preferably 0.01 to 30 parts by mass and more preferably 0.1 to 10 parts by mass. In the dye layer, all of the dyes may be the squaraine-based coloring agent represented by General Formula (1).

The content of the azo-based coloring agent represented by General Formula (i) in 100 parts by mass of the dye layer is preferably 0.01 to 30 parts by mass and more preferably 0.1 to 10 parts by mass. In the dye layer, the content of each of the coloring agents of the azo-based coloring agent represented by General Formula (ii), the azo-based coloring agent represented by General Formula (iii), the azo-based coloring agent represented by General Formula (iv), and the indoaniline-based coloring agent represented by General Formula (v) is also preferably 0.01 to 30 parts by mass and more preferably 0.1 to 10 parts by mass, Similarly to the content of the azo-based coloring agent represented by General Formula (i). In the dye layer, all of the dyes may be composed of at least one of the azo-based coloring agent represented by any of General Formulae (i) to (iv) or the indoaniline-based coloring agent represented by General Formula (v).

It is noted that in a case where the dye includes the quencher-embedded coloring agent, the content of the quencher-embedded coloring agent is, from the viewpoint of imparting light absorptance such as the antireflection effect, preferably 0.10 parts by mass or more, more preferably 0.15 parts by mass or more, still more preferably 0.20 parts by mass or more, particularly preferably 0.25 parts by mass or more, and especially preferably 0.30 parts by mass or more, with respect to 100 parts by mass of the resin constituting the dye layer. The upper limit value thereof is preferably 45 parts by mass or less, preferably 40 parts by mass or less, more preferably 30 parts by mass or less, still more preferably 15 parts by mass or less, and particularly preferably 10 parts by mass or less. That is, the total content of the quencher-embedded coloring agent in 100 parts by mass of the dye layer is preferably 0.10 to 45 parts by mass, more preferably 0.15 to 40 parts by mass, still more preferably 0.20 to 30 parts by mass, particularly preferably 0.25 to 15 parts by mass, and especially preferably 0.30 to 10 parts by mass.

<Compound that Generates Radical Upon Ultraviolet Irradiation>

The dye layer in the light absorption filter according to the embodiment of the present invention contains a compound that generates a radical upon ultraviolet irradiation (also simply referred to as a “radical generator” in the present invention).

The radical generator is not particularly limited as long as it is a compound that generates a radical upon ultraviolet irradiation, where the compound has a function of decolorizing the above-described dye. As the radical generator, it is possible to use, for example, a photoradical generator which may be used in combination with a compound B, will be described later.

The radical generator also preferably includes a combination of two or more compounds, where the combination is such that two or more compounds interact with each other to form a complex in the dye layer, and as a result, a radical is generated upon ultraviolet irradiation. Regarding the type of the compound to be combined, two or more types of compounds exhibiting functions different from each other need only to be used in a mechanism by which a radical is generated upon ultraviolet irradiation, and the type of the compound to be combined is preferably two types. Preferred examples of such a combination include a combination of a compound A having an acid group and a compound B having a structure that is capable of forming a hydrogen bond with an acid group contained in the compound A.

In the light absorption filter according to the embodiment of the present invention, in a case where the dye layer contains the compound A having an acid group and the compound B having a structure that is capable of forming a hydrogen bond with the acid group contained in the compound A, the efficiency of generating radical species upon ultraviolet irradiation is improved as compared with a case where the photoradical generator is used. As a result, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized.

Hereinafter, the compound A having an acid group and the compound B having a structure that is capable of forming a hydrogen bond with the acid group contained in the compound A will be described in detail.

### (1) Compound a Having Acid Group

It is preferable that the dye layer contains a compound A having an acid group (also simply referred to as a “compound A” in the present invention) as the radical generator, and a compound B having a structure that is capable of forming a hydrogen bond, together with a compound B having a structure that is capable of forming a hydrogen bond with the acid group contained in the compound A, where the compound B will be described later.

The acid group contained in the compound A is preferably a proton dissociable group having a pKa of 12 or less. Specific examples of the acid group include a carboxy group, a sulfonamide group, a phosphonate group (—P(═O)(OH)₂), a phosphate group (—OP(═O)(OH)₂), a sulfo group, a phenolic hydroxyl group, and a sulfonyl imide group, where a carboxy group is preferable. It is noted that pKa means a negative common logarithm (−logKa) of the acid dissociation constant (Ka) in water at 25° C., and it can be calculated in the same manner, except that in a calculation of the pKa of the compound B described later, a mixed solvent of water/methanol=50/50 (in terms of volume ratio) is changed to water.

The compound A may be a low-molecular-weight compound or a high-molecular-weight compound (hereinafter, also referred to as a “polymer”), where a polymer is preferable.

That is, the description that the compound A is a polymer means that the compound A is chemically bonded to a polymer that constitutes the resin contained in the dye layer.

In a case where the compound A is a low-molecular-weight compound, the molecular weight of the compound A is less than 5,000, and it is preferably 2,000 or less, more preferably 1,000 or less, still more preferably 500 or less, and particularly preferably 400 or less. The lower limit value thereof is not particularly limited. However, it is practically 100 or more, and it is preferably 200 or more. That is, it is practically 100 or more and less than 5,000, preferably 200 to 2,000, more preferably 200 to 1,000, still more preferably 200 to 500, and particularly preferably 200 to 400.

In a case where the compound A is a polymer, the lower limit value of the weight-average molecular weight of the compound A is 5,000 or more, and it is preferably 10,000 or more and more preferably 15,000 or more from the viewpoint of physical properties of the optical filter. The upper limit value thereof is not particularly limited; however, it is preferably 500,000 or less, more preferably 200,000 or less, and still more preferably 150,000 or less from the viewpoint of solubility in a solvent. That is, 5,000 to 500,000 is practical, 10,000 to 200,000 is preferable, and 15,000 to 150,000 is more preferable.

In addition, a part or all of the acid groups contained in the compound A may or may not be anionized in the dye layer, and in the present invention, both an anionized acid group and a non-anionized acid group are also referred to as an acid group. That is, the compound A may or may not be anionized in the dye layer.

The compound A is preferably a compound having a carboxy group from the viewpoint of excellent film-forming properties of the dye layer.

The above-described compound having a carboxy group is more preferably a monomer containing a carboxy group (hereinafter, also referred to as a “carboxy group-containing monomer”) or a polymer containing a carboxy group (hereinafter, also referred to as a “carboxy group-containing polymer”), and it is more preferably a carboxy group-containing polymer from the viewpoint of the film-forming properties of the dye layer.

It is noted that a part or all of the carboxy groups (—COOH) contained in the carboxy group-containing monomer and the carboxy group-containing polymer may or may not be anionized in the dye layer, and both an anionized carboxy group (—COO—) and a non-anionized carboxy group are also referred to as a carboxy group.

That is, the carboxy group-containing polymer may or may not be anionized in the dye layer, and both an anionized carboxy group-containing polymer and a non-anionized carboxy group-containing polymer are also referred to as a polymer.

The content of the compound A in the dye layer is preferably 1% by mass or more, more preferably 25% by mass or more, still more preferably 30% by mass or more, particularly preferably 45% by mass or more, and especially preferably 50% by mass or more. The upper limit value of the content of the compound A is preferably less than 100% by mass, more preferably 99% by mass or less, and still more preferably 97% by mass or less. That is, it is preferably 1% by mass or more and less than 100% by mass, more preferably 25% to 99% by mass, still more preferably 30% to 97% by mass, particularly preferably 45% to 97% by mass, and especially preferably 50% to 97% by mass.

Among the above, in a case where the compound A is a polymer, the content of the compound A in the dye layer is preferably 50% by mass or more and less than 100% by mass, more preferably 60% by mass or more and less than 100% by mass, and still more preferably 70% by mass or more and less than 100% by mass. The upper limit value thereof is also preferably 99% by mass or less, more preferably 97% by mass or less, still more preferably 95% by mass or less, and particularly preferably 90% by mass or less.

One kind of the compound A may be used alone, or two or more kinds thereof may be used in combination.

### (Carboxy Group-Containing Monomer)

Examples of the carboxy group-containing monomer include a polymerizable compound which contains a carboxy group and contains one or more (for example, 1 to 15) ethylenically unsaturated groups.

Examples of the ethylenically unsaturated group include a (meth)acryloyl group, a vinyl group, and a styryl group, and a (meth)acryloyl group is preferable.

It is noted that in a case where the ethylenically unsaturated group is a (meth)acryloyl group, a carbonyl bond in the (meth)acryloyl group and a carbonyl bond in the carboxy group may share one carbonyl bond.

From the viewpoint of more excellent film-forming properties, the carboxy group-containing monomer is preferably a bi- or higher functional monomer containing a carboxy group. The bi- or higher functional monomer means a polymerizable compound having 2 or more (for example, 2 to 15)ethylenically unsaturated groups in one molecule.

It suffices that the number of carboxy groups contained in the carboxy group-containing monomer is 1 or more, and the number thereof is, for example, preferably 1 to 8, more preferably 1 to 4, and still more preferably 1 or 2.

The carboxy group-containing monomer may further have, as an acid group, an acid group other than the carboxy group. Examples of the acid group other than the carboxy group include a phenolic hydroxyl group, a phosphoric acid group, and a sulfonic acid group.

The bi- or higher functional monomer containing a carboxy group is not particularly limited and can be appropriately selected from known compounds.

Examples of the bi- or higher functional monomer containing a carboxy group include, as product names, ARONIX M-520 and ARONIX M-510 (both manufactured by Toagosei Co., Ltd.).

In addition, examples of the bi- or higher functional monomer containing a carboxy group include a tri- or tetra-functional polymerizable compound having a carboxy group (a compound obtained by introducing a carboxy group into a pentaerythritol triacrylate and pentaerythritol tetraacrylate [PETA] skeleton (acid value=80 to 120 mgKOH/g)) and a penta- or hexa-functional polymerizable compound having a carboxy group (a compound obtained by introducing a carboxy group into a dipentaerythritol pentaacrylate and dipentaerythritol hexaacrylate [DPHA] skeleton (acid value=25 to 70 mgKOH/g)). In a case where the above-described tri- or higher functional monomer containing a carboxy group is used, from the viewpoint of more excellent film-forming properties, it is also preferable to use the bi- or higher functional monomer containing a carboxy group in combination.

Examples of the bi- or higher functional monomer containing a carboxy group and the bi- or higher functional monomer containing an acid group also include the polymerizable compounds having an acid group, which are described in paragraphs 0025 to 0030 of JP2004-239942A. The contents of this patent publication are incorporated in the present specification by reference.

### (Carboxy Group-Containing Polymer)

The carboxy group-containing polymer may further have, as an acid group, an acid group other than the carboxy group. Examples of the acid group other than the carboxy group include a phenolic hydroxyl group, a phosphoric acid group, and a sulfonic acid group.

In a case where the carboxy group-containing polymer is a copolymer, the structure of the polymer may be a random polymer or a regular polymer such as a block.

### <<Constitutional Unit Having Carboxy Group>>

The carboxy group-containing polymer preferably has a constitutional unit having a carboxy group.

Examples of the constitutional unit having a carboxy group include a constitutional unit derived from (meth)acrylic acid, crotonic acid, itaconic acid, maleic acid, or fumaric acid. Among the above, a constitutional unit derived from (meth)acrylic acid is preferable from the viewpoint of an excellent decolorizing property of the dye.

In the carboxy group-containing polymer, the content of the constitutional unit having a carboxy group is preferably 1% to 100% by mole, more preferably 3% to 65% by mole, still more preferably 5% to 60% by mole, particularly preferably 10% to 55% by mole, and among these, it is preferably 20% to 55% by mole in a case where the total of all the constitutional units of the carboxy group-containing polymer is set to 100% by mole.

One type of the constitutional unit having a carboxy group may be used alone, or two or more types thereof may be used in combination.

### <<Constitutional Unit Having Aromatic Ring>>

It is also preferable that the carboxy group-containing polymer has a constitutional unit having an aromatic ring (preferably, an aromatic hydrocarbon ring) in addition to the above-described constitutional unit. Examples thereof include a constitutional unit derived from a (meth)acrylate having an aromatic ring (specifically, benzyl (meth)acrylate, phenethyl (meth)acrylate, phenoxyethyl (meth)acrylate, or the like).

In the carboxy group-containing polymer, the content of the constitutional unit having an aromatic ring is preferably 0% to 97% by mole, more preferably 0% to 95% by mole, and still more preferably 0% to 90% by mole in a case where the total of all the constitutional units of the carboxy group-containing polymer is set to 100% by mole.

One kind of the constitutional unit having an aromatic ring may be used alone, or two or more kinds thereof may be used in combination.

### <<Constitutional Unit Having Alicyclic Structure>>

It is also preferable that the carboxy group-containing polymer has a constitutional unit having an alicyclic structure in addition to the above-described constitutional unit.

Examples of the alicyclic structure include a tricyclo[5.2.1.0^{2,6}]decane ring structure (also referred to as tetrahydrodicyclopentadiene, where a monovalent group is dicyclopentanyl), a tricyclo[5.2.1.0^{2,6}]decane-3-ene ring structure (also referred to as 5,6-dihydrodicyclopentadiene, where a monovalent group is dicyclopentenyl), an isobornane ring structure (where a monovalent group is isobornyl), an adamantane ring structure, and a cyclohexane ring structure (where a monovalent group is cyclohexyl).

Examples of the constitutional unit having an alicyclic structure include a constitutional unit derived from a (meth)acrylate having an alicyclic structure (specifically, dicyclopentanyl (meth)acrylate, dicyclopentenyl (meth)acrylate, isobornyl (meth)acrylate, adamantyl (meth)acrylate, cyclohexyl (meth)acrylate, or the like).

In the carboxy group-containing polymer, the content of the constitutional unit having an alicyclic structure is preferably 0% to 97% by mole, more preferably 0% to 95% by mole, and still more preferably 0% to 90% by mole in a case where the total of all the constitutional units of the carboxy group-containing polymer is set to 100% by mole.

One type of the constitutional unit having an alicyclic structure may be used alone, or two or more types thereof may be used in combination.

### <<Another Constitutional Unit>>

The carboxy group-containing polymer may have another constitutional unit in addition to the above-described constitutional units.

Examples of the other constitutional unit include a constitutional unit derived from methyl (meth)acrylate.

In the carboxy group-containing polymer, the content of the other constitutional unit is preferably 0% to 70% by mole, more preferably 0% to 50% by mole, and still more preferably 0% to 20% by mole in a case where the total of all the constitutional units of the carboxy group-containing polymer is set to 100% by mole.

One kind of the other constitutional unit may be used alone, or two or more kinds thereof may be used in combination.

### (2) Compound B

It is preferable that the dye layer contains together with the above-described compound A as the radical generator, a compound B having a structure that is capable of forming a hydrogen bond with the acid group contained in the compound A (also simply referred to as a “compound B” in the present invention).

The compound B is preferably a compound having such a structure that absorbs ultraviolet rays to be in an excited state, thereby having an increased basicity. In a case where the basicity of the compound B is increased in the excited state, it is possible to form a complex in which the acid group contained in the compound A interacts more strongly with the compound B, and it is possible to increase the efficiency of generating radicals.

A structure contained in the compound B, the structure that is capable of forming a hydrogen bond with the acid group contained in the compound A, may be a whole structure of the compound B or may be a partial structure that constitutes a part of the compound B.

The compound B may be a high-molecular-weight compound (which means a compound having a molecular weight of 5,000 or more) or a low-molecular-weight compound (which means a compound having a molecular weight of less than 5,000), and it is preferably a low-molecular-weight compound.

The molecular weight of the compound B as a low-molecular-weight compound is less than 5,000, and it is preferably less than 1,000, more preferably 500 or less, and still more preferably 350 or less. The lower limit value thereof is not particularly limited; however, it is preferably 65 or more and more preferably 75 or more. Examples of the preferred range of the molecular weight of the compound B which is a low-molecular-weight compound include 65 to 500 and more preferably 75 to 350.

From the viewpoint that the molar absorption coefficient with respect to ultraviolet rays is large, the compound B is preferably an aromatic compound.

Here, the aromatic compound is a compound having one or more aromatic rings.

Only one aromatic ring may be present in the compound B, or a plurality of aromatic rings may be present therein. In a case where a plurality of aromatic rings is present, the aromatic rings may be present, for example, in the side chain or the like of the polymer that constitutes the resin.

The aromatic ring may be any of an aromatic hydrocarbon ring or an aromatic heterocyclic ring. In a case of being an aromatic heterocyclic ring (also referred to as a heteroaromatic ring), it is a compound having one or more (for example, 1 to 4) heteroatoms (at least one among nitrogen atoms, oxygen atoms, sulfur atoms, or the like) as a ring member atom (ring-constituting atom) and preferably has one or more (for example, 1 to 4) nitrogen atoms as a ring member atom.

It is noted that since the unsubstituted aromatic hydrocarbon does not have a structure that is capable of forming a hydrogen bond with the acid group contained in the compound A, the unsubstituted aromatic hydrocarbon does not have a function of generating a radical upon ultraviolet irradiation and does not correspond to the compound B. In addition, since an unsubstituted aromatic hydrocarbon ring in a form in which the unsubstituted aromatic hydrocarbon ring is bonded to the side chain of the polymer that constitutes the resin does not have a structure that is capable of forming a hydrogen bond with the acid group contained in the compound A, the unsubstituted aromatic hydrocarbon ring does not have a function of generating a radical upon ultraviolet irradiation and does not correspond to the compound B.

The number of ring member atoms in the above-described aromatic ring is preferably 5 to 15.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

It is noted that in a case where a plurality of aromatic rings (for example, 2 to 5 aromatic rings) forms a series of aromatic ring structures bonded with a structure selected from a single bond, a carbonyl bond, and a multiple bond (for example, a vinylene group which may have a substituent, —C≡C—, —N═N—, and the like), the entire series of aromatic ring structures is regarded as one specific structure.

A series of aromatic ring structures in which the plurality of aromatic rings are bonded through a structure selected from a single bond, a carbonyl bond, or a multiple bond do not correspond to the above-described unsubstituted aromatic hydrocarbon ring, and do not correspond to the unsubstituted aromatic hydrocarbon ring in a form in which the unsubstituted aromatic hydrocarbon ring is bonded to a side chain of the polymer constituting the resin.

In addition, it is preferable that one or more of the aromatic rings constituting the series of aromatic ring structures are the above-described heteroaromatic rings.

Specific examples of the compound B include monocyclic aromatic compound such as a pyridine compound (pyridine or a pyridine derivative), a pyrazine compound (pyrazine or a pyrazine derivative), a pyrimidine compound (pyrimidine or a pyrimidine derivative), and a triazine compound (triazine or a triazine derivative); compounds in which two rings are fused to form an aromatic ring, such as a quinoline compound (quinoline or a quinoline derivative), an isoquinoline compound (isoquinoline or an isoquinoline derivative), a quinoxaline compound (quinoxaline or a quinoxaline derivative), and a quinazoline compound (quinazoline or a quinazoline derivative); and compounds in which three or more rings are fused to form an aromatic ring, such as an acridine compound (acridine or an acridine derivative), a phenanthridine compound (phenanthridine or a phenanthridine derivative), a phenanthroline compounds (phenanthroline or a phenanthroline derivative), and a phenazine compounds (phenazine or a phenazine derivative). In the specific examples of the compound B, the compound is used to have a meaning including not only the compound itself but a compound having a substituent (referred to as a “derivative”), including an unsubstituted compound in which a part of the structure has been changed, within a range where the effect of the present invention is not impaired.

It is presumed that this compound B forms a complex with the compound A and generates two molecules of radicals by the following mechanism upon ultraviolet irradiation.

1) The compound B in an excited state is generated by absorbing ultraviolet rays.

2) Positive holes move from the compound B in the excited state to the compound A in the ground state (the electrons of the compound A move to an orbital with lower energy in the two semi occupied molecular orbitals of the compound B in the excited state).

3) The movement of a proton from the compound A to the compound B generates a radical in which a hydrogen radical is loaded on the compound B and a radical in which a hydrogen radical is eliminated from the compound A.

In a case where the compound A is a compound having a carboxy group, the following reaction further occurs, and a radical is generated by a photodecarboxylation reaction.

4) Carbon dioxide is eliminated from the radical in which the hydrogen radical has been eliminated from the compound A.

Among the above, the compound B is preferably one or more among quinoline compounds (quinoline and a quinoline derivative) and isoquinoline compounds (isoquinoline and an isoquinoline derivative).

The substituent which may be contained in these compounds is preferably an alkyl group, an aryl group, a halogen atom, an acyl group, an alkoxycarbonyl group, an arylcarbonyl group, a carbamoyl group, a hydroxy group, a cyano group, or a nitro group.

In a case where the compound B is a polymer, the compound B may be a polymer in which the above-described specific structure is bonded to a polymer main chain through a single bond or a linking group.

The compound B as a polymer is obtained by, for example, polymerizing a monomer having a heteroaromatic ring (specifically, a (meth)acrylate monomer having a heteroaromatic ring having a vinyl group and/or a specific structure (preferably, a heteroaromatic ring)). As necessary, copolymerization with another monomer may be carried out.

Specific examples of the compound B include quinoline, 2-methylquinoline, 4-methylquinoline, 2,4-dimethylquinoline, 2-methyl-4-phenylquinoline, isoquinoline, 1-methylisoquinoline, 3-methylisoquinoline, and 1-phenylisoquinoline.

From the viewpoint of achieving both the decolorizing properties of the ultraviolet irradiated portion and the durability of the dye in the ultraviolet non-irradiated portion, the content of the compound B is preferably 0.1% to 50% by mass, more preferably 2.0% to 40% by mass, still more preferably 4% to 35% by mass, and particularly preferably 8% to 30% by mass, with respect to the total mass of the dye layer.

In addition, similarly, from the viewpoint of achieving both the decolorizing properties of the ultraviolet irradiated portion and the durability of the dye in the ultraviolet non-irradiated portion, the pKaH (the pKa of the conjugate acid), which is an index of the basicity of the compound B, is preferably 2.0 or more and 7.0 or less, more preferably 3.0 or more and 6.0 or less, and still more preferably 4.3 or more and 5.5 or less.

In the present invention, the pKa means a negative common logarithm (−logKa) of the acid dissociation constant (Ka) in a mixed solvent of water/methanol=50/50 (in terms of volume ratio) at 25° C. The pKa can be calculated by dropwise adding a 0.01 mol/L sodium hydroxide aqueous solution to a mixed solution of water/methanol=50/50 (in terms of volume ratio) of a measurement sample (a conjugate acid of the compound B) and reading the amount of the sodium hydroxide aqueous solution that has been dropwise added up to the half-equivalent point.

One kind of the compound B may be used alone, or two or more kinds thereof may be used in combination.

The dye layer may contain a compound (a photoradical generator) that generates a radical upon ultraviolet irradiation, in addition to the compound B. The photoradical generator is not particularly limited as long as it is a compound that generates a radical upon ultraviolet irradiation and has a function of decolorizing the above-described dye. It is noted that the radical generated may be a biradical in addition to the typical radical.

As the photoradical generator, a compound commonly used as a photoradical polymerization initiator a photoradical generator can be used without particular limitation, and examples thereof include an acetophenone generator, a benzoin generator, a benzophenone generator, a phosphine oxide generator, an oxime generator, a ketal generator, an anthraquinone generator, a thioxanthone generator, an azo compound generator, a peroxide generator, a disulfide generator, a lophine dimer generator, an onium salt generator, a borate salt generator, an active ester generator, an active halogen generator, an inorganic complex generator, and a coumarin generator. It is noted that an “XX generator” as the specific example of the photoradical generator may be individually referred to as an “XX compound” or “XX compounds”, and hereinafter, it is referred to as an “XX compound”.

Specific examples, preferred forms, commercially available products, and the like of the photoradical generator are respectively described as the specific examples, preferred forms, commercially available products, and the like of the photoradical initiator in paragraphs [0133] to [0151] of JP2009-098658A, and these can be similarly used suitably in the present invention.

The photoradical generator is preferably a compound that generates a radical upon intramolecular cleavage or a compound that abstracts a hydrogen atom from a compound present in the vicinity thereof to generate a radical, and it is more preferably a compound that abstracts a hydrogen atom from a compound present in the vicinity thereof to generate a radical, from the viewpoint of further improving the decolorization rate.

The above-described compound that generates a radical upon intramolecular cleavage (hereinafter, also referred to as an “intramolecular cleavage type photoradical generator”) means a compound that generates a radical, where the compound absorbing light undergoes bonding cleavage in a homolytic manner.

Examples of the intramolecular cleavage type photoradical generator include an acetophenone compound, a benzoin compound, a phosphine oxide compound, an oxime compound, a ketal compound, an azo compound, a peroxide compound, a disulfide compound, an onium salt compound, a borate salt compound, an active ester compounds, an active halogen compound, an inorganic complex compound, and a coumarin compound. Among these, an acetophenone compound, a benzoin compound, or a phosphine oxide compound, which is a carbonyl compound, is preferable. The Norrish type I reaction is known as a photodecomposition reaction of an intramolecular cleavage type carbonyl compound, and this reaction can be referenced as a radical generation mechanism.

The above-described compound that abstracts a hydrogen atom from a compound present in the vicinity thereof to generate a radical (hereinafter, also referred to as a “hydrogen abstraction type photoradical generator”) means a carbonyl compound in an excited triplet state obtained upon light absorption that abstracts a hydrogen atom from a compound present in the vicinity thereof to generate a radical.

A carbonyl compound is known as the hydrogen abstraction type photoradical generator, and examples thereof include a benzophenone compound, an anthraquinone compound, and a thioxanthone compound. The Norrish type II reaction is known as a photodecomposition reaction of a hydrogen abstraction type carbonyl compound, and this reaction can be referenced as a radical generation mechanism.

Examples of the compound present in the vicinity include various components present in the dye layer, such as a resin, a dye, and a radical generator.

The compound present in the vicinity which is a compound having a radical by a hydrogen atom being abstracted therefrom. Since a dye from which a hydrogen atom has been abstracted by the hydrogen abstraction type photoradical generator which is an active compound having a radical, the dye may be faded or decolorized through a reaction such as the decomposition of the dye having the radical.

In addition, in a case where the hydrogen abstraction type photoradical generator abstracts a hydrogen atom in the molecule, a biradical is generated.

The hydrogen abstraction type photoradical generator is preferably a benzophenone compound from the viewpoint of the quantum yield of the hydrogen abstraction reaction.

Various examples of the photoradical generator are also described in “Latest UV Curing Technology”, TECHNICAL INFORMATION INSTITUTE CO. LTD., 1991, p. 159, and “Ultraviolet Curing System”, written by Kiyomi Kato, 1989, published by SOGO GIJUTSU CENTER, p. 65 to 148, which can be also suitably used in the present invention.

In the photoradical generator, the maximal absorption wavelength of the ultraviolet ray to be absorbed is preferably in a range of 250 to 400 nm, more preferably in a range of 240 to 400 nm, and still more preferably in a range of 270 to 400 nm.

In a case where the photoradical generator is a benzophenone compound, the wavelength of the absorption maximum attributed to the n-π* transition, which is located on the longest wavelength side, is preferably in a range of 260 to 400 nm and more preferably in a range of 285 to 345 nm. The wavelength of the absorption maximum attributed to π-π*, which is located on the second longest wavelength side, is preferably in a range of 240 to 380 nm and more preferably in a range of 270 to 330 nm. In a case where the absorption maximum wavelength is set in the above range, the light of a light source used at the time of exposure, such as a metal halide lamp, is absorbed well. On the other hand, in a case of being incorporated into a display device, it is difficult to absorb an ultraviolet ray incident from the outside, and thus it is possible to achieve both the light resistance of the unexposed portion and the decolorizing properties of the exposed portion.

Among the benzophenone compounds, examples of the photoradical generator having absorption in a longer wavelength range include an alkoxybenzophenone compound.

In general, the maximal absorption wavelength of the ultraviolet ray absorbed by the photoradical generator is preferably separated by 30 nm or more from the main absorption wavelength band of the dye that has a main absorption wavelength band in a wavelength range of 400 to 700 nm. The upper limit value thereof is not particularly limited.

Examples of the commercially available photocleavage type photoradical generator include “Irgacure 651”, “Irgacure 184”, “Irgacure 819”, “Irgacure 907”, “Irgacure 1870” (a mixed initiator of CGI-403/Irgacure 184=7/3), “Irgacure 500”, “Irgacure 369”, “Irgacure 1173”, “Irgacure 2959”, “Irgacure 4265”, “Irgacure 4263”, “Irgacure 127”, or “OXE01”, all of which are product names, manufactured by BASF SE (formerly Ciba Specialty Chemicals Inc.); additionally, “Kayacure DETX-S”, “Kayacure BP-100”, “Kayacure BDMK”, “Kayacure CTX”, “Kayacure BMS”, “Kayacure 2-EAQ”, “Kayacure ABQ”, “Kayacure CPTX”, “Kayacure EPD”, “Kayacure ITX”, “Kayacure QTX”, “Kayacure BTC”, and “Kayacure MCA”, manufactured by Nippon Kayaku Co., Ltd.; and more additionally “Esacure (KIP100F, KB1, EB3, BP, X33, KTO46, KT37, KIP150, and TZT)” manufactured by Sartomer Company Inc. In addition, preferred examples thereof include a combination of two or more of these.

In a case where the dye layer contains a photoradical generator, the content of the photoradical generator in the dye layer is preferably 0.01% to 30% by mass and more preferably 0.1% to 20% by mass.

From the viewpoint of further improving the decolorization rate, the blending amount of the radical generator in the dye layer is preferably 0.1 to 20 mol with respect to 1 mol of the dye that has a main absorption wavelength band in a wavelength range of 400 to 700 nm. The lower limit value thereof is more preferably 0.25 mole or more and still more preferably 0.50 mole or more. The upper limit value thereof is more preferably 17.5 mol or less and still more preferably 15 mol or less. The blending amount of the radical generator referred to herein means the blending amount of the photoradical generator or the blending amount of the compound B described above, and does not include the blending amount of the compound A.

The dye layer may contain one kind of the radical generator or may contain two or more kinds thereof.

### <Resin>

The resin contained in the dye layer (hereinafter, also referred to as a “matrix resin”) is not limited as long as it can disperse (preferably dissolve) the above-described dye, can exhibit the decolorization action of the dye due to the radical generated from a compound (preferably, the radical generator containing the compound B that has been hydrogen-bonded to the acid group contained in the compound A) that generates a radical upon ultraviolet irradiation, and has desired light transmittance (the light transmittance is preferably 80% or more in the visible range in a wavelength range of 400 to 800 nm).

As a polymer that constitutes the above-described resin, various polymers can be used. Further, from the viewpoint that the molecular weight of the resin is not easily reduced upon ultraviolet irradiation, a polymer having an aromatic ring or an alicyclic structure in the side chain is preferable, and a (meth)acrylic polymer containing a constitutional unit having an aromatic ring or an alicyclic structure is more preferable. Among the above, from the viewpoint of further improving the decolorization rate and further improving the heat resistance and the light resistance as well, a (meth)acrylic polymer containing a constitutional unit having an alicyclic structure in the side chain is still more preferable.

Here, the (meth)acrylic polymer refers to a polymer containing at least one of a constitutional unit derived from (meth)acrylic acid or a constitutional unit derived from (meth)acrylic acid ester. It is noted that the constitutional unit derived from (meth)acrylic acid is a constitutional unit having a carboxy group as the acid group in the compound A, in a case where the polymer contains a constitutional unit derived from (meth)acrylic acid, and the polymer corresponds to a polymer in which the compound A is chemically bonded to the above-described polymer that constitutes the resin.

In addition, in the present invention, the “main chain” represents a relatively longest bonding chain in a molecule of a high-molecular-weight compound, and the “side chain” represents an atomic group branched from the main chain.

Examples of the monomer from which a constitutional unit having an aromatic ring is derived include benzyl acrylate, benzyl methacrylate, naphthyl acrylate, naphthyl methacrylate, naphthyl methyl acrylate, and naphthyl methyl methacrylate. In a case where the polymer does not contain a constitutional unit derived from (meth)acrylic acid, the content of the constitutional unit having an aromatic ring is preferably 5% to 100% by mass, more preferably 10% to 100% by mass, and still more preferably 20% to 100% by mass, with respect to the total mass of the polymer.

Examples of the monomer from which a constitutional unit having an alicyclic structure is derived include dicyclopentanyl (meth)acrylate, cyclohexyl (meth)acrylate, isobornyl (meth)acrylate, and adamantyl (meth)acrylate.

In a case where the polymer contains a constitutional unit having an alicyclic structure, the content of the constitutional unit having an alicyclic structure is preferably 1% to 90% by mass, more preferably 5% to 90% by mass, and still more preferably 5% to 80% by mass, with respect to the total mass of the polymer.

In addition, in the dye layer, the polymer that constitutes the resin may contain a constitutional unit bonded to the compound A having an acid group. The constitutional unit bonded to the compound A having an acid group is preferably a constitutional unit derived from (meth)acrylic acid. The content of the constitutional unit derived from (meth)acrylic acid is preferably 1% to 70% by mass and more preferably 1% to 60% by mass with respect to the total mass of the polymer. More preferably, the description of the content of the constitutional unit having the carboxy group of the carboxy group-containing polymer as the compound A is applied.

In a case where the polymer that constitutes the resin contains a constitutional unit bonded to the compound A having an acid group, the descriptions regarding the content of the constitutional unit having the carboxy group of the carboxy group-containing polymer as the compound A and the content of the constitutional unit having an aromatic ring and the content of the constitutional unit having an alicyclic structure are applied to the content of the constitutional unit bonded to the compound A having an acid group, the content of the constitutional unit having an aromatic ring, and the content of the constitutional unit having an alicyclic structure.

From the viewpoint of adjusting the glass transition temperature and the like, the polymer that constitutes the resin may contain a constitutional unit that has an alkyl group having 1 to 14 carbon atoms. Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination. The content of the constitutional unit having an alkyl group having 1 to 14 carbon atoms is preferably such that an amount of 0% by mass to 95% by mass is contained with respect to the total mass of the polymer that constitutes the resin.

The weight-average molecular weight (Mw) of the polymer that constitutes the resin is preferably 10,000 or more, more preferably 10,000 to 200,000, and still more preferably 15,000 to 150,000.

### <Other Components>

The dye layer may contain the above-described dye, the above-described radical generator (preferably the radical generator containing a combination of the compound A having an acid group and the compound B that hydrogen-bonds to the acid group in the compound A), and the above-described resin (matrix polymer), and further may contain an antifading agent, a matting agent, a leveling agent (surfactant), and the like.

### (Antifading Agent)

The dye layer preferably contains an antifading agent in order to prevent fading of the dye. It is preferable that the antifading agent does not inhibit the decolorization due to ultraviolet irradiation but has an effect of suppressing the dye decomposition due to visible light. As the antifading agent used in the present invention, the antifading agents described in paragraphs [0265] to [0280] of WO2022/210444A can be used.

The content of the antifading agent is preferably 1% to 15% by mass, more preferably 5% to 15% by mass, still more preferably 5% to 12.5% by mass, and particularly preferably 10% to 12.5% by mass, with respect to the total mass of 100% by mass of the dye layer.

In a case where the antifading agent is contained within the above-described preferred range, it is possible to improve the light resistance of the dye (the coloring agent) without causing side effects such as discoloration.

### (Matting Agent)

In order to impart sliding properties and prevent blocking, fine particles may be added to the surface of the dye layer as long as the effect of the present invention is not impaired. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms fine unevenness on the surface of the dye layer. Due to the unevenness, even in a case where the dye layers overlap each other or the dye layer and other films overlap each other, the films do not stick to each other and sliding properties are secured.

In a case where the dye layer contains a matting agent as fine particles, the effect of improving sliding properties and blocking properties is particularly large in the fine unevenness due to the protrusions in which fine particles protrude from the dye layer surface in a case where there are 10⁴/mm² or more of protrusions having a height of 30 nm or more.

It is preferable to apply the matting agent (fine particles) particularly onto the surface layer in order to improve the blocking properties and the sliding properties. Examples of the method of applying fine particles onto the surface layer include methods such as multilayer casting and coating.

The content of the matting agent in the dye layer is appropriately adjusted depending on the intended purpose.

However, it is preferable that the above-described matting agent (fine particles) is applied to a surface of the dye layer in contact with the diffusion inhibiting layer in the case where a gas barrier layer described later is provided on the surface of the dye layer in contact with the gas barrier layer, within a range where the effect of the present invention is not impaired.

### (Leveling Agent)

A leveling agent (surfactant) can be appropriately mixed with the dye layer. As the leveling agent, a commonly used compound can be used, and a fluorine-containing surfactant is particularly preferable. Specific examples thereof include the compounds described in paragraphs [0028] to [0056] of JP2001-330725A. In addition, as the commercially available product, MEGAFACE F (product name) series manufactured by DIC Corporation can also be used.

The content of the leveling agent in the dye layer is appropriately adjusted depending on the intended purpose.

The dye layer may contain, in addition to each component described above, a low-molecular plasticizer, an oligomer-based plasticizer, a retardation modifier, a deterioration preventing agent, a peeling accelerating agent, an infrared absorbing agent, an antioxidant, a filler, a compatibilizer.

In addition, the dye layer may contain the reaction accelerating agent or the reaction retarder described in paragraphs [0020] and [0021] of JP1997-286979A (JP-H09-286979A).

### <Method of Producing Dye Layer>

The dye layer can be produced by a method (coating method) of forming a coating layer on the diffusion inhibiting layer in the laminate of the support and the diffusion inhibiting layer according to a conventional method.

### (Coating Method)

In the present invention, a method of manufacturing a light absorption filter in which a support, a diffusion inhibiting layer, and a dye layer are laminated in this order by forming a dye layer on the diffusion inhibiting layer by a coating method with respect to a laminate in which the support and the diffusion inhibiting layer are provided on the support is preferable.

In the coating method, a solution of a material of a dye layer is applied onto a diffusion inhibiting layer of a laminate consisting of a support and the diffusion inhibiting layer to form a coating layer. A mold release agent or the like may be appropriately applied in advance to the surface of the diffusion inhibiting layer on the side where the coating layer is provided, in order to control the adhesiveness with the coating layer. The dye layer which is a coating layer can also be used by laminating the dye layer with other members through an adhesive layer or directly in a subsequent step and then peeling off the support. Any adhesive can be appropriately used as the adhesive constituting the adhesive layer. In addition, the support and the diffusion inhibiting layer can be appropriately stretched together in a state where a solution of a material of the dye layer is applied onto the diffusion inhibiting layer of the laminate consisting of the support and the diffusion inhibiting layer or in a state where the coating layer is laminated.

It is preferable that the solvent used in the solution of the material of the dye layer is capable of dissolving or dispersing the material of the dye layer and has a low affinity for the resin constituting the diffusion inhibiting layer, as described above. As long as these conditions are satisfied, a commonly used solvent can be used without particular limitation, and examples thereof include an aromatic hydrocarbon solvent such as toluene, an aliphatic hydrocarbon solvent such as cyclohexanone, an ether solvent such as tetrahydrofuran, and a ketone solvent such as methyl ethyl ketone.

In addition, from the viewpoints of easily obtaining a uniform surface state in the coating step and the drying step, ensuring liquid preservability, and having an appropriate saturated vapor pressure, the solvent can also be appropriately selected.

### -Addition of Dye (Coloring Agent) and Radical Generator-

The timing of adding the dye and the radical generator to the material of the dye layer is not particularly limited as long as they are added at the time of film formation. For example, the dye may be added at the time of synthesizing the matrix polymer, or may be mixed with the material of the dye layer at the time of preparing the coating liquid for the material of the dye layer. It is noted that in a case where the radical generator includes a combination of the compound A and the compound B, and the compound A is bonded to the polymer that constitutes the resin, the compound A is added at the time of adding the polymer that constitutes the resin.

### -Support-

The support used for forming the dye layer by a coating method or the like is preferably a film-shaped support (in the present invention, referred to as a “support film”). The support film preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the preferred upper limit value, the surface pressure applied to the multi-layer film is easily adjusted to be in an appropriate range, and thus adhesion defect is less likely to occur in a case where a multi-layer film of the dye layer, the diffusion inhibiting layer, and the support film is stored, for example, in a form of a long roll.

The surface energy of the support film is not particularly limited, and by adjusting the relationship between the surface energy of the material of the diffusion inhibiting layer or the coating solution and the surface energy of the surface of the support film on which the diffusion inhibiting layer is to be formed, the adhesive force between the diffusion inhibiting layer and the support film can be adjusted. In a case where the surface energy difference is reduced, the adhesive force tends to increase, and in a case where the surface energy difference is increased, the adhesive force tends to decrease, and thus the surface energy can be set appropriately.

In addition, the surface unevenness of the support film is not particularly limited, but can be adjusted, for example, for the purpose of preventing adhesion defects in a case of storing a multi-layer film of the dye layer and the diffusion inhibiting layer and the support film in a long roll form, according to the relationship between the surface energy, hardness, and surface unevenness of the layer of the dye layer and the like, which is located on the side opposite to the support film in the light absorption filter according to the embodiment of the present invention, and the surface energy and hardness of the surface of the support film opposite to the side on which the diffusion inhibiting layer is formed. In a case where the surface unevenness of the support film is increased, the adhesion defect tends to be suppressed, and in a case where the surface unevenness is decreased, the surface unevenness of the dye layer is reduced, and the haze of the dye layer tends to be small, and the surface unevenness can be appropriately set.

For such a support film, any material and film can be appropriately used. Specific examples of materials can include a polyester-based polymer (including polyethylene terephthalate-based film), an olefin-based polymer, a cyclo olefin-based polymer, a (meth)acrylic polymer, a cellulose-based polymer, and a polyamide-based polymer. In addition, a surface treatment can be appropriately carried out for the intended purpose of adjusting the surface energy of the support film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

### <Film Thickness of Dye Layer>

The film thickness of the dye layer is not particularly limited, and is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effect of the quencher is likely to be exhibited. On the other hand, in a case where the film thickness is equal to or larger than the above-described preferred lower limit value, it is easy to maintain the evenness of the in-plane absorbance.

In the present invention, the film thickness of 1 to 18 μm means that the thickness of the dye layer is within a range of 1 to 18 μm regardless of the site where the thickness is measured. The same applies to the film thicknesses of 1 to 12 μm and 2 to 8 μm. The film thickness can be measured with an electronic micrometer manufactured by Anritsu Corporation.

### <Absorbance of Light Absorption Filter According to Embodiment of Present Invention>

In the light absorption filter according to the embodiment of the present invention, the absorbance at the maximal absorption wavelength at which the highest absorbance is exhibited at a wavelength of 400 to 700 nm (hereinafter, also simply referred to as “Ab(λₘₐₓ)”) is preferably 0.3 or more, more preferably 0.5 or more, and still more preferably 0.7 or more.

However, the absorbance of the light absorption filter according to the embodiment of the present invention can be adjusted by the type, adding amount, or film thickness of the dye.

The light absorption filter according to the embodiment of the present invention has a decolorization rate upon ultraviolet irradiation of preferably exceeding 70%, more preferably 75% or more, still more preferably 80% or more, and particularly preferably 85% or more, among which 90% or more is preferable. The upper limit value thereof is not particularly limited, and it is preferably 100%.

The decolorization rate is calculated according to the following expression using the values of Ab(λₘₐₓ) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

Here, in the ultraviolet irradiation test, an ultra-high pressure mercury lamp (manufactured by HOYA Corporation, product name: UL750) is used under atmospheric pressure (101.33 kPa) to irradiate the light absorption filter with ultraviolet rays at an illuminance of 100 mW/cm² and an irradiation amount of 750 to 2,500 mJ/cm² at room temperature (25° C.).

The absorbance, the ultraviolet irradiation test, and the decolorization rate can be measured and calculated according to the methods described in Examples.

In addition, it is preferable that the light absorption filter according to the embodiment of the present invention hardly causes absorption (secondary absorption) derived from a new coloration structure associated with the decomposition of the coloring agent.

For example, the presence or absence of the absorption derived from the new coloration structure associated with the decomposition of the coloring agent can be checked based on the ratio of the absorbance at a specific wavelength to the above Ab(λₘₐₓ). As the specific wavelength, a wavelength at which the coloring agent before ultraviolet irradiation seldom exhibits absorption but new absorption due to the decomposition of the coloring agent is observed is selected.

As a specific example, as described in Examples described later, the presence or absence of the absorption derived from a new coloration structure associated with the decomposition of the coloring agent can be checked based on the ratio of the absorbance at a wavelength of 450 nm to the above Ab(λₘₐₓ) (hereinafter, also simply referred to as “Ab(450)”). That is, it is meant that the smaller the value obtained by subtracting the ratio of the following (I) from the ratio of the following (II), the less frequently the absorption derived from the new coloration structure associated with the decomposition of the coloring agent occurs. This value is preferably less than 8.5%, more preferably 7.0% or less, and still more preferably 5.0% or less. The lower limit value thereof is not particularly limited; however, it is practically-10% or more and preferably-6% or more from the viewpoint of making valid the evaluation related to the presence or absence of the secondary absorption associated with the decomposition of the coloring agent.

$$( Ab ( 450 ) before ultraviolet irradiation / Ab ( {λ}_{max} ) before ultraviolet irradiation ) \times 100 \% \qquad ( I )$$

$$( Ab ( 450 ) after ultraviolet irradiation / Ab ( {λ}_{max} ) before ultraviolet irradiation ) \times 100 \% \qquad ( II )$$

The checking of the presence or absence of the absorption derived from the new coloration structure associated with the decomposition of the coloring agent can be carried out by the measurement and the calculation according to the method described in Examples.

The light absorption filter according to the embodiment of the present invention can exhibit excellent decolorizing properties in a case where both the above-described decolorization rate and the above-described value for checking the presence or absence of the absorption derived from the new coloration structure associated with the decomposition of the coloring agent satisfy a preferred range.

The light absorptive portion having a light absorption effect in the optical filter according to the embodiment of the present invention preferably satisfies the above description of Ab(λₘₐₓ) related to the light absorption filter according to the embodiment of the present invention.

### <Treatment of Light Absorption Filter According to Embodiment of Present Invention>

Any surface of the light absorption filter according to the embodiment of the present invention (for example, a surface of the dye layer opposite to the side in contact with the diffusion inhibiting layer) may be subjected to a hydrophilization treatment by any glow discharge treatment, corona discharge treatment, or alkali saponification treatment, and the corona discharge treatment is preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

In addition, as a pressure-sensitive adhesive layer, a layer consisting of a pressure-sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure-sensitive adhesive layer in the OLED display device described later can be applied.

### «Gas Barrier Layer»

The light absorption filter according to the embodiment of the present invention may have a gas barrier layer on a surface of the dye layer opposite to the surface having the diffusion inhibiting layer. In a case where the light absorption filter according to the embodiment of the present invention has a gas barrier layer, the light absorption filter according to the embodiment of the present invention can be made to be a light absorption filter that achieves both high decolorizing properties and excellent light resistance and can be suitably used in the production of an optical filter described later.

The material that forms the gas barrier layer is not particularly limited, and examples thereof include an organic material (preferably a crystalline resin) such as polyvinyl alcohol or polyvinylidene chloride, an organic-inorganic hybrid material such as a sol-gel material, and an inorganic material such as SiO₂, SiOₓ, or SiON, SiNₓ, or Al₂O₃. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

In the light absorption filter according to the embodiment of the present invention, by providing the gas barrier layer on the surface that comes into contact with air in a case where the light absorption filter or the optical filter according to the embodiment of the present invention is used, a decrease in the absorption intensity of the dye in the dye layer can be suppressed.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

“The gas barrier layer containing a crystalline resin, where the thickness of the layer is 0.1 μm to 10 μm and the oxygen permeability of the layer is 60 cc/m²·day·atm or less” described above is the same as the gas barrier layers described in [0180] to [0184] of WO2022/149510A, and these descriptions can be applied as they are.

### <Manufacturing Method for Gas Barrier Layer>

The method of forming the gas barrier layer is not particularly limited, and examples thereof include a producing method according to a conventional method according to a casting method such as spin coating or slit coating, for example, in a case of an organic material. In addition, examples thereof can include a method of bonding a commercially available resin gas barrier film or a resin gas barrier film produced in advance to the dye layer. In addition, in a case of an inorganic material, examples thereof include a plasma enhanced chemical vapor deposition (CVD) method, a sputtering method, and a vapor deposition method.

In a case where the above-described gas barrier layer is provided in the light absorption filter according to the embodiment of the present invention, for example, a method of directly producing the above-described gas barrier layer on the light absorption filter according to the embodiment of the present invention produced according to the above-described production method is included. In this case, it is also preferable to apply a corona treatment to the surface of the dye layer of the light absorption filter according to the embodiment of the present invention to which the gas barrier layer is provided.

In addition, in a case where the optional optical functional film described later is provided, it is also preferable to carry out bonding while interposing a pressure-sensitive adhesive layer. For example, it is also preferable that a gas barrier layer is provided on the dye layer in the light absorption filter according to the embodiment of the present invention and then bonded to an optical functional film while interposing a pressure-sensitive adhesive layer.

### <Optical Functional Film>

The light absorption filter according to the embodiment of the present invention may appropriately have the gas barrier layer or any optical functional film as long as the effect of the present invention is not impaired.

The optional optical functional film is not particularly limited in terms of any of the optical properties and the materials, and a film containing (or containing as a main component) at least any of a cellulose ester resin, an acrylic resin, a cyclic olefin resin, or a polyethylene terephthalate resin can be preferably used. It is noted that an optically isotropic film or an optically anisotropic phase difference film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical functional film containing a (meth)acrylic resin having a glutaric anhydride unit described in JP2009-139754A can be used.

In addition, regarding the optional optical functional films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, and JP2008-063536A can be used.

### [Optical Filter]

The optical filter according to the embodiment of the present invention is obtained by subjecting the light absorption filter according to the embodiment of the present invention to mask exposure by ultraviolet irradiation.

The optical filter according to the embodiment of the present invention has a light absorptive portion having a light absorption effect and a portion in which light absorption properties have been eliminated (a light absorption property-eliminated portion) in response to a mask exposure pattern (hereinafter, also referred to as a “mask pattern”).

That is, in a case where the light absorption filter according to the embodiment of the present invention is subjected to mask exposure by ultraviolet irradiation, the masked portion of the light absorption filter according to the embodiment of the present invention is not exposed and present as a light absorptive portion having a light absorption effect, whereas the unmasked portion is exposed and is a light absorption property-eliminated portion.

The light absorptive portion can exhibit a desired absorbance.

In addition, the light absorption property-eliminated portion can exhibit optical characteristics close to colorlessness since the light absorption filter according to the embodiment of the present invention exhibits an excellent decolorization rate and secondary absorption seldom occurs in association with the dye decomposition.

The optical filter according to the embodiment of the present invention may have a form in which a support is provided, or may have a form in which the support is removed. In a case where the optical filter according to the embodiment of the present invention is incorporated into an OLED display device, an inorganic EL display device, or a liquid crystal display device, the optical filter may be incorporated in a form in which a support is provided, or may be incorporated in a form in which the support is removed.

### <Manufacturing Method for Optical Filter>

The optical filter according to the embodiment of the present invention can be obtained by irradiating the light absorption filter according to the embodiment of the present invention with an ultraviolet ray to carry out mask exposure.

The mask pattern can be appropriately adjusted so that the optical filter according to the embodiment of the present invention having a desired pattern consisting of a light absorptive portion and a light absorption property-eliminated portion can be obtained.

The conditions of ultraviolet irradiation can be appropriately adjusted so that the optical filter according to the embodiment of the present invention having a light absorption property-eliminated portion can be obtained. For example, the ultraviolet irradiation can be carried out under atmospheric pressure (101.33 kPa) regarding the pressure condition and can be carried out under a mild temperature condition regarding the temperature condition without carrying out heating at room temperature (10° C. to 30° C.) or the like, the lamp output can be set to 10 to 320 W/cm, and an air-cooled metal halide lamp, a mercury lamp such as an ultra-high pressure mercury lamp, or the like can be used as a lamp to be used. The irradiation dose can be set to 200 to 5,000 mJ/cm².

The optical filter according to the embodiment of the present invention may have an optical functional film described in the light absorption filter according to the embodiment of the present invention.

In addition, the optical filter according to the embodiment of the present invention may have a layer containing an ultraviolet absorbing agent. As the ultraviolet absorbing agent, a commonly used compound can be used without particular limitation, and examples thereof include an ultraviolet absorbing agent in the ultraviolet absorbing layer described later. The resin constituting the layer containing the ultraviolet absorbing agent is also not particularly limited, and examples thereof include a resin in the ultraviolet absorbing layer described later.

The content of the ultraviolet absorbing agent in the layer containing the ultraviolet absorbing agent is appropriately adjusted according to the intended purpose.

### [OLED Display Device]

The organic electroluminescent display device according to the embodiment of the present invention (referred to as an organic electroluminescence (EL) display device or an organic light emitting diode (OLED) display device, and abbreviated as an OLED display device in the present invention) includes the optical filter according to the embodiment of the present invention.

As another configuration of the OLED display device according to the embodiment of the present invention, the configuration of the generally used OLED display device can be used without particular limitation, as long as the optical filter according to the embodiment of the present invention is included. The configuration example of the OLED display device according to the embodiment of the present invention is not particularly limited, and examples thereof include a display device including glass, a layer containing a thin film transistor (TFT), an OLED display element, a barrier film, a color filter, glass, a pressure-sensitive adhesive layer, the optical filter according to the embodiment of the present invention, and a surface film, in order from the opposite side to external light.

The OLED display element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referenced.

Furthermore, as the color filter, in addition to a typical color filter, a color filter in which quantum dots are laminated can also be used.

A resin film can be used instead of the above glass.

### <Pressure-Sensitive Adhesive Layer>

In the OLED display device according to the embodiment of the present invention, a surface of the optical filter according to the embodiment of the present invention on the external light side may be bonded to an optical functional film having an antireflection layer or the like, or a polarizing plate including a polarizer and a polarizing plate protective film while interposing a pressure-sensitive adhesive layer. In addition, it is preferable that a surface of the optical filter according to the embodiment of the present invention, which is positioned opposite to the side of the external light, is bonded to the glass (the base material) with a pressure-sensitive adhesive layer being interposed.

For the pressure-sensitive adhesive layer, the descriptions related to the pressure-sensitive adhesive layer and the forming method in the OLED display device, which are described in [0239] to [0290] of WO2021/132674A, can be applied as they are.

It is noted that the pressure-sensitive adhesive composition described in WO2021/132674A preferably contains the above-described ultraviolet absorbing agent from the viewpoint of the light resistance of the optical filter.

### <Base Material>

In the OLED display device according to the embodiment of the present invention, a surface of the optical filter according to the embodiment of the present invention, which is positioned on the external light side, may be bonded to an optical functional film with a pressure-sensitive adhesive layer being interposed. In addition, it is preferable that a surface of the optical filter according to the embodiment of the present invention, which is positioned opposite to the side of the external light, is bonded to the glass (the base material) with a pressure-sensitive adhesive layer being interposed.

The method of forming the pressure-sensitive adhesive layer is not particularly limited, and for example, a method of applying the pressure-sensitive adhesive composition to the light absorption filter or optical filter according to the embodiment of the present invention by a usual means such as a bar coater, drying, and curing the pressure-sensitive adhesive composition; a method of applying the pressure-sensitive adhesive composition first to the surface of a peelable base material, and drying the composition, and then transferring the pressure-sensitive adhesive layer using the peelable base material to the light absorption filter or the optical filter according to the embodiment of the present invention and then aging and curing the composition is used.

The peelable base material is not particularly limited, and any peelable base material can be used, and examples thereof include the support film in the above-described coating method.

In addition, the conditions of application, drying, aging, and curing can be appropriately adjusted based on a conventional method.

### [Inorganic EL Display Device]

An inorganic electroluminescent display device (referred to as an inorganic EL (electroluminescence) display device and also simply referred to as an inorganic EL display device in the present invention) according to an embodiment of the present invention includes the optical filter according to the embodiment of the present invention.

As another configuration of the inorganic EL display device according to the embodiment of the present invention, a configuration of a generally used inorganic EL display device can be used without particular limitation as long as the optical filter according to the embodiment of the present invention is included. For example, the descriptions regarding the inorganic EL element and the inorganic electroluminescent display device, which are described in JP2005-338640A can be preferably applied.

### [Liquid Crystal Display Device]

The liquid crystal display device according to the embodiment of the present invention includes the optical filter according to the embodiment of the present invention.

The optical filter according to the embodiment of the present invention may be used as at least any one of a polarizing plate-protective film or a pressure-sensitive adhesive layer as described later, or it may be included in a backlight unit that is used in the liquid crystal display device.

It is preferable that the liquid crystal display device includes the optical filter according to the embodiment of the present invention, a polarizing plate including a polarizer and a polarizing plate-protective film, a pressure-sensitive adhesive layer, and a liquid crystal cell, where it is preferable that the polarizing plate is bonded to the liquid crystal cell with a pressure-sensitive adhesive layer being interposed. In the liquid crystal display device, the optical filter according to the embodiment of the present invention may also serve as the polarizing plate-protective film or the pressure-sensitive adhesive layer. That is, the liquid crystal display device is divided into a case where the liquid crystal display device includes a polarizing plate including a polarizer and the optical filter (polarizing plate-protective film) according to the embodiment of the present invention, a pressure-sensitive adhesive layer, and a liquid crystal cell, and a case where the liquid crystal display device includes a polarizing plate including a polarizer and a polarizing plate-protective film, the optical filter (pressure-sensitive adhesive layer) according to the embodiment of the present invention, and a liquid crystal cell.

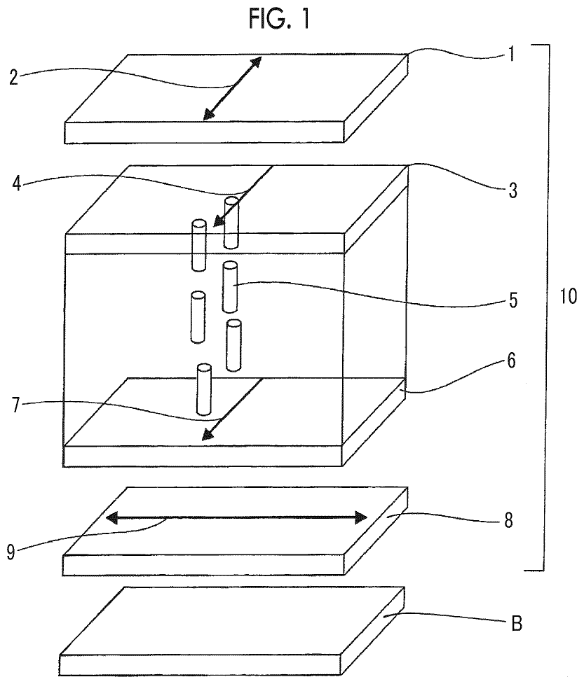

FIG. 1 is a schematic view illustrating an example of the liquid crystal display device according to the embodiment of the present invention. In FIG. 1, a liquid crystal display device 10 consists of a liquid crystal cell having a liquid crystal layer 5 and having a liquid crystal cell upper electrode substrate 3 and a liquid crystal cell lower electrode substrate 6, which are respectively disposed above and below the liquid crystal layer 5, and an upper polarizing plate 1 and a lower polarizing plate 8, which are respectively disposed on both sides of the liquid crystal cell. A color filter layer may be laminated on the upper electrode substrate 3 or the lower electrode substrate 6. On the rear surface of the liquid crystal display device 10, a backlight is disposed. As a light source of the backlight, those described in the above backlight unit can be used.

Each of the upper polarizing plate 1 and the lower polarizing plate 8 has a configuration in which each of them is laminated such that a polarizer is sandwiched between two polarizing plate protective films, and in the liquid crystal display device 10, at least one polarizing plate is preferably a polarizing plate including the optical filter according to the embodiment of the present invention.

In addition, in the liquid crystal display device 10, the liquid crystal cell may be bonded to the polarizing plates (the upper polarizing plate 1 and/or the lower polarizing plate 8) with a pressure-sensitive adhesive layer (not illustrated in the drawing) being interposed. In this case, the optical filter according to the embodiment of the present invention may also serve as the above-described pressure-sensitive adhesive layer.

The liquid crystal display device 10 includes an image direct vision-type liquid crystal display, an image projection-type liquid crystal display device, and a light modulation-type liquid crystal display device. The present invention is effective for an active matrix liquid crystal display device that uses a three-terminal or two-terminal semiconductor element such as a thin film transistor or a metal insulator metal (MIM). Of course, it is also effective for a passive matrix liquid crystal display device represented by a super twisted nematic (STN) mode which is called the time division driving.

In a case where the optical filter according to the embodiment of the present invention is included in the backlight unit, the polarizing plate of the liquid crystal display device may be a general polarizing plate (a polarizing plate that does not include the optical filter according to the embodiment of the present invention) or may be a polarizing plate that includes the optical filter according to the embodiment of the present invention. In addition, the pressure-sensitive adhesive layer may be a typical pressure-sensitive adhesive layer (not the optical filter according to the embodiment of the present invention) or may be a pressure-sensitive adhesive layer formed of the optical filter according to the embodiment of the present invention.

The in plane switching (IPS) mode liquid crystal display device described in paragraphs 0128 to 0136 of JP2010-102296A is preferable as the liquid crystal display device according to the embodiment of the present invention except that the optical filter according to the embodiment of the present invention is used.

### <Polarizing Plate>

The polarizing plate that is used in the present invention includes a polarizer and at least one polarizing plate-protective film.

The polarizing plate that is used in the present invention is preferably a polarizing plate having a polarizer and polarizing plate-protective films on both surfaces of the polarizer, and it is preferable that at least one surface of the polarizer includes the optical filter according to the embodiment of the present invention as the polarizing plate-protective film. The surface of the polarizer opposite to the surface having the optical filter according to the embodiment of the present invention (the polarizing plate-protective film according to the embodiment of the present invention) may have a general polarizing plate-protective film.

The film thickness of the polarizing plate protective film is preferably 5 to 120 μm and more preferably 10 to 100 μm. A thinner film is preferable since in a case of being incorporated in the liquid crystal display device, the display unevenness after elapse of time in high temperature and high humidity is less likely to occur. On the other hand, in a case where the film is too thin, it is difficult to transport the film stably at the time of producing the film and producing the polarizing plate. In a case where the optical filter according to the embodiment of the present invention also serves as the polarizing plate-protective film, it is preferable that the thickness of the optical filter satisfies the above-described range.

For the polarizing plate that is used in the present invention, the descriptions related to the performance, the shape, the configuration, the polarizer, the method of laminating the polarizer and the polarizing plate-protective film, the functionalization of the polarizing plate, and the like regarding the polarizing plate described in [0299] to [0309] of WO2021/132674A can be applied as they are.

### <Pressure-Sensitive Adhesive Layer>

In the liquid crystal display device according to the embodiment of the present invention, the polarizing plate is preferably bonded to the liquid crystal cell with a pressure-sensitive adhesive layer being interposed. The optical filter according to the embodiment of the present invention may also serve as the pressure-sensitive adhesive layer. In a case where the optical filter according to the embodiment of the present invention does not serve as the pressure-sensitive adhesive layer, a typical pressure-sensitive adhesive layer can be used as the pressure-sensitive adhesive layer.

The pressure-sensitive adhesive layer is not particularly limited as long as the polarizing plate can be bonded to the liquid crystal cell, and for example, an acrylic type, a urethane type, polyisobutylene, or the like is preferable.

In a case where the optical filter according to the embodiment of the present invention also serves as a pressure-sensitive adhesive layer, the pressure-sensitive adhesive layer includes the dye and the base polymer, and further contains a crosslinking agent, a coupling agent, or the like to impart adhesiveness.

In a case where the optical filter according to the embodiment of the present invention also serves as a pressure-sensitive adhesive layer, the pressure-sensitive adhesive layer preferably contains 90% to 100% by mass of the base polymer, and preferably contains 95% to 100% by mass of the base polymer. The content of the coloring agent is as described above.

The thickness of the pressure-sensitive adhesive layer is not particularly limited; however, it is preferably 1 to 50 μm and more preferably 3 to 30 μm.

### <Liquid Crystal Cell>

The liquid crystal cell is not particularly limited, and a typical liquid crystal cell can be used.

### <Ultraviolet Absorbing Layer>

The organic electroluminescent display device, inorganic electroluminescent display device, or liquid crystal display device including the optical filter according to the embodiment of the present invention preferably has a layer (hereinafter, also referred to as an “ultraviolet absorbing layer”) that inhibits the light absorption (the ultraviolet absorption) of the compound that generates a radical upon ultraviolet irradiation, on the viewer side with respect to the optical filter according to the embodiment of the present invention. In a case where the ultraviolet absorbing layer is provided, it is possible to prevent the fading of the optical filter according to the embodiment of the present invention due to external light.

Hereinafter, the ultraviolet absorbing layer that is used in the present invention will be described.

### (Ultraviolet Absorbing Agent)

The ultraviolet absorbing layer usually contains a resin and an ultraviolet absorbing agent.

Specific examples of the ultraviolet absorbing agent preferably used in the present invention include a hindered phenol-based compound, a benzophenone-based compound such as a hydroxybenzophenone-based compound, a benzotriazole-based compound, a salicylic acid ester-based compound, a cyanoacrylate-based compound, and a nickel complex salt-based compound.

Examples of the hindered phenol-based compound include 2,6-di-tert-butyl-p-cresol, pentaerythrityl-tetrakis[3-(3,5-di-tert-butyl-4-hydroxyphenyl) propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, and tris-(3,5-di-tert-butyl-4-hydroxybenzyl)-isocyanurate.

Examples of the benzotriazole-based compound include 2-(2′-hydroxy-5′-methylphenyl)benzotriazole, 2,2-methylene bis(4-(1,1,3,3-tetramethylbutyl)-6-(2H-benzotriazole-2-yl) phenol), 2,4-bis(n-octylthio)-6-(4-hydroxy-3,5-di-tert-butylanilino)-1,3,5-triazine, triethyleneglycol-bis[3-(3-tert-butyl-5-methyl-4-hydroxyphenyl) propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, 2-(2′-hydroxy-3′,5′-Di-tert-butylphenyl)-5-chlorbenzotriazole, 2-(2′-hydroxy-3′,5′-di-tert-amylphenyl)-5-chlorbenzotriazole, 2,6-di-tert-butyl-p-cresol, and pentaerythrityl-tetrakis[3-(3,5-di-tert-butyl-4-hydroxyphenyl) propionate].

The adding amount of this ultraviolet absorbing agent is preferably 0.1 parts by mass to 30.0 parts by mass with respect to 100 parts by mass of the resin.

In addition, a compound (1) represented by Formula (1) is particularly preferably used as an ultraviolet absorbing agent from the viewpoint of further improving the light resistance of the optical filter according to the embodiment of the present invention.

### «Compound Represented by Formula (1) (Compound (1))»

A resin composition for forming the ultraviolet absorbing layer preferably contains a compound represented by Formula (1) (hereinafter, also referred to as a compound (1)).

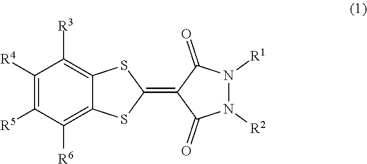

In Formula (1), R¹ and R² each independently represent an alkyl group, an aryl group, or a heterocyclic group, R³ and R⁶ each independently represent an alkoxy group, an acyloxy group, a carbamoyloxy group, or an alkoxycarbonyloxy group, R⁴ represents an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group, and R⁵ represents a hydrogen atom, an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

R¹ and R² may be bonded to each other to form a ring, R³ and R⁴ may be bonded to each other to form a ring, R⁴ and R⁵ may be bonded to each other to form a ring, and R⁵ and R⁶ may be bonded to each other to form a ring. These rings to be formed may be aromatic or may not exhibit aromaticity.

However, in a case where R³ and R⁶ each independently represent an acyloxy group or a carbamoyloxy group, at least one of R⁴ or R⁵ represents an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

In Formula (1), R¹ and R² each independently represent an alkyl group, an aryl group, or a heterocyclic group, where an alkyl group or an aryl group is preferable. From the viewpoint of light resistance, it is preferable that R¹ and R² are each independently an alkyl group. In addition, from the viewpoint of the absorbability of ultraviolet rays in the vicinity of a wavelength of 400 nm, it is preferable that R¹ and R² are each independently an aryl group.

The alkyl group represented by R¹ and R² preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include the groups described regarding the substituent T described later, and preferred examples thereof include a halogen atom, an alkoxy group, an alkenyl group, and an aryl group.

The aryl group represented by R¹ and R² preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The above-described aryl group is preferably a phenyl group or a naphthyl group, and more preferably a phenyl group. The aryl group may have a substituent. Examples of the substituent include the groups described regarding the substituent T described later, and preferred examples thereof include an alkoxy group.

It is preferable that the heterocyclic ring in the heterocyclic group represented by R¹ and R² includes a 5- or 6-membered saturated or unsaturated heterocyclic ring. The heterocyclic ring may be fused with an aliphatic ring, an aromatic ring, or another heterocyclic ring. Examples of the heteroatom constituting the ring of the heterocyclic ring include B, N, O, S, Se, and Te, and the heteroatom is preferably at least one of N, O, or S. It is preferable that the carbon atom that constitutes the ring has a free valence (monovalent) (the heterocyclic group is bonded at the carbon atom). The heterocyclic group preferably has 1 to 40 carbon atoms, more preferably has 1 to 30, and still more preferably has 1 to 20 carbon atoms. Examples of the saturated heterocyclic ring in the heterocyclic group include a pyrrolidine ring, a morpholine ring, a 2-bora-1,3-dioxolane ring, and a 1,3-thiazolidine ring. Examples of the unsaturated heterocyclic ring in the heterocyclic group include an imidazole ring, a thiazole ring, a benzothiazole ring, a benzoxazole ring, a benzotriazole ring, a benzoselenazole ring, a pyridine ring, a pyrimidine ring, and a quinoline ring. The heterocyclic group may have a substituent. Examples of the substituent include groups described in the section of the substituent T described below.

R¹ and R² may be bonded to each other to form a ring. The ring formed by bonding R¹ and R² to each other is preferably a 5-membered or 6-membered ring, which preferably does not exhibit aromaticity. The ring formed by bonding R¹ and R² to each other may have a substituent. Examples of the substituent include groups described in the section of the substituent T described below.

In Formula (1), R³ and R⁶ each independently represent an alkoxy group, an acyloxy group, a carbamoyloxy group, or an alkoxycarbonyloxy group and are preferably an alkoxy group or an acyloxy group. Due to the reason that it is easier to enhance the absorbability of ultraviolet rays in the vicinity of 400 nm while suppressing coloration, it is still more preferable that at least one of R³ or R⁶ is an alkoxy group. From the studies by the inventors of the present invention, it was found that as the substituent on the benzene ring of benzodithiol is a group that exhibits a higher electron donating ability (electron donating property), the maximal absorption wavelength of the compound is more easily shifted to the longer wavelength side. Since the alkoxy group is a substituent having a higher electron donating ability, it is presumed that the maximal absorption wavelength of the compound can be shifted to a longer wavelength side. It is particularly preferable that both R³ and R⁶ represent an alkoxy group.

The alkoxy group represented by R³ and R⁶ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The alkoxy group represented by R³ and R⁶ preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

The carbamoyloxy group represented by R³ and R⁶ preferably has 2 to 30 carbon atoms, more preferably has 2 to 20 carbon atoms, still more preferably has 2 to 15 carbon atoms, particularly preferably has 2 to 10 carbon atoms, and most preferably has 2 to 8 carbon atoms. The carbamoyloxy group may be linear or branched. The carbamoyloxy group may have a substituent. Examples of the substituent include groups described in the section of the substituent T described below.

The alkoxycarbonyloxy group represented by R³ and R⁶ preferably has 2 to 30 carbon atoms, more preferably has 2 to 20 carbon atoms, still more preferably has 2 to 15 carbon atoms, particularly preferably has 2 to 10 carbon atoms, and most preferably has 2 to 8 carbon atoms. The alkoxycarbonyloxy group may be linear or branched. The alkoxycarbonyloxy group may have a substituent. Examples of the substituent include groups described in the section of the substituent T described below.

In Formula (1), R⁴ represents an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group, and R⁵ represents a hydrogen atom, an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

The alkyl group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include the groups described regarding the substituent T described later, and preferred examples thereof include an alkenyl group.

The aryl group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The above-described aryl group is preferably a phenyl group or a naphthyl group, and more preferably a phenyl group. The aryl group may have a substituent. Examples of the substituent include groups described in the section of the substituent T described below.

The alkoxy group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The aryloxy group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The aryloxy group may have a substituent. Examples of the substituent include groups described in the section of the substituent T described below.

The alkoxy group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

The alkylamino group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl moiety in the alkylamino group may be linear or branched. The alkylamino group may have a substituent. Examples of the substituent include groups described in the section of the substituent T described below.

The anilino group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The anilino group may have a substituent. Examples of the substituent include the groups described regarding the substituent T described later, and preferred examples thereof include an alkyl group.

The acylamino group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The acylamino group may have a substituent. Examples of the substituent include groups described in the section of the substituent T described below.

The alkylsulfonylamino group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The alkylsulfonylamino group may have a substituent. Examples of the substituent include groups described in the section of the substituent T described below.

The arylsulfonylamino group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The arylsulfonylamino group may have a substituent. Examples of the substituent include groups described in the section of the substituent T described below.

The alkylthio group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkylthio group may be linear or branched. The alkylthio group may have a substituent. Examples of the substituent include groups described in the section of the substituent T described below.

The arylthio group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The arylthio group may have a substituent. Examples of the substituent include groups described in the section of the substituent T described below.

In Formula (1), R³ and R⁴ may be bonded to each other to form a ring, R⁴ and R⁵ may be bonded to each other to form a ring, and R⁵ and R⁶ may be bonded to each other to form a ring. It is preferable that the ring formed by bonding these groups to each other is a 5- or 6-membered ring. The ring formed by bonding these groups to each other may have a substituent. Examples of the substituent include groups described in the section of the substituent T described below.

Due to the reason that it is easier to enhance the absorbability of ultraviolet rays in the vicinity of 400 nm while suppressing coloration, it is preferable that R⁴ is an alkyl group, an aryl group, an alkoxy group, or an aryloxy group, and R⁵ is a hydrogen atom, an alkyl group, an aryl group, an alkoxy group, or an aryloxy group, and it is more preferable that R⁴ is an alkyl group or an alkoxy group, and R⁵ is a hydrogen atom, an alkyl group, or an alkoxy group.

In addition, from the viewpoint of ease of synthesis, it is preferable that R⁴ is an alkyl group, an aryl group, an alkoxy group, or an aryloxy group, and R⁵ is a hydrogen atom, and it is more preferable that R⁴ is an alkyl group or an alkoxy group, and R⁵ is a hydrogen atom.

In addition, from the viewpoint of lengthening the absorption spectrum, it is preferable that R⁴ and R⁵ are each independently an alkyl group, an aryl group, an alkoxy group, or an aryloxy group, where an alkyl group or an alkoxy group is more preferable, and it is still more preferable that both R⁴ and R⁵ are an alkyl group, or both R⁴ and R⁵ are an alkoxy group.

In addition, it is preferable that R⁴ and R⁵ are bonded to each other to form a ring.

It is preferable that the compound represented by Formula (1) (the compound (1)) is a compound represented by Formula (1a).

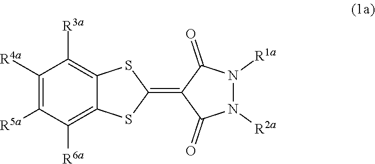

In Formula (1a), R^{1a} and R^{2a} each independently represent an alkyl group,
R^{3a} and R^{6a} each independently represent an alkoxy group or an acyloxy group,
R^{4a} represents an alkyl group or an alkoxy group, and
R^{5a} represents a hydrogen atom, an alkyl group, or an alkoxy group.

R^{1a} and R^{2a} may be bonded to each other to form a ring, R^{3a} and R^{4a} may be bonded to each other to form a ring, R^{4a} and R^{5a} are bonded to each other to form a ring, and R^{5a} and R^{6a} may be bonded to each other to form a ring.

However, in a case where R^{3a} and R^{6a} represent an acyloxy group, at least one of R^{4a} or R^{5a} represents an alkoxy group.

The alkyl group represented by R^{1a} and R^{2a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include groups described in the section of the substituent T described below.

R^{1a} and R^{2a} may be bonded to each other to form a ring. It is preferable that the ring formed by bonding R^{1a} and R^{2a} to each other is a 5- or 6-membered ring. The ring formed by bonding R^{1a} and R^{2a} to each other may have a substituent. Examples of the substituent include groups described in the section of the substituent T described below.

In Formula (1a), R^{3a} and R^{6a} each independently represent an alkoxy group or an acyloxy group. Due to the reason that it is easier to enhance the absorbability of ultraviolet rays in the vicinity of 400 nm while suppressing coloration, it is preferable that at least one of R^{3a} or R^{6a} is an alkoxy group, and it is more preferable that both R^{3a} and R^{6a} represent an alkoxy group.

The alkoxy group represented by R^{3a} and R^{6a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The alkoxy group represented by R^{3a} and R^{6a} preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

In Formula (1a), R^{4a} represents an alkyl group or an alkoxy group, and R^{5a} represents a hydrogen atom, an alkyl group, or an alkoxy group.

The alkyl group represented by R^{4a} and R^{5a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include groups described in the section of the substituent T described below.

The alkoxy group represented by R^{4a} and R^{5a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

In Formula (1a), R^{3a} and R^{4a} may be bonded to each other to form a ring, R^{4a} and R^{5a} are bonded to each other to form a ring, and R^{5a} and R^{6a} may be bonded to each other to form a ring. It is preferable that the ring formed by bonding these groups to each other is a 5- or 6-membered ring. The ring formed by bonding these groups to each other may have a substituent. Examples of the substituent include groups described in the section of the substituent T described below.

### (Substituent T)

Examples of the substituent T include the following groups:
a halogen atom (for example, a chlorine atom, a bromine atom, or an iodine atom),
an alkyl group [a linear, branched, or cyclic alkyl group, specific examples thereof include a linear or branched alkyl group (preferably a linear or branched alkyl group having 1 to 30 carbon atoms, and examples thereof include a methyl group, an ethyl group, an n-propyl group, an isopropyl group, a t-butyl group, an n-octyl group, an eicosyl group, a 2-chloroethyl group, a 2-cyanoethyl group, and a 2-ethylhexyl group), a cycloalkyl group (preferably a cycloalkyl group having 3 to 30 carbon atoms, and examples thereof include a cyclohexyl group, a cyclopentyl group, and a 4-n-dodecylcyclohexyl group), a bicycloalkyl group (preferably a bicycloalkyl group having 5 to 30 carbon atoms, that is, a monovalent group obtained by removing one hydrogen atom from a bicycloalkane having 5 to 30 carbon atoms, examples thereof also include a bicyclo[1,2,2]heptane-2-yl group, a bicyclo[2,2,2]octane-3-yl group), and further, a group obtained by removing one hydrogen atom from a tricycloalkane structure having a large number of ring structures, an alkyl group in a substituent described below (for example,
an alkyl group in an alkylthio group) also represents an alkyl group having such a concept], an alkenyl group [linear, branched, or cyclic alkenyl group, specific examples thereof include a linear or branched alkenyl group (preferably a linear or branched alkenyl group having 2 to 30 carbon atoms, and examples thereof include a vinyl group, an allyl group, a prenyl group, a geranyl group, and an oleyl group), a cycloalkenyl group (preferably a cycloalkenyl group having 3 to 30 carbon atoms, that is, a monovalent group obtained by removing one hydrogen atom from a cycloalkene having 3 to 30 carbon atoms, and examples thereof include a 2-cyclopentene-1-yl group and a 2-cyclohexene-1-yl group), and a bicycloalkenyl group (preferably a bicycloalkenyl group having 5 to 30 carbon atoms, that is, a monovalent group obtained by removing one hydrogen atom from a bicycloalkene having one double bond, and examples thereof include a bicyclo[2,2,1]hepto-2-en-1-yl group and a bicyclo[2,2,2]octo-2-en-4-yl group)],
an alkynyl group (preferably a linear or branched alkynyl group having 2 to 30 carbon atoms, examples thereof include an ethynyl group and a propargyl group),
an aryl group (preferably an aryl group having 6 to 30 carbon atoms, and examples thereof include a phenyl group, a p-tolyl group, a naphthyl group, an m-chlorophenyl group, an o-hexadecanoylaminophenyl group);
a heterocyclic group (preferably a monovalent group obtained by removing one hydrogen atom from a 5- or 6-membered aromatic or non-aromatic heterocyclic compound and more preferably a 5- or 6-membered aromatic heterocyclic group having 3 to 30 carbon atoms, and examples thereof include a 2-furyl group, a 2-thienyl group, a 2-pyrimidinyl group, and a 2-benzothiazolyl group);
a cyano group;
a hydroxy group;
a nitro group;
a carboxy group;
an alkoxy group (preferably a linear or branched alkoxy group having 1 to 30 carbon atoms, and examples thereof include a methoxy group, an ethoxy group, an isopropoxy group, a t-butoxy group, an n-octyloxy group, and a 2-methoxyethoxy group),
an aryloxy group (preferably an aryloxy group having 6 to 30 carbon atoms, and examples thereof include a phenoxy group, a 2-methylphenoxy group, a 4-t-butylphenoxy group, a 3-nitrophenoxy group, and a 2-tetradecanoylaminophenoxy group),
a heterocyclic oxy group (preferably a heterocyclic oxy group having 2 to 30 carbon atoms, and examples thereof include a 1-phenyltetrazole-5-oxy 1 group and a 2-tetrahydropyranyloxy group),
an acyloxy group (preferably a formyloxy group, an alkylcarbonyloxy group having 2 to 30 carbon atoms, or an arylcarbonyloxy group having 6 to 30 carbon atoms, and examples thereof include a formyloxy group, an acetyloxy group, a pivaloyloxy group, a stearoyloxy group, a benzoyloxy group, and a p-methoxyphenylcarbonyloxy group);
a carbamoyloxy group (preferably a carbamoyloxy group having 1 to 30 carbon atoms, and examples thereof include a N,N-dimethylcarbamoyloxy group, a N,N-diethylcarbamoyloxy group, a morpholinocarbonyloxy group, a N,N-di-n-octylaminocarbonyloxy group, and a N-n-octylcarbamoyloxy group),
an alkoxycarbonyloxy group (preferably an alkoxycarbonyloxy group having 2 to 30 carbon atoms, and examples thereof include a methoxycarbonyloxy group, an ethoxycarbonyloxy group, a t-butoxycarbonyloxy group, and an n-octylcarbonyloxy group),
an aryloxycarbonyloxy group (preferably an aryloxycarbonyloxy group having 7 to 30 carbon atoms, and examples thereof include a phenoxycarbonyloxy group, a p-methoxyphenoxycarbonyloxy group, and a p-n-hexadecyloxyphenoxycarbonyloxy group);
an amino group (preferably an unsubstituted amino group (—NH₂), an alkylamino group having 1 to 30 carbon atoms, or an anilino group having 6 to 30 carbon atoms, examples thereof include an unsubstituted amino group (—NH₂), a methylamino group, a dimethylamino group, an anilino group, a N-methyl-anilino group, and a diphenylamino group);
an acylamino group (preferably a formylamino group, an alkylcarbonylamino group having 2 to 30 carbon atoms, or an arylcarbonylamino group having 6 to 30 carbon atoms, and examples thereof include a formylamino group, an acetylamino group, a pivaloylamino group, a lauroylamino group, a benzoylamino group, and a 3,4,5-tri-n-octyloxyphenylcarbonylamino group);
an aminocarbonylamino group (preferably an aminocarbonylamino group having 1 to 30 carbon atoms, and examples thereof include a carbamoylamino group, a N,N-dimethylaminocarbonylamino group, a N,N-diethylaminocarbonylamino group, and a morpholinocarbonylamino group),
an alkoxycarbonylamino group (preferably an alkoxycarbonylamino group having 2 to 30 carbon atoms, and examples thereof include a methoxycarbonylamino group, an ethoxycarbonylamino group, a t-butoxycarbonylamino group, an n-octadecyloxycarbonylamino group, and a N-methyl-methoxycarbonylamino group),
an aryloxycarbonylamino group (preferably an aryloxycarbonylamino group having 7 to 30 carbon atoms, and examples thereof include a phenoxycarbonylamino group, a p-chlorophenoxycarbonylamino group, and an m-n-octyloxyphenoxycarbonylamino group),
a sulfamoylamino group (preferably a sulfamoylamino group having 0 to 30 carbon atoms, and examples thereof sulfamoylamino include a group, a N,N-dimethylaminosulfonylamino group, and a N-n-octylaminosulfonylamino group),
an alkyl or arylsulfonylamino group (preferably an alkyl sulfonylamino group having 1 to 30 carbon atoms or an arylsulfonylamino group having 6 to 30 carbon atoms, and examples thereof include a methylsulfonylamino group, a butylsulfonylamino group, a phenylsulfonylamino group, a 2,3,5-trichlorophenylsulfonylamino group, and a p-methylphenylsulfonylamino group),
a mercapto group,
an alkylthio group (preferably an alkylthio group having 1 to 30 carbon atoms, and examples thereof include a methylthio group, an ethylthio group, and an n-hexadecylthio group),
an arylthio group (preferably an arylthio group having 6 to 30 carbon atoms, and examples thereof include a phenylthio group, a p-chlorophenylthio group, and an m-methoxyphenylthio group),
a heterocyclic thio group (preferably a heterocyclic thio group having 2 to 30 carbon atoms, and examples thereof include a 2-benzothiazolylthio group and a 1-phenyltetrazole-5-ylthio group);
a sulfamoyl group (preferably a sulfamoyl group having 0 to 30 carbon atoms, and examples thereof include a N-ethylsulfamoyl group, a N-(3-dodecyloxypropyl) sulfamoyl group, a N,N-dimethylsulfamoyl group, a N-acetylsulfamoyl group, a N-benzoylsulfamoyl group, a N—(N′-phenylcarbamoyl) sulfamoyl group),
a sulfo group,
an alkyl or arylsulfinyl group (preferably an alkyl sulfinyl group having 1 to 30 carbon atoms or an arylsulfinyl group having 6 to 30 carbon atoms, and examples thereof include a methylsulfinyl group, an ethylsulfinyl group, a phenylsulfinyl group, and a p-methylphenylsulfinyl group),
an alkyl or arylsulfonyl group (preferably an alkylsulfonyl group having 1 to 30 carbon atoms or an arylsulfonyl group having 6 to 30 carbon atoms, and examples thereof include a methylsulfonyl group, an ethylsulfonyl group, a phenylsulfonyl group, and a p-methylphenylsulfonyl group);
an acyl group (preferably a formyl group, an alkylcarbonyl group having 2 to 30 carbon atoms, an arylcarbonyl group having 7 to 30 carbon atoms, or a heterocyclic carbonyl group having 4 to 30 carbon atoms and bonded to a carbonyl group, and examples include an acetyl group, a pivaloyl group, a 2-chloroacetyl group, a stearoyl group, a benzoyl group, a p-n-octyloxyphenylcarbonyl group, a 2-pyridylcarbonyl group, and a 2-furylcarbonyl group),
an aryloxycarbonyl group (preferably an aryloxycarbonyl group having 7 to 30 carbon atoms, and examples thereof include a phenoxycarbonyl group, an o-chlorophenoxycarbonyl group, an m-nitrophenoxycarbonyl group, and a p-t-butylphenoxycarbonyl group),
an alkoxycarbonyl group (preferably an alkoxycarbonyl group having 2 to 30 carbon atoms, and examples thereof include a methoxycarbonyl group, an ethoxycarbonyl group, a t-butoxycarbonyl group, and an n-octadecyloxycarbonyl group);
a carbamoyl group (preferably a carbamoyl group having 1 to 30 carbon atoms, and examples thereof include a carbamoyl group, a N-methylcarbamoyl group, a N,N-dimethylcarbamoyl group, a N,N-di-n-octylcarbamoyl group, and a N-(methylsulfonyl) carbamoyl group),
an aryl or heterocyclic azo group (preferably an arylazo group having 6 to 30 carbon atoms or a heterocyclic azo group having 3 to 30 carbon atoms, and examples thereof include a phenylazo group, a p-chlorophenylazo group, and a 5-ethylthio-1,3,4-thiadiazole-2-ylazo group),
an imide group (preferably a N-succinimide group or a N-phthalimide group),
a phosphino group (preferably a phosphino group having 2 to 30 carbon atoms, and examples thereof include a dimethylphosphino group, a diphenylphosphino group, and a methylphenoxyphosphino group),
a phosphinyl group (preferably a phosphinyl group having 2 to 30 carbon atoms, and examples thereof include a phosphinyl group, a dioctyloxyphosphinyl group, and a diethoxyphosphinyl group),
a phosphinyloxy group (preferably a phosphinyloxy group having 2 to 30 carbon atoms, and examples thereof include a diphenoxyphosphinyloxy group and a dioctyloxyphosphinyloxy group), and
a phosphinylamino group (preferably a phosphinylamino group having 2 to 30 carbon atoms, and examples thereof include a dimethoxyphosphinylamino group and a dimethylaminophosphinylamino group).

Among the groups described above, one or more hydrogen atoms of a group having hydrogen atoms may be substituted with the above-described substituents T. Examples of such substituents include an alkylcarbonylaminosulfonyl group, an arylcarbonylaminosulfonyl group, an alkylsulfonylaminocarbonyl group, and an arylsulfonylaminocarbonyl group. Specific examples include a methylsulfonylaminocarbonyl group, a p-methylphenylsulfonylaminocarbonyl group, an acetylaminosulfonyl group, and a benzoylaminosulfonyl group.

Specific examples of the compound (1) include compounds having the following structures. However, the liquid crystal cell is not limited thereto. In the structural formulae shown below, Me represents a methyl group, Et represents an ethyl group, Bu represents a butyl group, tBu represents a tert-butyl group, Pr represents a propyl group, and Ph represents a phenyl group.

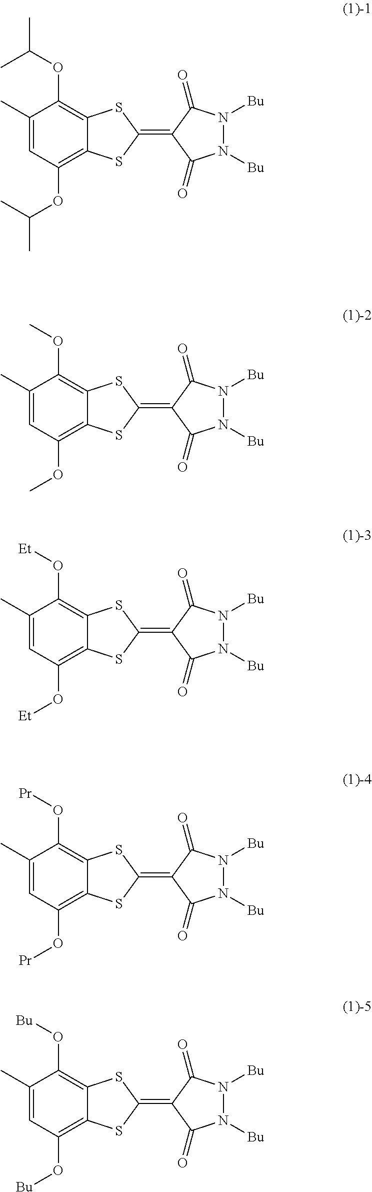

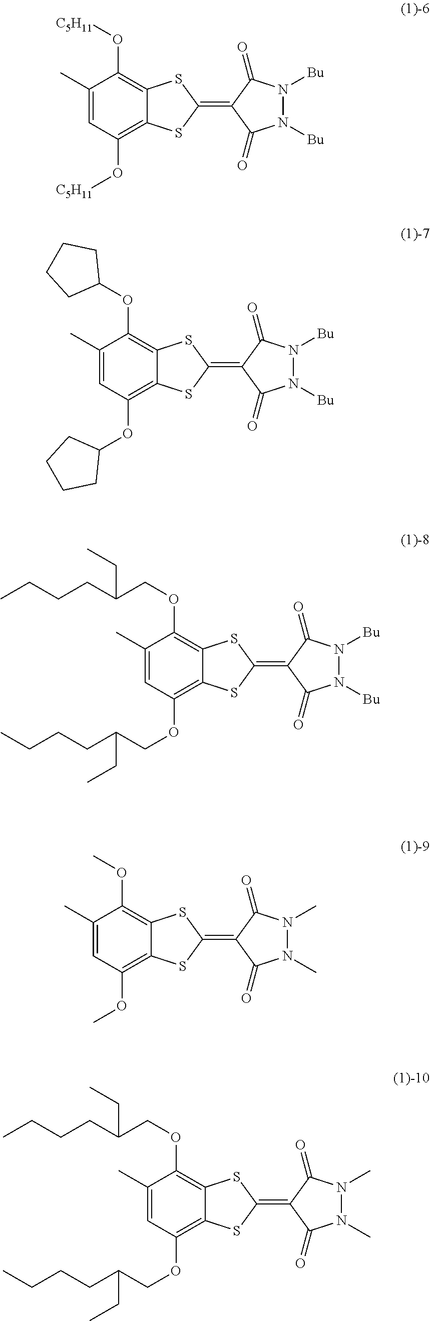

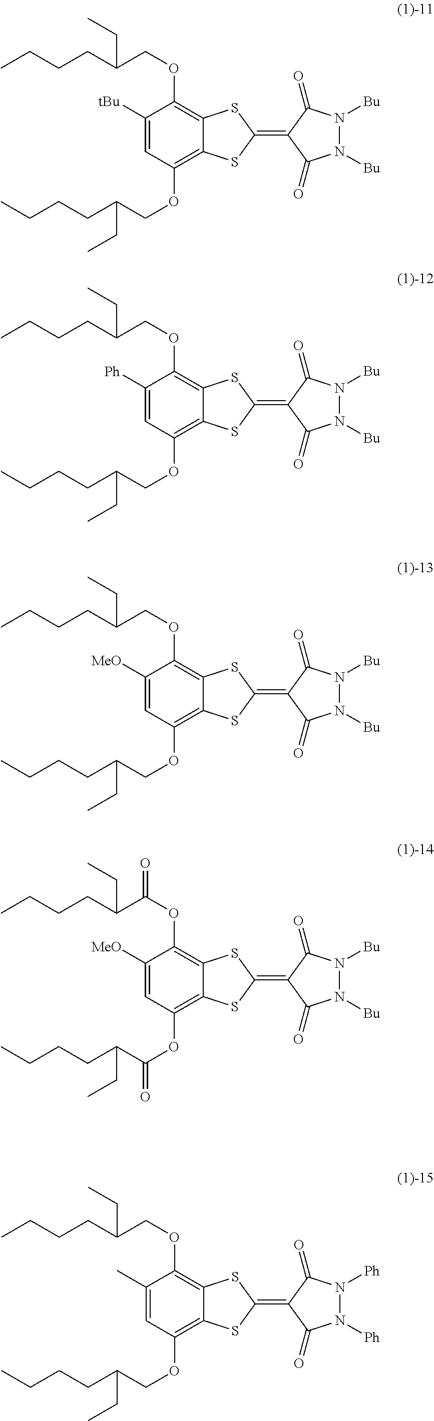

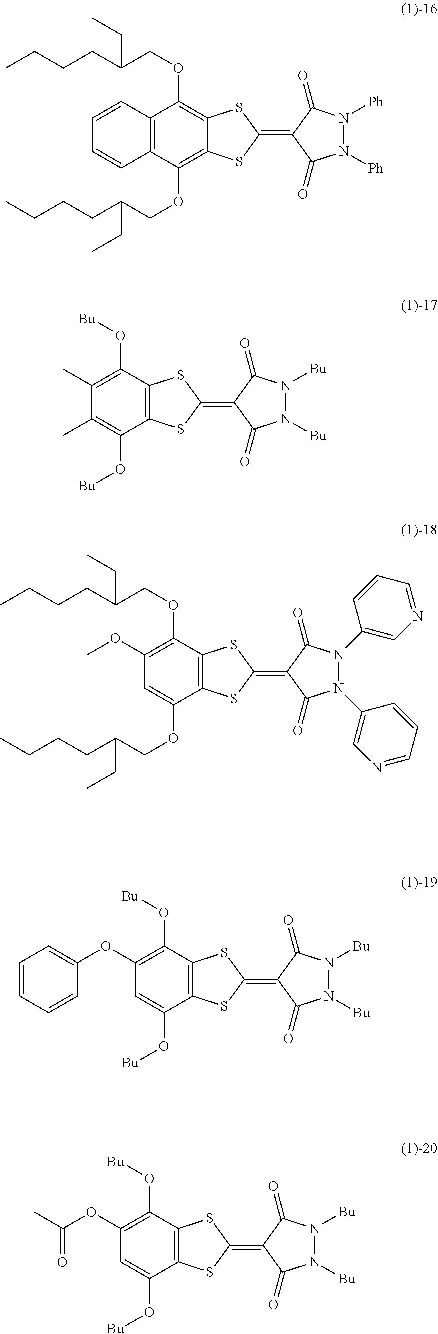

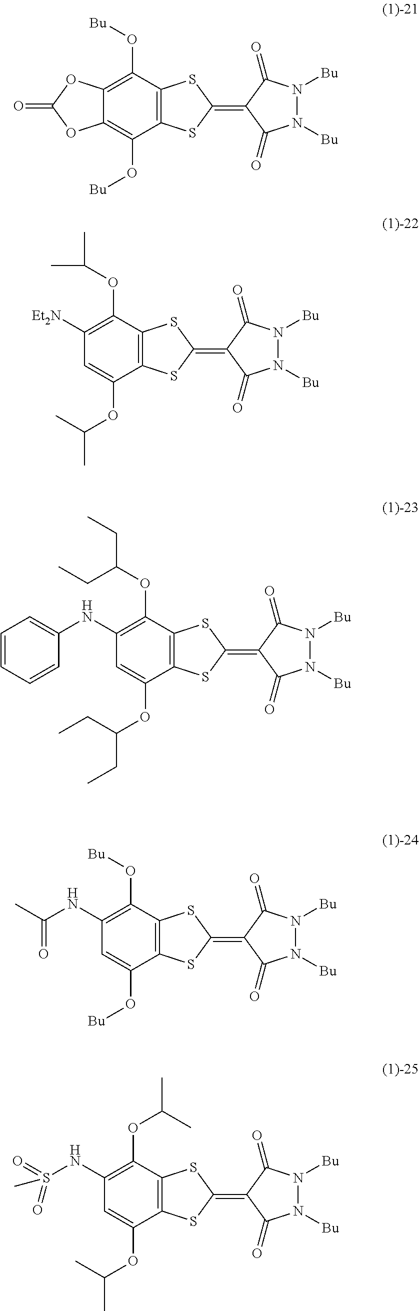

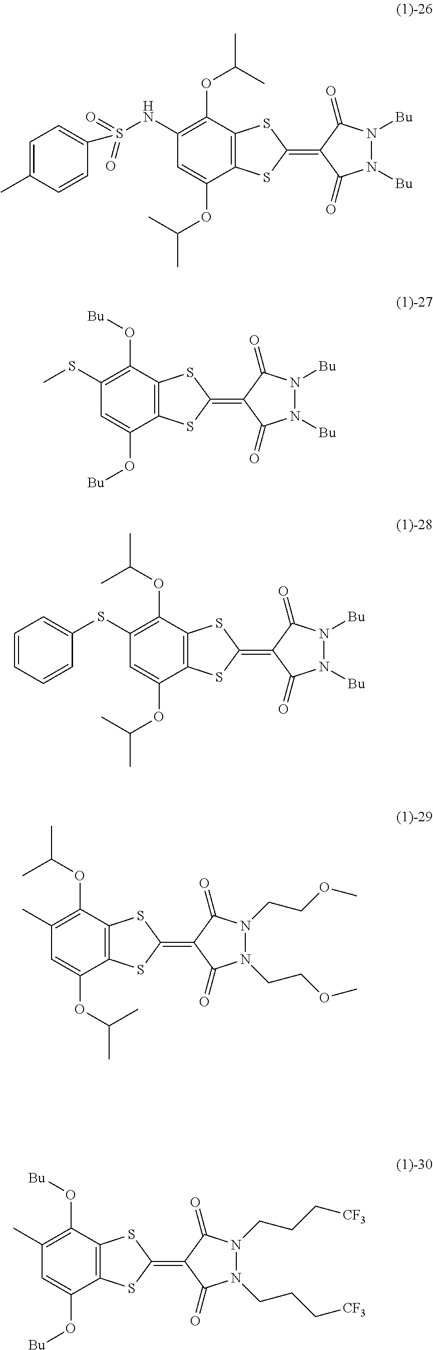

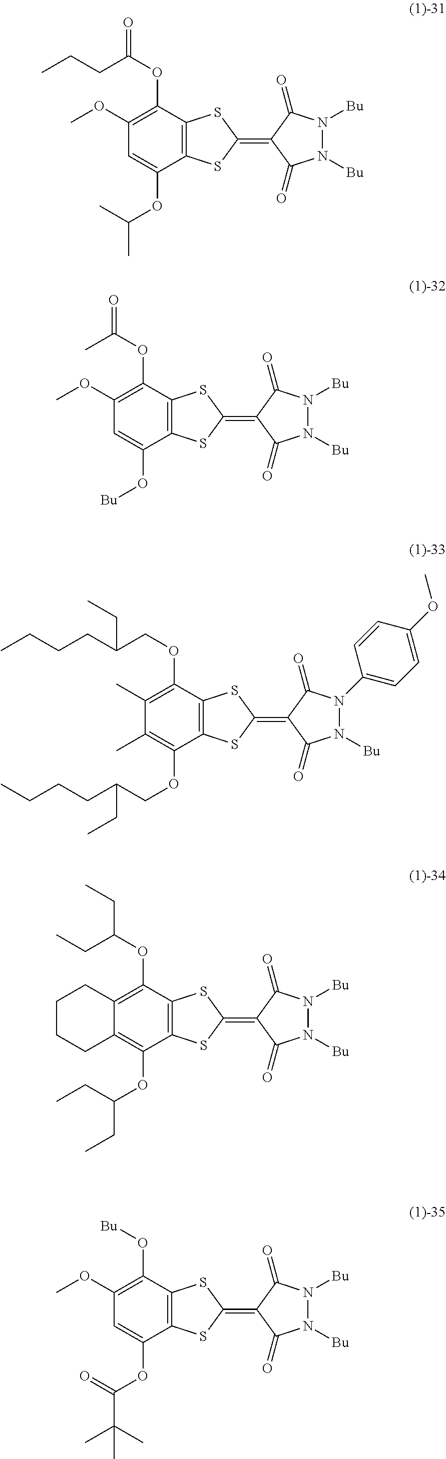

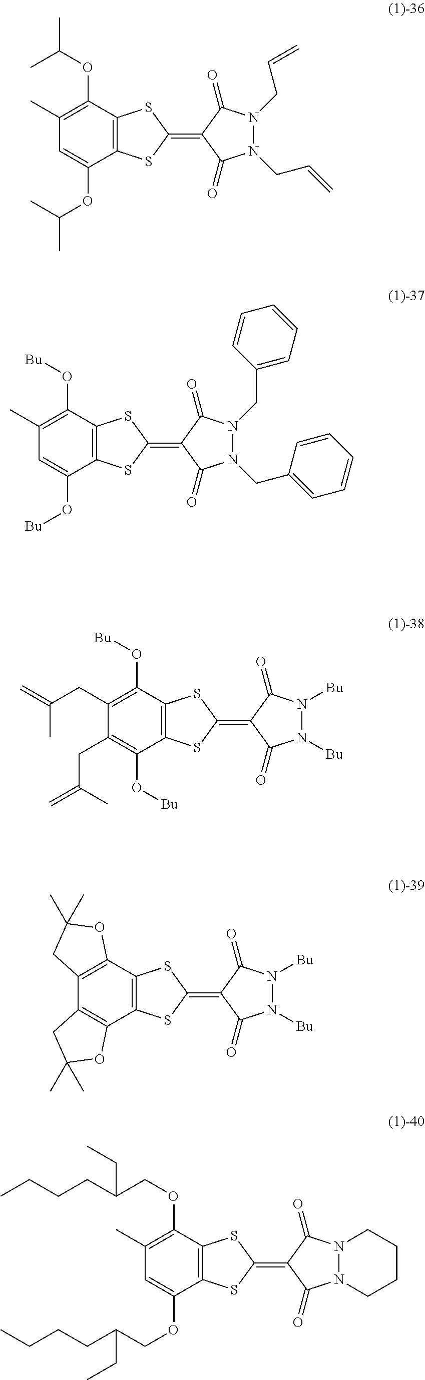

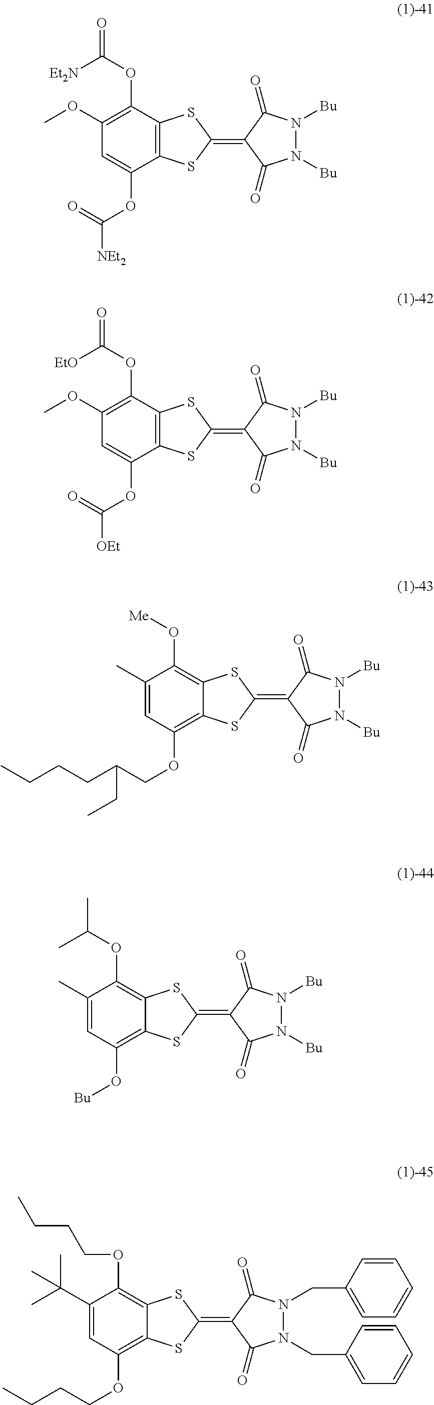

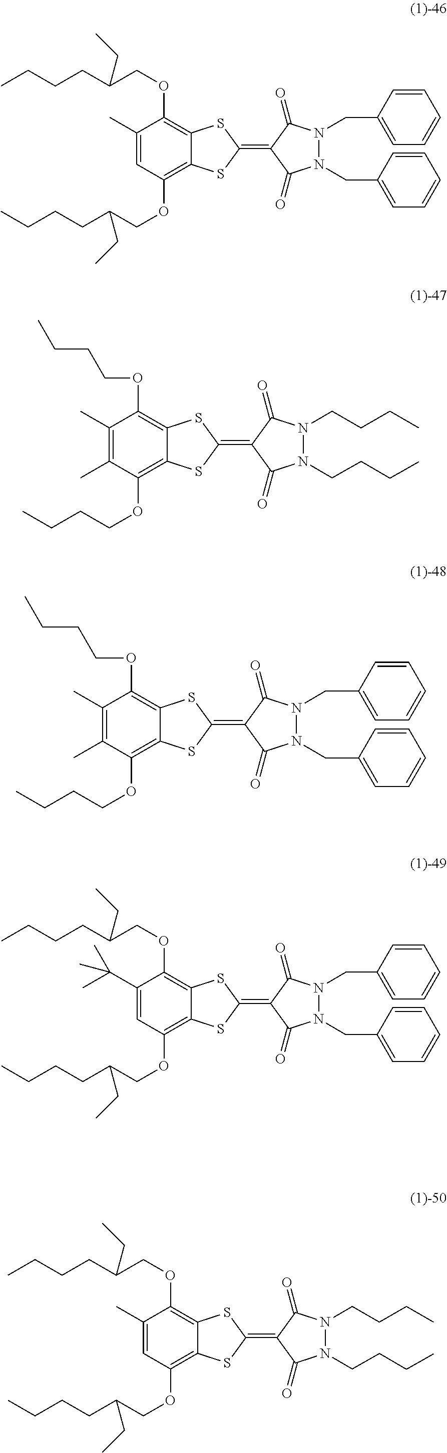

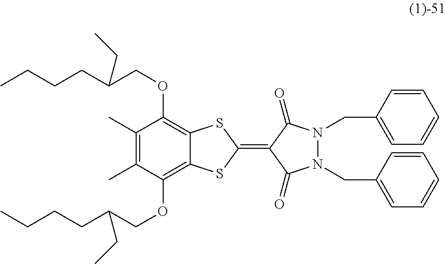 [SMILES: CCCCC(CC)COc1c(C)c(C)c(OCC(CC)CCCC)c2c1SC(=C1C(=O)N(Cc3ccccc3)N(Cc3ccccc3)C1=O)S2]

The compound (1) is preferably used as an ultraviolet absorbing agent. The maximal absorption wavelength of the compound (1) is present preferably in a wavelength range of 370 to 420 nm and more preferably in a wavelength range of 380 to 400 nm.

The molar absorption coefficient 8405 of the compound (1) at a wavelength of 405 nm, which is calculated from the following expression, is preferably 500 or more, more preferably 1,000 or more, still more preferably 2,000 or more, and particularly preferably 3,000 or more.

$${ε}_{405} = {ε}_{max} \times ( {A}_{405} / {A}_{max} )$$

ε₄₀₅ is a molar absorption coefficient of the compound (1) at a wavelength of 405 nm, εₘₐₓ is a molar absorption coefficient of the compound (1) at the maximal absorption wavelength, A₄₀₅ is an absorbance of the compound (1) at a wavelength of 405 nm, and Aₘₐₓ is an absorbance of the compound (1) at the maximal absorption wavelength. It is noted that the unit of the molar absorption coefficient described above is L/(mol cm). A₄₀₅ and Aₘₐₓ shall be an absorbance in a spectral absorption spectrum of the compound (1), which is measured in ethyl acetate.

In the spectral absorption spectrum of the compound (1), which is measured in ethyl acetate, a ratio (A₄₃₀/A₄₀₅) of the absorbance A₄₀₅ at a wavelength 405 nm to the absorbance A₄₃₀ at a wavelength 430 nm is preferably less than 0.13 and more preferably 0.10 or less. The lower limit of the ratio is not particularly limited; however, it can be set to 0 or more. Since a compound having such an absorbance ratio is excellent in light transmittance in a visible range in the vicinity of the ultraviolet range despite high absorption in the vicinity of a wavelength of 405 nm, it has excellent absorbability of ultraviolet rays on the longer wavelength side and has excellent visible transparency. It is noted that in a case where an attempt is made to shift the absorption range of ultraviolet rays in the compound to a longer wavelength side, the transmittance of light in the visible range (in particular, the transmittance of light in the visible range in the vicinity of the ultraviolet range) also tends to decrease; however, according to the compound (1), it is possible to exhibit an excellent effect of improving the absorbability of ultraviolet rays on a longer wavelength side while maintaining the transmittance of light in the visible range at a high level.

The compound (1) can be synthesized with reference to the synthetic methods described in JP2016-081035A, JP5376885B, and the like.

The content of the compound (1) in the total solid content of the resin composition for forming the ultraviolet absorbing layer is preferably in a range of 0.01% to 50% by mass. The lower limit value thereof is preferably 0.05% by mass or more and more preferably 0.10% by mass or more. The upper limit value thereof is more preferably 40% by mass or less, still more preferably 30% by mass or less, and particularly preferably 20% by mass or less.

The content of the compound (1) is preferably 0.01 to 50 parts by mass with respect to 100 parts by mass of the resin. The lower limit thereof is preferably 0.05 parts by mass or more and more preferably 0.10 parts by mass or more. The upper limit value thereof is more preferably 40 parts by mass or less, still more preferably 30 parts by mass or less, and particularly preferably 20 parts by mass or less.

The resin composition may contain only one kind of the compound (1) or may contain two or more types thereof. In a case where the resin composition contains two or more types of the compounds (1), it is preferable that the total amount thereof is in the above-described range.

### (Resin)

As the resin that is used for the ultraviolet absorbing layer, a known resin can be used, which is not particularly limited as long as it does not contradict the gist of the present invention. Examples of the resin include a cellulose acylate resin, an acrylic resin, a cycloolefin-based resin, a polyester-based resin, and an epoxy resin.

### (Installation Position of Ultraviolet Absorbing Layer)

The disposition of the ultraviolet absorbing layer is not particularly limited as long as it is on the viewer side with respect to the optical filter according to the embodiment of the present invention, and the ultraviolet absorbing layer can be installed at any position. For example, it is also possible to add an ultraviolet absorbing agent to a member such as a protective film of the polarizing plate, an antireflection film, or the like to impart it a function of an ultraviolet absorbing layer. In addition, an ultraviolet absorbing agent can also be added to the above-described pressure-sensitive adhesive layer.

### EXAMPLES

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified. Room temperature means “25° C.”.

In the following examples, the “base material” means the “support” defined in the present invention.

All steps from a preparation step of a dye layer forming liquid to a production step of a base material-attached light absorption filter using the dye layer forming liquid and to the use thereof in the ultraviolet irradiation test were carried out under a yellow lamp to avoid ultraviolet irradiation.

### [Production of Light Absorption Filter]

Materials used to produce the light absorption filter are shown below.

### <Matrix Polymer (Resin)>

### (Resin 1)

A cyclohexyl methacrylate-methacrylic acid random copolymer, methacrylic acid content: 29% by mole, weight-average molecular weight: 26300.

It is noted that the methacrylic acid moiety of the resin 1 corresponds to the compound A having an acid group defined in the present invention.

### (Resin 2)

Adamantyl methacrylate-acrylic acid random copolymer, acrylic acid content: 52 mol %, weight-average molecular weight: 46300.

It is noted that the acrylic acid moiety of the resin 2 corresponds to the compound A having an acid group defined in the present invention.

### (Resin 3)

Dicyclopentanyl methacrylate-acrylic acid random copolymer, acrylic acid content: 52 mol %, weight-average molecular weight: 32700.

It is noted that the acrylic acid moiety of the resin 3 corresponds to the compound A having an acid group defined in the present invention.

### <Compound B>

4-methylquinoline (manufactured by Tokyo Chemical Industry Co., Ltd., Lepidine, pKaH: 5.1)

### <Dye>

In the structural formulae described below, Bu represents a butyl group.

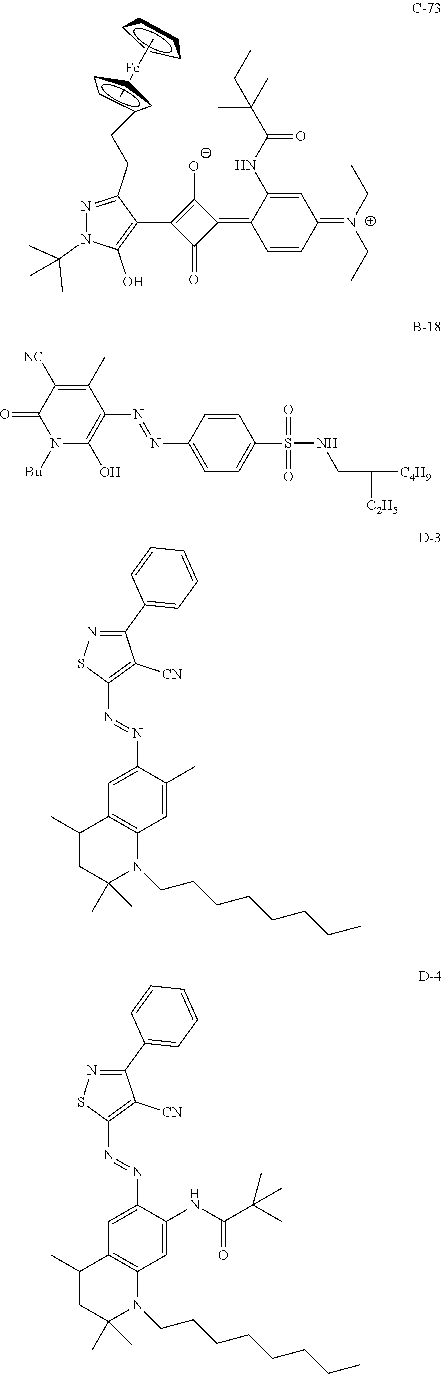

### (Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

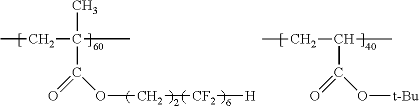

### (Base Material 1)

A cellulose acylate film (manufactured by FUJIFILM Corporation, product name: ZRD40SL)

### (Base Material 2)

The resin 1 was immersed in a 2.3 mol/L sodium hydroxide aqueous solution at 55° C. for 3 minutes. Washing was carried out in a water washing bath at room temperature (25° C.), and neutralization was carried out at 30° C. with 0.05 mol/L sulfuric acid. Washing was carried out again in a water washing bath at room temperature (25° C.), and drying was carried out with warm air at 100° C. A cellulose acylate film subjected to the saponification treatment in this way was used as a base material 2.

### (Base Material 5)

Cellulose acylate film (manufactured by FUJIFILM Corporation, product name: TG40UL)

### Example 1

<1. Production of Base Material 2 with Diffusion Inhibiting Layer>

### (1) Preparation of Diffusion Inhibiting Layer Forming Liquid A

Each component was mixed with the composition shown below, and the mixture was stirred in a constant-temperature tank at 90° C. for 1 hour to dissolve Kuraray Poval 5-98 (product name, manufactured by Kuraray Co., Ltd., polyvinyl alcohol, saponification degree: 98% to 99 mol %, δt value=28.8), thereby preparing a diffusion inhibiting layer forming liquid A.

Composition of diffusion inhibiting layer forming liquid A

| | |
|---|---|
| KURARAY POVAL 5-98 (product name, | 4.0 parts by mass |
| manufactured by Kuraray Co., Ltd.) | |
| Pure water | 88.5 parts by mass |
| Isopropyl alcohol | 7.5 parts by mass |

Subsequently, the obtained diffusion inhibiting layer forming liquid A was filtered using a filter having an absolute filtration precision of 5 μm (product name: Hydrophobic Fluorepore Membrane, manufactured by Millex).

### (2) Production of Diffusion Inhibiting Layer

The base material 2 was coated with the diffusion inhibiting layer forming liquid A after the filtration treatment using a bar coater such that the film thickness after drying was 1.6 μm, and dried at 130° C. for 60 seconds to produce a base material 2 with a diffusion inhibiting layer.

### <2. Production of Light Absorption Filter No. 101>

### (1) Preparation of Resin Solution (Dye Layer Forming Liquid)

A dye layer forming liquid (composition) Ba-1 was prepared by mixing each component with the composition shown below.

Composition of dye layer forming liquid Ba-1

| | |
|---|---|
| Resin 1 | 81.1 parts by mass |
| Leveling agent 1 | 0.08 parts by mass |
| Dye C-73 | 1.57 parts by mass |
| 4-methylquinoline (manufactured by | 17.2 parts by mass |
| Tokyo Chemical Industry Co., Ltd.) | |
| Toluene (solvent, δt value = 20.7) | 510.0 parts by mass |
| Cyclohexanone (solvent, δt value = 22.1) | 56.7 parts by mass |

Subsequently, the obtained light dye layer forming liquid Ba-1 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Light Absorption Filter

The dye layer forming liquid Ba-1 after the filtration treatment was applied onto the diffusion inhibiting layer of the base material 2 with a diffusion inhibiting layer using a bar coater such that the film thickness after drying was 2.5 μm, and dried at 120° C. to produce a dye layer, thereby producing a light absorption filter No. 101.

<3. Production of Light Absorption Filter No. c201>

A light absorption filter No. c201 was produced in the same manner as in the production of the light absorption filter No. 101, except that in the production of the light absorption filter No. 101, the dye layer was produced by directly applying the dye layer forming liquid Ba-1 onto the base material 1 without the diffusion inhibiting layer.

<4. Production of Light Absorption Filter No. r202>

A light absorption filter No. r202 was produced in the same manner as in the production of the light absorption filter No. 101, except that, in the production of the light absorption filter No. 101, the dye C-73 and 4-methylquinoline in the dye layer forming liquid Ba-1 were excluded.

<5. Production of Light Absorption Filter No. r203>

A light absorption filter No. r203 was produced in the same manner as in the production of the light absorption filter No. c201, except that, in the production of the light absorption filter No. c201, the dye C-73 and 4-methylquinoline in the dye layer forming liquid Ba-1 were excluded.

<6. Production of Light Absorption Filter No. c204>

A light absorption filter No. c204 was produced in the same manner as in the production of the light absorption filter No. 101, except that in the production of the light absorption filter No. 101, the dye layer was produced by directly applying the dye layer forming liquid Ba-1 onto the base material 2 without the diffusion inhibiting layer.

Here, No. 101 is the light absorption filter according to the embodiment of the present invention, Nos. c201 and c204 are light absorption filters for comparison, and Nos. r202 to r203 are light absorption filters for reference.

### [Production of Light Absorption Filter Having Gas Barrier Layer]

Regarding the light absorption filters Nos. 101, c201, r202, r203, and c204, a light absorption filter (light absorption filter having a gas barrier layer) in which a gas barrier layer is further laminated on the dye layer of the light absorption filter was produced as follows, and the evaluation described later was performed.

### (1) Production of Base Material 3

The dye layer side of the base material-attached light absorption filter was subjected to a corona treatment using a corona treatment device (product name: Corona-Plus, manufactured by VETAPHONE) under the conditions of a discharge amount of 1,000 W·min/m² and a processing speed of 3.2 m/min and used as a base material 3.

### (2) Preparation of Resin Solution

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98 to 99 mol %), whereby a gas barrier layer forming liquid was prepared.

Composition of gas barrier layer forming liquid

| | |
|---|---|
| Kuraray Exceval AQ-4105 (product name, | 4.0 parts by mass |
| manufactured by KURARAY Co., Ltd.) | |
| Pure water | 88.5 parts by mass |
| Isopropyl alcohol | 7.5 parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied to the corona-treated surface (dye layer) side of the base material 3 using a bar coater so that the film thickness after drying was 1.6 μm, and dried at 120° C. for 60 seconds, whereby a light absorption filter having a gas barrier layer was produced.

The light absorption filter having a gas barrier layer has a configuration in which the base material 1 or base material 2, the diffusion inhibiting layer, the dye layer, and the gas barrier layer are laminated in this order. However, the light absorption filters Nos. c201 and c204 do not have a diffusion inhibiting layer.

### <Absorbance of Light Absorption Filter (Before Ultraviolet Irradiation)>

### (1) Measurement of Absorbance

Using a UV3600 spectrophotometer (product name) manufactured by Shimadzu Corporation, the absorbance of the light absorption filter having a gas barrier layer and the standard filter in a wavelength range of 380 to 800 nm was measured for every 1 nm. It is noted that the optical path length is 2.5 μm.

The standard filter for the light absorption filters Nos. 101 and c204 is a light absorption filter No. r202 which has been changed not to contain the dye and the compound B.

The standard filter for the light absorption filter No. c201 is a light absorption filter No. r203 which has been changed not to contain the dye and the compound B.

### (2) Calculation of Absorbance

Using the absorbance value Abₓ(λ) of the light absorption filter having a gas barrier layer at each wavelength λ nm measured as described above and the absorbance value Ab₀(λ) of the corresponding standard filter at each wavelength λ nm, the absorbance Ab(λ) of the light absorption filter before ultraviolet irradiation was calculated according to the following expression.

$$Ab ( λ ) = {Ab}_{x} ( λ ) - {Ab}_{0} ( λ )$$

Hereinafter, among the absorbances Ab(λ) of the light absorption filter in a wavelength range of 400 to 700 nm, the wavelength at which the highest absorbance Ab(λ) among the wavelengths at which the highest maximal absorption is exhibited was defined as the maximal absorption wavelength (hereinafter, also simply referred to as “λₘₐₓ”), and the absorbance at λₘₐₓ was defined as the absorption maximal value (hereinafter, also simply referred to as “Ab(λₘₐₓ)”). The λₘₐₓ of the dye C-73 is 591 nm.

### <<Evaluation 1>>

The decolorization rate of each light absorption filter was evaluated.

The results are shown in Table 1 below.

### (Ultraviolet Irradiation Test)

Using an ultra-high pressure mercury lamp (manufactured by HOYA Corporation, product name: UL750) under atmospheric pressure (101.33 kPa), the light absorption filter having a gas barrier layer and the standard filter were irradiated at room temperature with an ultraviolet ray (UV) at an illuminance of 100 mW/cm² and an irradiation amount of 750 mJ/cm² from the dye layer side (the side opposite to base material 1 or the base material 2).

<Absorbance of Light Absorption Filter (after Ultraviolet Irradiation)>

Using the light absorption filter having a gas barrier layer after ultraviolet irradiation and the standard filter, the absorbance Ab(λ) of the light absorption filter after ultraviolet irradiation was calculated according to the same method as described in <Absorbance of light absorption filter (before ultraviolet irradiation)> described above.

### [1. Evaluation of Decolorization Rate]

The decolorization rate was calculated according to the following expression using the maximal absorption values (Ab(λₘₐₓ)) before and after the ultraviolet irradiation test.

$$Decolorization rate ( \% ) = 100 - [ ( Ab ( {λ}_{max} ) after ultraviolet irradiation / Ab ( {λ}_{max} ) before ultraviolet irradiation ) \times 100 \% ]$$

[2. Absorption (Secondary Absorption) Derived from New Coloration Structure, Associated with Decomposition of Coloring Agent]

It is noted that in the light absorption filter No. 101, a value obtained by subtracting the ratio of (I) from the ratio of (II), which is defined in the above-described paragraph [0152], was 5.0% or less, and the secondary absorption associated with the decomposition of the dye upon ultraviolet irradiation was suppressed.

TABLE 1

| | | Thickness of | Decolorization |
|---|---|---|---|
| | Light absorption | diffusion | rate |
| | filter No. | inhibiting layer | @750 mJ/cm² |
| Example 101 | Light absorption | 1.6 μm | 99% |
| | filter 101 | | |
| Comparative | Light absorption | None | 70% |
| Example c201 | filter c201 | | |
| Comparative | Light absorption | None | 70% |
| Example c204 | filter c204 | | |

From the results in Table 1, it can be seen that the light absorption filter No. 101 according to the embodiment of the present invention, which has a diffusion inhibiting layer, exhibits an excellent decolorization rate with respect to the light absorption filters Nos. c201 and c204 of Comparative Examples, which do not have a diffusion inhibiting layer, and is excellent in decolorizing property by irradiation with UV light.

### Example 2

<1. Production of Base Material 5 with Diffusion Inhibiting Layer>

(1) Preparation of diffusion inhibiting layer forming liquid B Each component was mixed with the composition shown below, and the mixture was stirred in a constant-temperature tank at 50° C. for 1 hour to dissolve poly(methacrylic acid) (manufactured by FUJIFILM Wako Pure Chemical Corporation, weight-average molecular weight: 100000, δt value=19.0), thereby preparing a diffusion inhibiting layer forming liquid B.

Composition of diffusion inhibiting layer forming liquid B

| | |
|---|---|
| Poly(methacrylic acid) (manufactured by FUJIFILM | 4.0 parts by mass |
| Wako Pure Chemical Corporation, weight- | |
| average molecular weight: 100000) | |
| Pure water | 60.0 parts by mass |
| Ethanol | 36.0 parts by mass |

Subsequently, the obtained diffusion inhibiting layer forming liquid B was filtered using a filter having an absolute filtration precision of 5 μm (product name: Hydrophobic Fluorepore Membrane, manufactured by Millex).

### (2) Production of Diffusion Inhibiting Layer

The base material 5 was coated with the diffusion inhibiting layer forming liquid B after the filtration treatment using a bar coater such that the film thickness after drying was 0.9 μm, and dried at 120° C. for 60 seconds to produce a base material 5 with a diffusion inhibiting layer.

### <2. Production of Light Absorption Filter No. 301>

### (1) Preparation of Resin Solution (Dye Layer Forming Liquid)

A dye layer forming liquid (composition) Ba-2 was prepared by mixing each component with the composition shown below.

Composition of dye layer forming liquid Ba-2

| | |
|---|---|
| Resin 2 | 76.8 parts by mass |
| Leveling agent 1 | 0.08 parts by mass |
| Dye D-3 | 3.05 parts by mass |
| Dye B-18 | 2.85 parts by mass |
| 4-methylquinoline (manufactured by | 17.2 parts by mass |
| Tokyo Chemical Industry Co., Ltd.) | |
| Tetrahydrofuran (solvent, δt value = 23.6) | 566.7 parts by mass |

Subsequently, the obtained light dye layer forming liquid Ba-2 was filtered using a filter paper (#63, manufactured by Toyo Roshi Kaisha, Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Light Absorption Filter

The dye layer forming liquid Ba-2 after the filtration treatment was applied onto the diffusion inhibiting layer of the base material 5 with a diffusion inhibiting layer using a bar coater such that the film thickness after drying was 2.5 μm, and dried at 130° C., thereby producing a light absorption filter No. 301.

<3. Production of Light Absorption Filters Nos. 302, 303, r401, and r402>

A light absorption filter No. 302 according to the embodiment of the present invention was produced in the same manner as in the production of the light absorption filter No. 301, except that in the production of the light absorption filter No. 301, the poly(methacrylic acid) added to the diffusion inhibiting layer was changed to an equal part by mass of Kuraray Poval 5-98 (product name, manufactured by Kuraray Co., Ltd., polyvinyl alcohol, δt value=28.8).

In addition, a light absorption filter No. 303 was produced in the same manner as in the production of the light absorption filter No. 301, except that, in the production of the light absorption filter No. 301, the dye D-3 of Ba-2 in the dye layer forming liquid was changed to the dye D-4 in an equimolar amount, the resin 2 was changed to the resin 3 in terms of an equal part by mass, and the drying temperature after the application of the dye layer forming liquid was changed to 110° C.

In addition, a light absorption filter No. r401 was produced in the same manner as in the production of the light absorption filter No. 301, except that in the production of the light absorption filter No. 301, the dye D-3 and the dye B-18 in Ba-2 in the dye layer forming liquid, and 4-methylquinoline were removed.

Further, a light absorption filter No. r402 was produced in the same manner as in the production of the light absorption filter No. 302, except that in the production of the light absorption filter No. 302, the dye D-3 and the dye B-18 in the dye layer forming liquid Ba-2, and 4-methylquinoline were removed.

In addition, a light absorption filter No. r404 was produced in the same manner as in the production of the light absorption filter No. 303, except that in the production of the light absorption filter No. 303, the dye D-4 and the dye B-18 in the dye layer forming liquid Ba-2, and 4-methylquinoline were removed.

Here, Nos. 301 to 303 are the light absorption filters according to the embodiment of the present invention, and Nos. r401, r402, and r404 are light absorption filters for reference.

<4. Production of Light Absorption Filter No. c403>

A light absorption filter No. c403 for comparison was produced in the same manner as in the production of the light absorption filter No. 301, except that in the production of the light absorption filter No. 301, the dye layer was produced by directly applying the dye layer forming liquid Ba-2 onto the base material 5 without the diffusion inhibiting layer.

### [Production of Light Absorption Filter Having Gas Barrier Layer]

Regarding the light absorption filters Nos. 301 to 303, r401, r402, r404, and c403, a light absorption filter (light absorption filter having a gas barrier layer) in which a gas barrier layer is further laminated on the dye layer of the light absorption filter was produced as follows, and the evaluation described later was performed.

### (1) Preparation of Resin Solution

Each component was mixed with the composition shown below, stirred in a constant-temperature tank at 90° C. for 1 hour, and then cooled to room temperature after dissolving Kuraray Exceval AQ-4105 (product name, manufactured by Kuraray Co., Ltd., modified polyvinyl alcohol, saponification degree: 98% to 99 mol %), and polyethyleneimine (manufactured by FUJIFILM Wako Pure Chemical Corporation, weight-average molecular weight: about 10000) was added thereto to prepare a gas barrier layer forming liquid.

Composition of gas barrier layer forming liquid

| | |
|---|---|
| Kuraray Exceval AQ-4105 (product name, | 3.6 parts by mass |
| manufactured by KURARAY Co., Ltd.) | |
| Polyethyleneimine (manufactured by FUJIFILM | 0.4 parts by mass |
| Wako Pure Chemical Corporation, weight- | |
| average molecular weight: about 10000) | |
| Pure water | 88.5 parts by mass |
| Isopropyl alcohol | 7.5 parts by mass |

Subsequently, the obtained gas barrier layer forming liquid was filtered using a filter having an absolute filtration precision of 5 μm (product name: Hydrophobic Fluorepore Membrane, manufactured by Millex).

### (2) Lamination of Gas Barrier Layer

The gas barrier layer forming liquid after the filtration treatment was applied to the dye layer side of the light absorption filter using a bar coater such that the film thickness after drying was 0.6 μm, and dried at 130° C. for 60 seconds, thereby preparing a light absorption filter having a gas barrier layer.

The light absorption filter having a gas barrier layer has a configuration in which the base material 5, the diffusion inhibiting layer, the dye layer, and the gas barrier layer are laminated in this order. However, the light absorption filter No. c403 does not have a diffusion inhibiting layer.

### <Absorbance of Light Absorption Filter (Before Ultraviolet Irradiation)>

In the same manner as in Example 1, the absorbance in a wavelength range of 380 to 800 nm was measured for every 1 nm, and the absorbance Ab(λ) of the light absorption filter before ultraviolet irradiation was calculated.

The standard filter for the light absorption filters Nos. 301 and c403 is a light absorption filter No. r401 which has been changed not to contain the dye and the compound B, and the standard filter for the light absorption filter No. 302 is a light absorption filter No. r402 which has been changed not to contain the dye and the compound B. In addition, the standard filter for the light absorption filter No. 303 is a light absorption filter No. r404 which has been changed not to contain the dye and the compound B.

The λₘₐₓ of the dye B-18 is 435 nm, the λₘₐₓ of the dye D-3 is 578 nm, and the λₘₐₓ of the dye D-3 is 578 nm.

### <<Evaluation 1>>

The decolorization rate and the adhesiveness of each light absorption filter were evaluated.

The results are shown in Table 2 below.

### (Ultraviolet Irradiation Test)

An ultraviolet irradiation test was performed in the same manner as in Example 1, except that the irradiation amount of ultraviolet rays was changed to 2000 mJ/cm².

<Absorbance of Light Absorption Filter (after Ultraviolet Irradiation)>

Using the light absorption filter having a gas barrier layer after ultraviolet irradiation and the standard filter, the absorbance Ab(λ) of the light absorption filter after ultraviolet irradiation was calculated according to the same method as described in <Absorbance of light absorption filter (before ultraviolet irradiation)> described above.

### [1. Evaluation of Decolorization Rate]

The decolorization rate was calculated according to the following expression using the maximal absorption values (Ab(λₘₐₓ)) before and after the ultraviolet irradiation test.

$$Decolorization rate ( \% ) = 100 - [ ( Ab ( {λ}_{max} ) after ultraviolet irradiation / Ab ( {λ}_{max} ) before ultraviolet irradiation ) \times 100 \% ]$$

[2. Absorption (Secondary Absorption) Derived from New Coloration Structure, Associated With Decomposition of Coloring Agent]

It is noted that in the light absorption filters Nos. 301 to 303, a value obtained by subtracting the ratio of (I) from the ratio of (II), which is defined in the above-described paragraph [0152], was 5.0% or less, and the secondary absorption associated with the decomposition of the dye upon ultraviolet irradiation was suppressed.

### [3. Adhesiveness]

A light absorption filter having a gas barrier layer was cut into a size of a width of 25 mm and a length of 150 mm, and the gas barrier layer side of the light absorption filter was bonded to glass through a pressure sensitive adhesive (product name: SK2057, manufactured by Soken Chemical & Engineering Co., Ltd.) having a width of 30 mm and a length of 100 mm, thereby preparing an adhesiveness evaluation film. In the light absorption filter having a gas barrier layer, the size of the bonding surface between the pressure sensitive adhesive and the light absorption filter having a gas barrier layer was 25 mm in width and 100 mm in length, and the pressure sensitive adhesive and the glass were bonded to each other to protrude (not bonded to the pressure sensitive adhesive) by 25 mm in width and 50 mm in length.

Subsequently, a 90-degree peeling test was performed at a peeling rate of 300 mm/sec under a condition of 25° C. according to JIS standard: JIS Z-0237 (2009). Specifically, in the adhesiveness evaluation film obtained as described above, a cut was made with a cutter at a boundary portion between a portion of the light absorption filter having a gas barrier layer, which was bonded to the pressure sensitive adhesive, and a portion of the light absorption filter having a gas barrier layer, which was not bonded to the pressure sensitive adhesive, from the gas barrier layer side to the layer (diffusion inhibiting layer in the light absorption filters Nos. 301 to 303 and dye layer in the light absorption filter No. c403) in front of the base material such that the cut did not reach the base material, the cut having a width of 25 mm. A portion of the light absorption filter having a gas barrier layer that was not bonded to the glass was gripped, and a portion of the light absorption filter having a gas barrier layer that was bonded to the glass was peeled off by 50 mm in a direction perpendicular to the glass surface toward a side opposite to the glass side, and the peeling force at that time was measured with a tensile tester.

In the above test, an average value (average peeling force) of the peeling forces from a position where 20 mm peeling was performed to a position where 50 mm peeling was performed was calculated, and the adhesiveness was evaluated according to the following standard based on the average peeling force.

The adhesiveness between the glass and the gas barrier layer in the light absorption filter due to the pressure sensitive adhesive is sufficiently higher than the adhesiveness between each layer constituting the light absorption filter, and the average peeling force obtained by the above test is the peeling force between two layers that are most easily peeled off among each layer constituting the light absorption filter.

### -Evaluation Standards-

A: average peeling force was 5 N/25 mm or more.
B: average peeling force was 2 N/25 mm or more and less than 5 N/25 mm.
C: average peeling force was less than 2 N/25 mm.

TABLE 2

| | | Thickness of | | |
|---|---|---|---|---|
| | | diffusion | Decolorization | |
| | Light absorption | inhibiting | rate | |
| | filter No. | layer | @2000 mJ/cm² | Adhesiveness |
| Example 301 | Light absorption | 0.9 μm | 90% | A |
| | filter 301 | | | |
| Example 302 | Light absorption | 0.9 μm | 92% | C |
| | filter 302 | | | |
| Example 303 | Light absorption | 0.9 μm | 92% | A |
| | filter 303 | | | |
| Comparative | Light absorption | None | 70% | B |
| Example c403 | filter c403 | | | |

From the results in Table 2, it can be seen that the light absorption filters Nos. 301 to 303 according to the embodiment of the present invention, which have a diffusion inhibiting layer, exhibit an excellent decolorization rate with respect to the light absorption filter No. c403 of Comparative Example, which does not have a diffusion inhibiting layer, and are excellent in decolorizing property by irradiation with UV light.

In addition, the light absorption filters Nos. 301 and 303 according to the embodiment of the present invention, in which the resin constituting the diffusion inhibiting layer is poly(methacrylic acid), are preferable from the viewpoint that the adhesiveness between each layer is excellent with respect to the light absorption filter No. 302 according to the embodiment of the present invention, in which the resin constituting the diffusion inhibiting layer is polyvinyl alcohol, and exhibit excellent adhesiveness as compared with the light absorption filter No. c403 of Comparative Example, which does not contain the diffusion inhibiting layer.

### Reference Example

### [Production of Light Absorption Filter]

Materials used to produce the light absorption filter are shown below. The materials and filters Nos. in this paragraph and the following paragraphs are applied in the Reference Examples described in this paragraph and the following paragraphs.

### <Matrix Polymer (Resin)>

### (Resin 1)

A cyclohexyl methacrylate-methacrylic acid random copolymer, methacrylic acid content: 29% by mole, weight-average molecular weight: 26300.

It is noted that the methacrylic acid moiety of the resin 1 corresponds to the compound A having an acid group defined in the present invention.

### <Compound B>

4-methylquinoline (manufactured by Tokyo Chemical Industry Co., Ltd., Lepidine, pKaH: 5.1)

### <Dye>

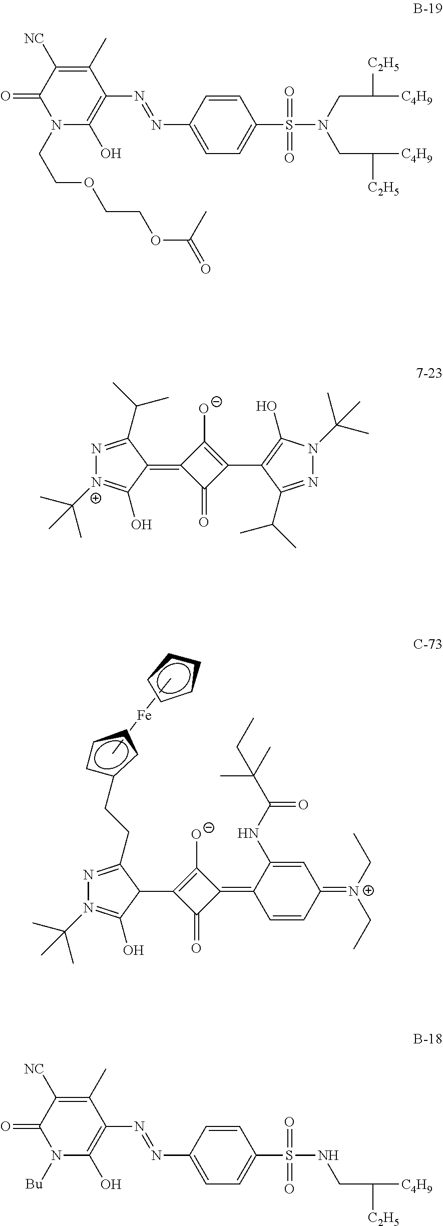

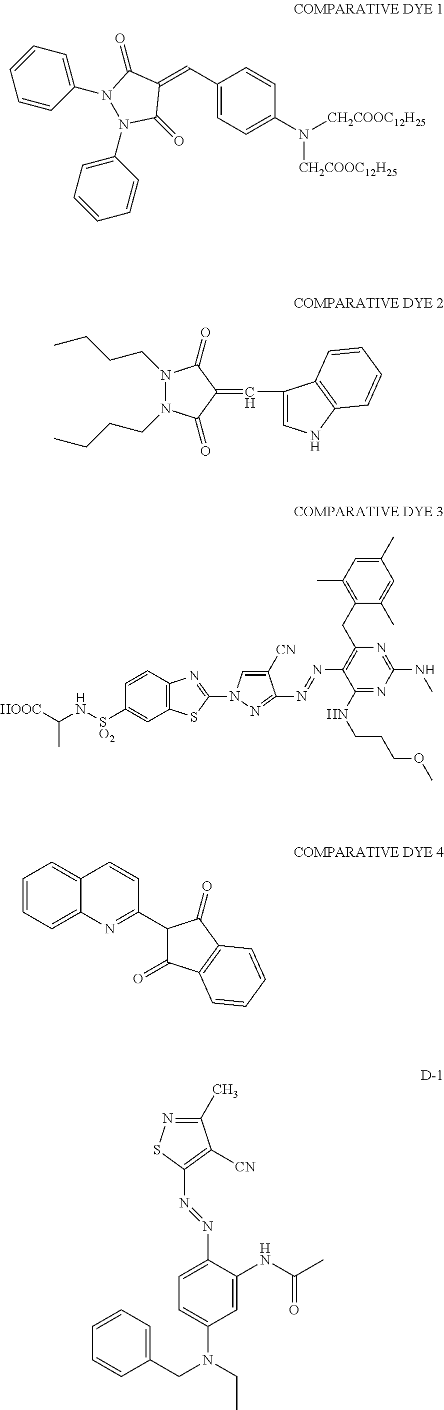

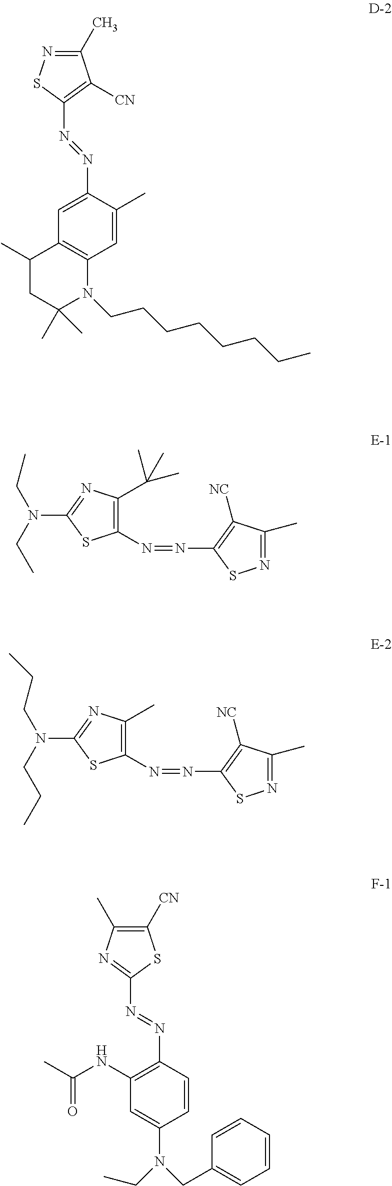

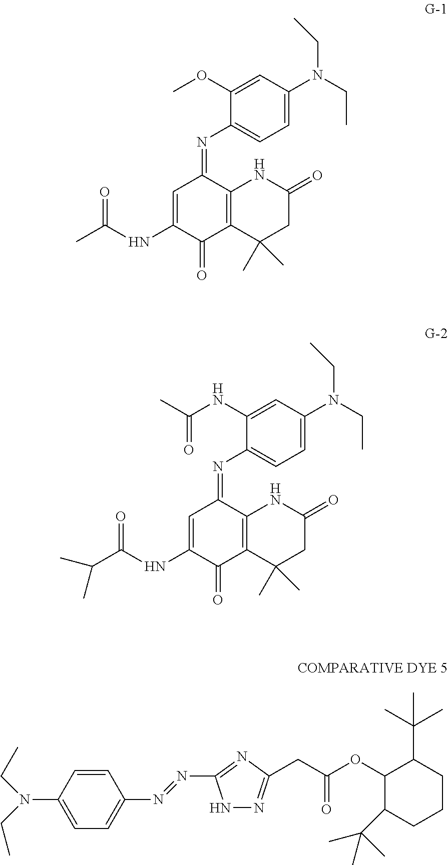

### (Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

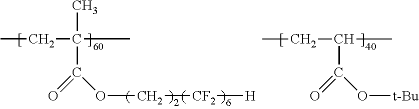

### (Base Material 1)

A polyethylene terephthalate film (manufactured by TORAY INDUSTRIES, Inc., product name: Lumirror XD-510P, film thickness: 50 μm)

### <1. Production of Light Absorption Filter No. 101>

### (1) Preparation of Resin Solution (Light Absorption Filter Forming Liquid)

Each component was mixed with the composition shown below to prepare a light absorption filter forming liquid (composition) Ba-1.

Composition of light absorption filter forming liquid Ba-1

| | |
|---|---|
| Resin 1 | 81.1 parts by mass |
| Leveling agent 1 | 0.08 parts by mass |
| Dye B-19 | 1.56 parts by mass |
| 4-methylquinoline (manufactured by | 17.2 parts by mass |
| Tokyo Chemical Industry Co., Ltd.) | |
| Methyl ethyl ketone (solvent) | 566.7 parts by mass |

Subsequently, the obtained light absorption filter forming liquid Ba-1 was filtered using a filter paper (#63, manufactured by Toyo Filter Paper Co., Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Light Absorption Filter

The light absorption filter forming liquid Ba-1 after the filtration treatment was applied onto a base material 1 by using a bar coater so that the film thickness after drying was 2.2 μm, and dried at 120° C. to produce a light absorption filter No. 101.

<2. Production of Light Absorption Filters Nos. 102 to 112, r201, and c202 to c206>

Light absorption filters Nos. 102 to 112 and c202 to c206 were produced in the same manner as in the production of the light absorption filter No. 101, except that in the production of the light absorption filter No. 101, at least any one of the kind or the blending amount of the dye was changed to the content described in Table 3. It is noted that the adjustment is carried out such that the blending amount of the leveling agent 1 and the compound B in the light absorption filter No. 101 is fixed, the blending amount of the resin is changed according to the change in the blending amount of the dye, and the mass of the entire filter does not change.

In addition, a light absorption filter No. r201 was produced in the same manner, except that in the production of the light absorption filter No. 101, the compound B and the dye were not blended and the blending amount of the resin was changed so that the mass of the entire filter was not changed.

Here, Nos. 101 to 112 are the light absorption filters of Reference Examples, Nos. c202 to c206 are light absorption filters for comparison, and No. r201 is a light absorption filter for reference.

### [Production of Light Absorption Filter Having Gas Barrier Layer]

Regarding each of the light absorption filters Nos. 101 to 112, r201, and c202 to c206 a light absorption filter (a light absorption filter having a gas barrier layer) formed by further laminating a gas barrier layer on the light absorption filter was produced as described below, and the evaluation described later was carried out.

### (1) Production of Base Material 3

The light absorption filter side of the base material-attached light absorption filter produced above was subjected to a corona treatment using a corona treatment device (product name: Corona-Plus, manufactured by VETAPHONE) under the conditions of a discharge amount of 1,000 W·min/m² and a processing speed of 3.2 m/min and used as a base material 3.

### (2) Preparation of Resin Solution

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98 to 99 mol %), whereby a gas barrier layer forming liquid was prepared.

Composition of gas barrier layer forming liquid

| | |
|---|---|
| Kuraray Exceval AQ-4105 (product name, | 4.0 parts by mass |
| manufactured by KURARAY Co., Ltd.) | |
| Pure water | 88.5 parts by mass |
| Isopropyl alcohol | 7.5 parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied to the corona-treated surface side of the base material 3 using a bar coater so that the film thickness after drying was 1.6 μm, and dried at 120° C. for 60 seconds, whereby a light absorption filter having a gas barrier layer was produced.

The light absorption filter having a gas barrier layer has a configuration in which the base material 1, the light absorption filter, and the gas barrier layer are laminated in this order.

### <Evaluation of Physical Properties of Gas Barrier Layer>

The physical properties of the gas barrier layer, which had been measured by the method described in [0182] to [0184] of WO2022/149510A, were a degree of crystallinity of 53%, an oxygen permeability of 0.4 cc/m²·day·atm, and a thickness of 1.6 μm, respectively.

<Absorbance of light absorption filter (before ultraviolet irradiation)>
(1) Measurement of absorbance

Using a UV3600 spectrophotometer (product name) manufactured by Shimadzu Corporation, the absorbance of the light absorption filter having a gas barrier layer and the standard filter in a wavelength range of 380 to 800 nm was measured for every 1 nm.

A standard filter for the light absorption filters Nos. 101 to 112, and c202 to c206, which contain the resin 1, is the light absorption filter No. r201 which has been changed not to contain the dye and the compound B.

### (2) Calculation of Absorbance

Using the absorbance value Abₓ(λ) of the light absorption filter having a gas barrier layer at each wavelength 2 nm measured as described above and the absorbance value Ab₀(λ) of the standard filter containing the same resin at each wavelength 2 nm, the absorbance Ab(λ) of the light absorption filter before ultraviolet irradiation was calculated according to the following expression.

$$Ab ( λ ) = {Ab}_{x} ( λ ) - {Ab}_{0} ( λ )$$

Hereinafter, among the absorbances Ab(λ) of the light absorption filter in a wavelength range of 400 to 700 nm, the wavelength at which the highest absorbance Ab(λ) among the wavelengths at which the highest maximal absorption is exhibited was defined as the maximal absorption wavelength (hereinafter, also simply referred to as “λₘₐₓ”), and the absorbance at λₘₐₓ was defined as the absorption maximal value (hereinafter, also simply referred to as “Ab(λₘₐₓ)”).

It is noted that the above-described maximal absorption wavelength and absorption maximal value were determined for each of the dye A, the dye B, and the dye C, and the decolorization rate described later was evaluated for each dye. Here, the dyes B-19 and B-18, which are the azo-based coloring agents represented by General Formula (i) described above, and the comparative dyes 1 to 4 are classified into the dye A, the dye 7-23, the dye F-1 which is the azo-based coloring agent represented by General Formula (ii) described above, the dyes E-1 and E-2, which are the azo-based coloring agents represented by General Formula (iii) described above, the dyes D-1 and D-2, which are the azo-based coloring agents represented by General Formula (iv) described above, and the comparative dye 5 are classified into the dye B, and the dyes G-1 and G-2, which are the indoaniline-based coloring agents represented by General Formula (v) described above, and the dye C-73 are classified into the dye C, respectively.

### <<Evaluation 1>>

The decolorization rate of each light absorption filter was evaluated.

The results are summarized in Table 4 below.

### (Ultraviolet Irradiation Test)

At room temperature, the light absorption filter having a gas barrier layer and the standard filter were irradiated with ultraviolet rays (UV) at an illuminance of 100 mW/cm² and an irradiation amount shown in Table 3 from the gas barrier layer side (the side opposite to the base material 1) by using an ultra-high pressure mercury lamp (manufactured by HOYA Corporation, product name: UL750) under atmospheric pressure (101.33 kPa).

<Absorbance of Light Absorption Filter (after Ultraviolet Irradiation)>

Using the light absorption filter having a gas barrier layer after ultraviolet irradiation and the standard filter, the absorbance Ab(λ) of the light absorption filter after ultraviolet irradiation was calculated according to the same method as described in <Absorbance of light absorption filter (before ultraviolet irradiation)> described above.

### [1. Evaluation of Decolorization Rate]

The decolorization rate was calculated according to the following expression using the maximal absorption values (Ab(λₘₐₓ)) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

[2. Evaluation of Presence or Absence of Secondary Absorption Associated with Decomposition of Coloring Agent]

The presence or absence of the absorption (secondary absorption) derived from the new coloration structure associated with the decomposition of the coloring agent was evaluated based on a ratio of an absorbance at a wavelength of 450 nm (hereinafter, also simply referred to as “Ab(450)”) to the absorption maximal value (Ab(λₘₐₓ)) before ultraviolet irradiation and a ratio of an absorbance at a wavelength of 650 nm (hereinafter, also simply referred to as “Ab(650)”) to the absorption maximal value (Ab(λₘₐₓ)) before ultraviolet irradiation. It means that the smaller the value obtained by subtracting the ratio of the following (I) from the ratio of the following (II) and the value obtained by subtracting the ratio of the following (III) from the ratio of the following (IV), the less frequently the absorption derived from the new coloration structure associated with the decomposition of the coloring agent occurs.

It is noted that in the description of Table 4 described later, as a wavelength at which the coloring agent before ultraviolet irradiation seldom exhibits absorption but new absorption due to the decomposition of the coloring agent is observed, where the wavelength is a wavelength at which the presence or absence of the secondary absorption associated with the decomposition of the coloring agent can be evaluated, a wavelength of 450 nm can be selected for evaluations of Nos. 101, 105, 106, 109 to 111, and c203, and a wavelength of 650 nm can be selected for evaluations of Nos. 101 to 109, 112, and c202 to c206, respectively.

$$( Ab ( 450 ) before ultraviolet irradiation / Ab ( {λ}_{max} ) before ultraviolet irradiation ) \times 100 \% \qquad ( I )$$

$$( Ab ( 450 ) after ultraviolet irradiation / Ab ( {λ}_{max} ) before ultraviolet irradiation ) \times 100 \% \qquad ( II )$$

$$( Ab ( 650 ) before ultraviolet irradiation / Ab ( {λ}_{max} ) before ultraviolet irradiation ) \times 100 \% \qquad ( III )$$

$$( Ab ( 650 ) after ultraviolet irradiation / Ab ( {λ}_{max} ) before ultraviolet irradiation ) \times 100 \% \qquad ( IV )$$

TABLE 3

| | Dye | | | | Compound B | | Irradiation |
|---|---|---|---|---|---|---|---|
| | | λmax | Blending | | | Blending | amount |
| No. | Type | (nm) | amount | Resin | Type | amount | (mJ/cm²) |
| 101 | B-19 | 431 | 1.56 | 1 | 4- | 17.2 | 750 |
| | | | | | methylquinoline | | |
| 102 | B-19 | 431 | 0.85 | 1 | 4- | 17.2 | 1250 |
| | 7-23 | 505 | 0.72 | | methylquinoline | | |
| | C-73 | 593 | 1.10 | | | | |
| 103 | B-19 | 431 | 1.34 | 1 | 4- | 17.2 | 1500 |
| | 7-23 | 505 | 0.92 | | methylquinoline | | |
| | C-73 | 593 | 1.57 | | | | |
| 104 | B-18 | 431 | 1.14 | 1 | 4- | 17.2 | 750 |
| | | | | | methylquinoline | | |
| 105 | D-1 | 549 | 0.95 | 1 | 4- | 17.2 | 1000 |
| | | | | | methylquinoline | | |
| 106 | D-2 | 566 | 1.03 | 1 | 4- | 17.2 | 1000 |
| | | | | | methylquinoline | | |
| 107 | E-1 | 527 | 0.82 | 1 | 4- | 17.2 | 1000 |
| | | | | | methylquinoline | | |
| 108 | E-2 | 520 | 0.79 | 1 | 4- | 17.2 | 1000 |
| | | | | | methylquinoline | | |
| 109 | F-1 | 546 | 0.95 | 1 | 4- | 17.2 | 1000 |
| | | | | | methylquinoline | | |
| 110 | G-1 | 658 | 0.99 | 1 | 4- | 17.2 | 1000 |
| | | | | | methylquinoline | | |
| 111 | G-2 | 634 | 1.12 | 1 | 4- | 17.2 | 1000 |
| | | | | | methylquinoline | | |
| 112 | B-19 | 431 | 1.31 | 1 | 4- | 17.2 | 1250 |
| | E-2 | 520 | 0.46 | | methylquinoline | | |
| | C-73 | 593 | 1.17 | | | | |
| c202 | Comparative | 450 | 1.96 | 1 | 4- | 17.2 | 750 |
| | dye 1 | | | | methylquinoline | | |
| c203 | Comparative | 416 | 0.77 | 1 | 4- | 17.2 | 750 |
| | dye 2 | | | | methylquinoline | | |
| c204 | Comparative | 443 | 1.66 | 1 | 4- | 17.2 | 750 |
| | dye 3 | | | | methylquinoline | | |
| c205 | Comparative | 421 | 1.14 | 1 | 4- | 17.2 | 750 |
| | dye 4 | | | | methylquinoline | | |
| c206 | Comparative | 453 | 1.16 | 1 | 4- | 17.2 | 1000 |
| | dye 5 | | | | methylquinoline | | |

TABLE 4

| | | | | | | Ratio of Ab (450) to | | | | Ratio of Ab (650) to | |
|---|---|---|---|---|---|---|---|---|---|---|---|
| | | | | | | Ab (λmax) before | | | | Ab (λmax) before | |
| | | | | Ab(450) | | ultraviolet irradiation | | Ab(650) | | ultraviolet irradiation | |
| | Decolorization rate | | | Before | After | Before | After | Before | After | Before | After |
| | Dye | Dye | Dye | ultraviolet | ultraviolet | ultraviolet | ultraviolet | ultraviolet | ultraviolet | ultraviolet | ultraviolet |
| No. | A | B | C | irradiation | irradiation | irradiation | irradiation | irradiation | irradiation | irradiation | irradiation |
| 101 | 93% | — | — | 0.012 | 0.012 | 5% | 5% | 0.009 | 0.005 | 3% | 2% |
| 102 | 93% | 96% | 99% | 0.195 | 0.013 | 24% | 2% | 0.008 | 0.009 | 1% | 1% |
| 103 | 90% | 93% | 97% | 0.252 | 0.030 | 24% | 3% | 0.013 | 0.015 | 1% | 1% |
| 104 | 91% | — | — | 0.220 | 0.034 | 82% | 13% | 0.005 | 0.009 | 2% | 3% |
| 105 | — | 95% | — | 0.052 | 0.006 | 14% | 2% | 0.009 | 0.009 | 2% | 2% |
| 106 | — | 96% | — | 0.028 | 0.004 | 8% | 1% | 0.012 | 0.007 | 4% | 2% |
| 107 | — | 95% | — | 0.049 | 0.005 | 17% | 2% | 0.011 | 0.012 | 4% | 4% |
| 108 | — | 95% | — | 0.061 | 0.001 | 22% | 0% | 0.007 | 0.011 | 3% | 4% |
| 109 | — | 96% | — | 0.049 | 0.004 | 16% | 1% | 0.009 | 0.011 | 3% | 4% |
| 110 | — | — | 96% | 0.007 | 0.001 | 4% | 1% | 0.146 | 0.008 | 92% | 5% |
| 111 | — | — | 96% | 0.010 | 0.001 | 5% | 0% | 0.216 | 0.009 | 99% | 4% |
| 112 | 92% | 90% | 92% | 0.277 | 0.021 | 37% | 2% | 0.007 | 0.007 | 1% | 1% |
| c202 | 84% | — | — | 0.358 | 0.058 | 100% | 16% | 0.007 | 0.005 | 2% | 1% |
| c203 | 31% | — | — | 0.031 | 0.019 | 16% | 10% | 0.007 | 0.002 | 4% | 1% |
| c204 | 56% | — | — | 0.282 | 0.126 | 97% | 43% | 0.005 | 0.008 | 2% | 3% |
| c205 | 1% | — | — | 0.330 | 0.340 | 86% | 88% | 0.011 | 0.008 | 3% | 2% |
| c206 | — | 73% | — | 0.079 | 0.021 | 100% | 27% | 0.004 | 0.006 | 5% | 8% |

(Note in table)

λₘₐₓ means a wavelength at which the highest absorbance Ab(λ) is exhibited among the maximal absorption wavelengths that the light absorption filter has in a wavelength range of 400 to 700 nm.

The blending amount of the dye and the compound B means an amount in terms of a part by mass with respect to 100 parts by mass of the filter.

Ab(λₘₐₓ) means the value of the absorbance at the maximal absorption wavelength λₘₐₓ.

“-” in the column of decolorization rate indicates that the corresponding dye is not contained.

From the results in Table 3 and Table 4, the following points can be seen.

In all of the light absorption filters Nos. c202 to c206 of Comparative Examples, which did not contain any of the azo-based coloring agent represented by any of General Formulae (i) to (iv) and the indoaniline-based coloring agent represented by General Formula (v) but contained any of the comparative dyes 1 to 5, the decolorization rate upon irradiation with UV light was low.

In contrast to these, in all of the light absorption filters Nos. 101 and 104 of Reference Examples which contain the dye B-19 or B-18 which is an azo-based coloring agent represented by General Formula (i), the light absorption filters Nos. 105 and 106 of Reference Examples which contain the dye D-1 or D-2 which is an azo-based coloring agent represented by General Formula (iv), the light absorption filters Nos. 107 and 108 of Reference Examples which contain the dye E-1 or E-2 which is an azo-based coloring agent represented by General Formula (iii), the light absorption filter No. 109 of Reference Example which contains the dye F-1 which is an azo-based coloring agent represented by General Formula (ii), and the light absorption filters Nos. 110 and 111 of Reference Examples which contain the dye G-1 or G-2 which is an indoaniline-based coloring agent represented by General Formula (v), the decolorization rate upon irradiation with UV light was high, there was almost no secondary absorption associated with the decomposition of the dye upon UV light irradiation, and the decolorizing properties was excellent.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.

### EXPLANATION OF REFERENCES

1: upper polarizing plate
2: direction of absorption axis of upper polarizing plate
3: liquid crystal cell upper electrode substrate
4: alignment control direction of upper substrate
5: liquid crystal layer
6: liquid crystal cell lower electrode substrate
7: alignment control direction of lower substrate
8: lower polarizing plate
9: direction of absorption axis of lower polarizing plate
B: backlight unit
10: liquid crystal display device

What is claimed is:

1. A light absorption filter comprising:
a support; and
a dye layer containing a resin, a dye having a main absorption wavelength band in a wavelength range of 400 to 700 nm, and a compound that generates a radical upon ultraviolet irradiation, the dye layer being provided on the support,
wherein a layer that inhibits diffusion of a component in the dye layer to the support is provided between the support and the dye layer.

2. The light absorption filter according to claim 1,
wherein the compound that generates the radical upon the ultraviolet irradiation includes a combination of a compound A having an acid group and a compound B having a structure that is capable of forming a hydrogen bond with the acid group contained in the compound A.

3. The light absorption filter according to claim 2,
wherein the compound A is chemically bonded to a polymer that constitutes the resin.

4. The light absorption filter according to claim 1,
wherein in the light absorption filter, the dye is chemically changed to be decolorized upon the ultraviolet irradiation.

5. An optical filter that is obtained by subjecting the light absorption filter according to claim 1 to mask exposure by ultraviolet irradiation.

6. An organic electroluminescent display device, an inorganic electroluminescent display device, or a liquid crystal display device, comprising:
the optical filter according to claim 5.

7. The organic electroluminescent display device, the inorganic electroluminescent display device, or the liquid crystal display device according to claim 6,
wherein a layer that inhibits light absorption of the compound that generates the radical upon the ultraviolet irradiation is provided on a viewer side with respect to the optical filter.

8. A manufacturing method for an optical filter, comprising:
irradiating the light absorption filter according to claim 1 with an ultraviolet ray to carry out mask exposure.
